(19) United States
(12) Patent Application Publication
(10) Pub. No.: US 2020/0249568 A1
(43) Pub. Date: Aug. 6, 2020

(54) CURABLE FORMULATION WITH HIGH REFRACTIVE INDEX AND ITS APPLICATION IN SURFACE RELIEF GRATING USING NANOIMPRINTING LITHOGRAPHY

(71) Applicant: Facebook Technologies, LLC, Menlo Park, CA (US)

(72) Inventors: Tingling RAO, Bellevue, WA (US); Zachary PERLMUTTER, Ballard, WA (US); Ankit VORA, Bothell, WA (US); Austin LANE, Bellevue, WA (US); Giuseppe CALAFIORE, Redmond, WA (US); Matthew E. COLBURN, Woodinville, WA (US)

(21) Appl. No.: 16/779,446

(22) Filed: Jan. 31, 2020

Related U.S. Application Data
(60) Provisional application No. 62/801,554, filed on Feb. 5, 2019.
(60) Provisional application No. 62/968,057, filed on Jan. 30, 2020.

(51) Int. Cl. G03F 7/00; C08L 63/00; C09D 11/101; B82Y 40/00

(52) U.S. Cl. CPC G03F 7/0002; B82Y 40/00; C09D 11/101; C08L 63/00

(57) ABSTRACT

Disclosed herein is a nanoimprint lithography (ML) precursor material comprising a base resin component having a first refractive index ranging from 1.45 to 1.80, and a nanoparticles component having a second refractive index greater than the first refractive index of the base resin component. According to certain embodiments, further disclosed herein are a cured NIL material made by curing the NIL precursor material, a NIL grating comprising the cured NIL material, an optical component comprising the NIL grating, and methods for forming the NIL grating and the optical component using a NIL process.

### RELATED APPLICATIONS

This application claims the benefit of, and priority to, U.S. Provisional Patent Application Ser. No. 62/801,554, filed on Feb. 5, 2019 and U.S. Provisional Patent Application Ser. No. 62/968,057, filed on Jan. 30, 2020, both of which are incorporated by reference herein in their entireties.

This application is related to U.S. patent application Ser. No. 16/778,492, filed Jan. 31, 2020, which is incorporated by reference herein in its entirety.

### BACKGROUND

An artificial reality system, such as a head-mounted display (HMD) or heads-up display (HUD) system, generally includes a near-eye display (e.g., a headset or a pair of glasses) configured to present content to a user via an electronic or optic display within, for example, about 10-20 mm in front of the user's eyes. The near-eye display may display virtual objects or combine images of real objects with virtual objects, as in virtual reality (VR), augmented reality (AR), or mixed reality (MR) applications. For example, in an AR system, a user may view both images of virtual objects (e.g., computer-generated images (CGIs)) and the surrounding environment by, for example, seeing through transparent display glasses or lenses (often referred to as optical see-through).

One example optical see-through AR system may use a waveguide-based optical display, where light of projected images may be coupled into a waveguide (e.g., a substrate), propagate within the waveguide, and be coupled out of the waveguide at different locations. In some implementations, the light of the projected images may be coupled into or out of the waveguide using a diffractive optical element, such as a slanted surface-relief grating. To achieve desired performance, such as high efficiency, low artifact, and angular selectivity, deep surface-relief gratings with large slanted angles and wide ranges of grating duty cycles may be used. However, fabricating the slanted surface-relief grating with the desired profile at a high fabrication speed and high yield remains a challenging task.

### SUMMARY

This disclosure relates generally to waveguide-based near-eye display system. More specifically, this disclosure relates to curable formulation with high refractive index and its application in nanoimprint lithographic (NIL) techniques, including but not limited to UV-NIL techniques, for manufacturing surface-relief structures, such as slanted or non-slanted surface-relief gratings used in a near-eye display system.

The disclosure provides a nanoimprint lithography (NIL) precursor material including a base resin component having a first refractive index ranging from 1.45 to 1.80, and a nanoparticles component having a second refractive index greater than the first refractive index of the base resin component. In some embodiments, the base resin component is UV curable. In some embodiments, the base resin component is light-sensitive. In some embodiments, the first refractive index ranges from 1.52 to 1.73. In some embodiments, the first refractive index ranges from 1.52 to 1.71. In some embodiments, the first refractive index ranges from 1.52 to 1.70. In some embodiments, the first refractive index ranges from 1.55 to 1.77. In some embodiments, the first refractive index ranges from 1.58 to 1.77. In some embodiments, the first refractive index ranges from 1.55 to 1.73. In some embodiments, the first refractive index ranges from 1.50 to 1.73. In some embodiments, the first refractive index ranges from 1.58 to 1.73. In some embodiments, the first refractive index ranges from 1.60 to 1.77. In some embodiments, the first refractive index ranges from 1.60 to 1.73. In some embodiments, the first refractive index ranges from 1.50 to 1.80, from 1.55 to 1.80, from 1.57 to 1.80, from 1.58 to 1.77, from 1.58 to 1.70, or from 1.60 to 1.70. In some embodiments, the first refractive index is selected from about 1.50, about 1.51, about 1.52, about 1.53, about 1.54, about 1.55, about 1.56, about 1.57, about 1.58, about 1.59, about 1.60, about 1.61, about 1.62, about 1.63, about 1.64, about 1.65, about 1.66, about 1.67, about 1.68, about 1.69, about 1.70, about 1.71, about 1.72, about 1.73, about 1.74, about 1.75, about 1.76, and about 1.77. In some embodiments, the first refractive index is measured at 589 nm.

In some embodiments, the base resin component has a viscosity ranging from 0.5 cps to 400 cps. In some embodiments, the base resin component has a viscosity ranging from 2 cps to 100 cps. In some embodiments, the base resin component has a viscosity ranging from 10 cps to 100 cps. In some embodiments, the base resin component has a viscosity ranging from 10 cps to 60 cps. In some embodiments, the base resin component has a viscosity selected from about 1 cps, about 2 cps, about 3 cps, about 4 cps, about 5 cps, about 6 cps, about 7 cps, about 8 cps, about 9 cps, about 10 cps, about 11 cps, about 12 cps, about 13 cps, about 14 cps, about 15 cps, about 16 cps, about 17 cps, about 18 cps, about 19 cps, about 20 cps, about 21 cps, about 22 cps, about 23 cps, about 24 cps, about 25 cps, about 26 cps, about 27 cps, about 28 cps, about 29 cps, about 30 cps, about 31 cps, about 32 cps, about 33 cps, about 34 cps, about 35 cps, about 36 cps, about 37 cps, about 38 cps, about 39 cps, about 40 cps, about 41 cps, about 42 cps, about 43 cps, about 44 cps, about 45 cps, about 46 cps, about 47 cps, about 48 cps, about 49 cps, about 50 cps, about 51 cps, about 52 cps, about 53 cps, about 54 cps, about 55 cps, about 56 cps, about 57 cps, about 58 cps, about 59 cps, and about 60 cps. In some embodiments, the viscosity is measured in the absence of the nanoparticles component. In some embodiments, the viscosity is measured in the absence of a solvent. In some embodiments, the base resin component is a liquid at room temperature. In some embodiments, room temperature is considered between 15 and 25° C. In some embodiments, the base resin component is a liquid at a temperature between 20 and 25° C.

In some embodiments, the base resin component comprises one or more crosslinkable monomers, one or more polymerizable monomers, or both. In some embodiments, the crosslinkable monomers or the polymerizable monomers include one or more crosslinkable or polymerizable moieties. In some embodiments, the crosslinkable or polymerizable moieties are selected from an ethylenically unsaturated group, an oxirane ring, and a heterocyclic group. In some embodiments, the crosslinkable or polymerizable moieties are selected from vinyl, allyl, epoxide, acrylate, and methacrylate. In some embodiments, the crosslinkable or polymerizable moieties are selected from optionally substituted alkenyl, optionally substituted cycloalkenyl, optionally substituted alkynyl, optionally substituted acrylate, optionally substituted methacrylate, optionally substituted styrene, optionally substituted epoxide, optionally substituted thiirane, optionally substituted lactone, and optionally substituted carbonate. In some embodiments, the crosslinkable or polymerizable moieties are selected from:

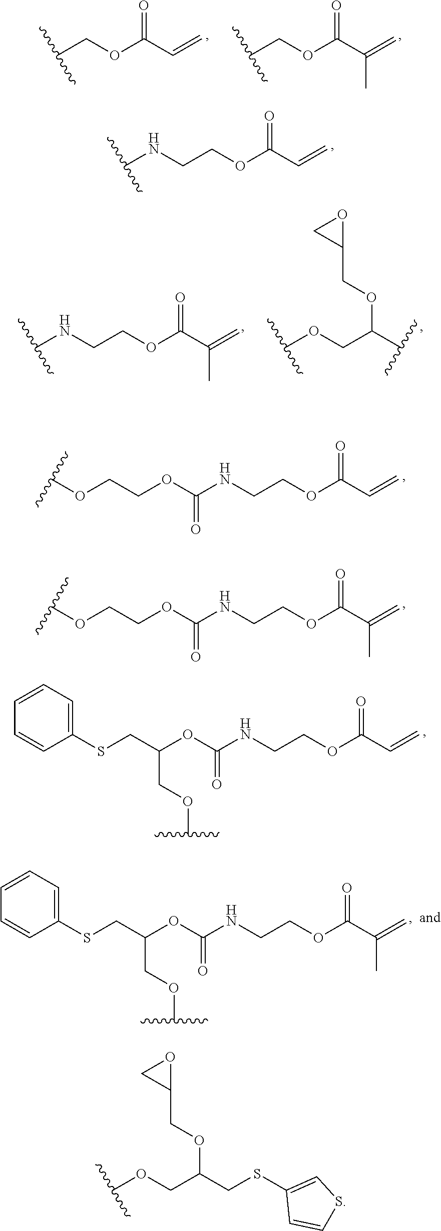

In some embodiments, the crosslinkable monomers or the polymerizable monomers include one or more moieties selected from optionally substituted alkyl, optionally substituted heteroalkyl, optionally substituted alkenyl, optionally substituted alkynyl, optionally substituted cycloalkyl, optionally substituted heterocycloalkyl, optionally substituted aryl, optionally substituted arylalkyl, optionally substituted heteroaryl, and optionally substituted heteroarylalkyl. In some embodiments, the crosslinkable monomers or the polymerizable monomers include one or more moieties selected from fluorene, cardo fluorene, spiro fluorene, thianthrene, thiophosphate, anthraquinone, and lactam. In some embodiments, the crosslinkable monomers or the polymerizable monomers include one or more linking groups selected from —C₁₋₁₀ alkyl-, —O—C₁₋₁₀ alkyl-, —C₁₋₁₀ alkenyl-, —O—C₁₋₁₀ alkenyl-, —C₁₋₁₀ cycloalkenyl-, —O—C₁₋₁₀ cycloalkenyl-, —C₁₋₁₀ alkynyl-, —O—C₁₋₁₀ alkynyl-, —C₁₋₁₀ aryl-, —O—C₁₋₁₀—, -aryl-, —O—, —S—, —C(O)—, —C(O)O—, —OC(O)—, —OC(O)O—, —N(R^{b})—, —C(O)N(R^{b})—, —N(R^{b})C(O)—, —OC(O)N(R^{b})—, —N(R^{b})C(O)O—, —SC(O)N(R^{b})—, —N(R^{b})C(O)S—, —N(R^{b})C(O)N(R^{b})—, —N(R^{b})C(NR^{b})N(R^{b})—, —N(R^{b})S(O)_{w}—, —S(O)_{w}N(R^{b})—, —OS(O)_{w}—, —OS(O)_{w}O—, —O(O)P(OR^{b})O—, (O)P(O—)₃, —O(S)P(OR^{b})O—, and (S)P(O—)₃, where w is 1 or 2, and R^{b} is independently hydrogen, optionally substituted alkyl, or optionally substituted aryl.

In some embodiments, the crosslinkable monomers or the polymerizable monomers include one or more terminal groups selected from optionally substituted thiophenyl, optionally substituted thiopyranyl, optionally substituted thienothiophenyl, and optionally substituted benzothiophenyl. In some embodiments, the base resin component includes one or more derivatives of bisfluorene, dithiolane, thianthrene, biphenol, o-phenylphenol, phenoxy benzyl, bisphenol A, bisphenol F, benzyl, or phenol. In some embodiments, the base resin component includes one or more of (2,7-bis[(2-acryloyloxyethl)-sulfanyl]thianthrene), benzyl methacrylate, 1,6-hexanediol diacrylate, 1,4-butanediol diacrylate, acryloxypropylsilsesquioxane, or methylsilsesquioxane.

In some embodiments, the base resin component includes one or more of trimethylolpropane (EO)n triacrylate, caprolactone acrylate, polypropylene glycol monomethacrylate, cyclic trimethylolpropane formal acrylate, phenoxy benzyl acrylate, 3,3,5-trimethyl cyclohexyl acrylate, isobornyl acrylate, o-phenylphenol EO acrylate, 4-tert-butylcyclohexyl acrylate, benzyl acrylate, benzyl methacrylate, biphenylmethyl acrylate, lauryl acrylate, lauryl methacrylate, tridecyl acrylate, lauryl tetradecyl methacrylate, isodecyl acrylate, isodecyl methacrylate, phenol (EO) acrylate, phenoxyethyl methacrylate, phenol (EO)2 acrylate, phenol (EO)4 acrylate, tetrahydrofurfuryl acrylate, tetrahydrofurfuryl methacrylate, nonyl phenol (PO)2 acrylate, nonyl phenol (EO)4 acrylate, nonyl phenol (EO)8 acrylate, ethoxy ethoxy ethyl acrylate, stearyl acrylate, stearyl methacrylate, methoxy PEG600 methacrylate, 1,6-hexanediol diacrylate, 1,6-hexanediol dimethacrylate, 1,6-hexanediol (EO)n diacrylate, polypropylene glycol 400 diacrylate, 1,4-butanediol dimethacrylate, polypropylene glycol 700 (EO)6 dimethacrylate, 1,6-Hexanediol (EO)n diacrylate, hydroxy pivalic acid neopentyl glycol diacrylate, bisphenol A (EO)10 diacrylate, bisphenol A (EO)10 dimethacrylate, neopentyl glycol dimethacrylate, neopentyl glycol (PO)2 diacrylate, tripropylene glycol diacrylate, ethylene glycol dimethacrylate, dipropylene glycol diacrylate, bisphenol A (EO)30 diacrylate, bisphenol A (EO)30 dimethacrylate, diethylene glycol dimethacrylate, triethylene glycol diacrylate, triethylene glycol dimethacrylate, tetraethylene glycol dimethacrylate, bisphenol A (EO)4 diacrylate, bisphenol A (EO)4 dimethacrylate, bisphenol A (EO)3 diacrylate, bisphenol A (EO)3 dimethacrylate, 1,3-butylene glycol dimethacrylate, tricyclodecane dimethanol diacrylate, tetraethylene glycol diacrylate, polyethylene glycol 400 diacrylate, polyethylene glycol 400 dimethacrylate, polyethylene glycol 200 diacrylate, polyethylene glycol 200 dimethacrylate, polyethylene glycol 300 diacrylate, polyethylene glycol 600 diacrylate, polyethylene glycol 600 dimethacrylate, bisphenol F (EO)4 diacrylate, trimethylolpropane triacrylate, trimethylolpropane trimethacrylate, trimethylolpropane (EO)3 triacrylate, trimethylolpropane (EO)15 triacrylate, trimethylolpropane (EO)6 triacrylate, trimethylolpropane (EO)9 triacrylate, glycerine (PO)3 triacrylate, pentaerythritol triacrylate, trimethylolpropane (PO)3 triacrylate, tris(2-hydroxyethyl)isocyanurate triacrylate, pentaerythritol (EO)n tetraacrylate, ditrimethylolpropane tetraacrylate, pentaerythritol tetraacrylate, dipentaerythritol pentaacrylate, and dipentaerythritol hexaacrylate.

In some embodiments, the base resin component includes one or more of a phosphate methacrylate, an amine acrylate, an acrylated amine synergist, a carboxylethyl acrylate, a modified epoxy acrylate, a bisfluorene diacrylate, a modified bisphenol fluorene diacrylate, a modified bisphenol fluorene type, a butadiene acrylate, an aromatic difunctional acrylate, an aliphatic multifunctional acrylate, a polyester acrylate, a trifunctional polyester acrylate, a tetrafunctional polyester acrylate, a phenyl epoxy acrylate, a bisphenol A epoxy acrylate, a water soluble acrylate, an aliphatic alkyl epoxy acrylate, a bisphenol A epoxy methacrylate, a soybean oil epoxy acrylate, a difunctional polyester acrylate, a trifunctional polyester acrylate, a tetrafunctional polyester acrylate, a chlorinated polyester acrylate, a hexafunctional polyester acrylate, an aliphatic difunctional acrylate, an aliphatic difunctional methacrylate, an aliphatic trifunctional acrylate, an aliphatic trifunctional methacrylate, an aromatic difunctional acrylate, an aromatic tetrafunctional acrylate, an aliphatic tetrafunctional acrylate, an aliphatic hexafunctional acrylate, an aromatic hexafunctional acrylate, an acrylic acrylate, a polyester acrylate, a sucrose benzoate, a caprolactone methacrylate, a caprolactone acrylate, a phosphate methacrylate, an aliphatic multifunctional acrylate, a phenol novolac epoxy acrylate, a cresol novolac epoxy acrylate, an alkali strippable polyester acrylate, a melamine acrylate, a silicone polyester acrylate, a silicone urethane acrylate, a dendritic acrylate, an aliphatic tetrafunctional methacrylate, a water dispersion urethane acrylate, a water soluble acrylate, an aminated polyester acrylate, a modified epoxy acrylate, or a trifunctional polyester acrylate.

In some embodiments, the base resin component includes one or more of:

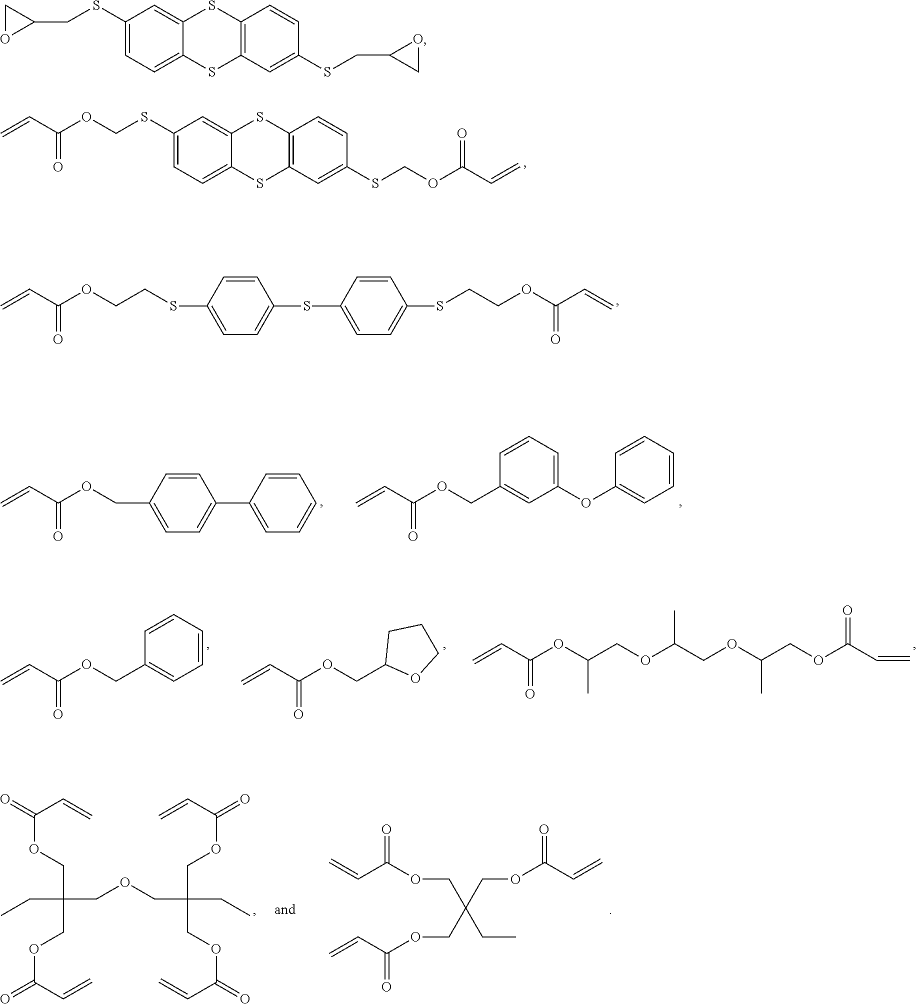

In some embodiments, the base resin component includes one or more of:

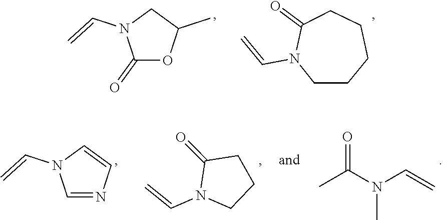

In some embodiments, the base resin component includes one or more fluorinated compounds. In some embodiments, the one or more fluorinated compounds are selected from: 2,2,3,3,4,4,5,5,6,6,7,7-dodecafluoroheptyl acrylate, 3,3,4,4,5,5,6,6,7,7,8,8,9,9,10,10,11,11,12,12,12-heneicosafluorododecyl acrylate, 3,3,4,4,5,5,6,6,7,7,8,8,9,9,10,10,10-heptadecafluorodecyl methacrylate, 2,2,3,3,4,4,4-heptafluorobutyl acrylate, 2,2,3,3,4,4,4-heptafluorobutyl methacrylate, 2,2,3,4,4,4-hexafluorobutyl acrylate, 2,2,3,4,4,4-hexafluorobutyl methacrylate, 1,1,1,3,3,3-hexafluoroisopropyl acrylate, 1,1,1,3,3,3-hexafluoroisopropyl methacrylate, 2,2,3,3,4,4,5,5-octafluoropentyl acrylate, 2,2,3,3,4,4,5,5-octafluoropentyl methacrylate, 2,2,3,3,3-pentafluoropropyl acrylate, 2,2,3,3,3-pentafluoropropyl methacrylate, 1H,1H,2H,2H-perfluorodecyl acrylate, 2,2,3,3-tetrafluoropropyl methacrylate, 3,3,4,4,5,5,6,6,7,7,8,8,8-tridecafluorooctyl acrylate, 3,3,4,4,5,5,6,6,7,7,8,8,8-tridecafluorooctyl methacrylate, 2,2,2-trifluoroethyl methacrylate, and 2-[(1′,1′,1′-trifluoro-2′-(trifluoromethyl)-2′-hydroxy)propyl]-3-norbornyl methacrylate.

In some embodiments, the base resin component further includes one or more solvents. In some embodiments, the one or more solvents are selected from 2-(1-methoxy)propyl acetate, propylene glycol monomethyl ether acetate, propylene glycol methyl ether, ethyl acetate, xylene, and toluene.

In some embodiments, the base resin component further includes one or more of a photo radical generator, a photo acid generator, or both.

In some embodiments, the base resin component further includes one or more inhibitors. In some embodiments, the one or more inhibitors are selected from monomethyl ether hydroquinone and 4-tert-butylcatechol.

In some embodiments, the base resin component further includes one or more surfactants. In some embodiments, the one or more surfactants are selected from a fluorinated surfactant, a crosslinkable surfactant, and a non-crosslinkable surfactant.

In some embodiments, the base resin component further includes one or more siloxane derivative compounds. In some embodiments, the base resin component does not include silicon.

In some embodiments, the nanoparticles component comprises one or more of titanium oxide, zirconium oxide, hafnium oxide, tungsten oxide, zinc tellurium, gallium phosphide, or any combination or derivative thereof. In some embodiments, the nanoparticles component includes titanium oxide nanoparticles. In some embodiments, the nanoparticles component includes zirconium oxide nanoparticles. In some embodiments, the nanoparticles component includes a mixture of titanium oxide nanoparticles and zirconium oxide nanoparticles.

In some embodiments, the nanoparticles component includes a plurality of surface-modified nanoparticles, a plurality of capped nanoparticles, or both. In some embodiments, the surface-modified nanoparticles, the capped nanoparticles, or both, include a substantially inorganic core, and a substantially organic shell. In some embodiments, the substantially organic shell includes one or more crosslinkable or polymerizable moieties. In some embodiments, the one or more crosslinkable or polymerizable moieties are linked to the substantially inorganic core.

In some embodiments, the crosslinkable or polymerizable moieties include one or more of an ethylenically unsaturated group, an oxirane ring, or a heterocyclic group. In some embodiments, the crosslinkable or polymerizable moieties include one or more of vinyl, allyl, epoxide, acrylate, and methacrylate. In some embodiments, the crosslinkable or polymerizable moieties include one or more of optionally substituted alkenyl, optionally substituted cycloalkenyl, optionally substituted alkynyl, optionally substituted acrylate, optionally substituted methacrylate, optionally substituted styrene, optionally substituted epoxide, optionally substituted thiirane, optionally substituted lactone, and optionally substituted carbonate. In some embodiments, the crosslinkable or polymerizable moieties include one or more linking groups selected from —Si(—O—)₃, —C₁₋₁₀ alkyl-, —O—C₁₋₁₀ alkyl-, —C₁₋₁₀ alkenyl-, —O—C₁₋₁₀ alkenyl-, —C₁₋₁₀ cycloalkenyl-, —O—C₁₋₁₀ cycloalkenyl-, —C₁₋₁₀ alkynyl-, —O—C₁₋₁₀ alkynyl-, —C₁₋₁₀ aryl-, —O—C₁₋₁₀—, -aryl-, —O—, —S—, —C(O)—, —C(O)O—, —OC(O)—, —OC(O)O—, —N(R^{b})—, —C(O)N(R^{b})—, —N(R^{b})C(O)—, —OC(O)N(R^{b})—, —N(R^{b})C(O)O—, —SC(O)N(R^{b})—, —N(R^{b})C(O)S—, —N(R^{b})C(O)N(R^{b})—, —N(R^{b})C(NR^{b})N(R^{b})—, —N(R^{b})S(O)_{w}—, —S(O)_{w}N(R^{b})—, —S(O)_{w}O—, —OS(O)_{w}—, —OS(O)_{w}O—, —O(O)P(OR^{b})O—, (O)P(O—)₃, —O(S)P(OR^{b})O—, and (S)P(O—)₃, where w is 1 or 2, and R^{b} is independently hydrogen, optionally substituted alkyl, or optionally substituted aryl.

In some embodiments, the substantially organic shell includes one or more of an organosilane or a corresponding organosilanyl substituent, an organoalcohol or a corresponding organoalkoxy substituent, or an organocarboxylic acid or a corresponding organocarboxylate substituent. In some embodiments, the organosilane is selected from n-propyltrimethoxysilane, n-propyltriethoxysilane, n-octyltrimethoxysilane, n-octyltriethoxysilane, phenylrimethoxysilane, 2-methoxy(polyethyleneoxy)propyl-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanatopropyltriethoxysilane, 3-isocyanatopropyltrimethoxysilane, and glycidoxypropyltrimethoxysilane. In some embodiments, the organoalcohol is selected from heptanol, hexanol, octanol, benzyl alcohol, phenol, ethanol, propanol, butanol, oleylalcohol, dodecylalcohol, octadecanol and triethylene glycol monomethyl ether. In some embodiments, the organocarboxylic acid is selected from octanoic acid, acetic acid, propionic acid, 2-2-(2-methoxyethoxy)ethoxyacetic acid, oleic acid, and benzoic acid. In some embodiments, the substantially organic shell includes one or more of 3-(methacryloyloxy)propyl trimethoxysilane, 3-(methacryloyloxy)propyl dimethoxysilyl, or 3-(methacryloyloxy)propyl methoxysiloxyl.

In some embodiments, the diameter of a substantially inorganic core ranges from about 1 nm to about 25 nm. In some embodiments, the diameter of a substantially inorganic core is selected from about 1 nm, about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, and about 25 nm. In some embodiments, the diameter of a substantially inorganic core is measured by transmission electron microscopy (TEM).

In some embodiments, the diameter of a surface-modified nanoparticle, a capped nanoparticle, or both, including a substantially organic shell, ranges from about 5 nm to about 100 nm. In some embodiments, the diameter of a surface-modified nanoparticle, a capped nanoparticle, or both, including a substantially organic shell, ranges from about 10 nm to about 50 nm. In some embodiments, the diameter of a surface-modified nanoparticle, a capped nanoparticle, or both, including a substantially organic shell, is selected from about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, and about 25 nm, about 26 nm, about 27 nm, about 28 nm, about 29 nm, about 30 nm, about 31 nm, about 32 nm, about 33 nm, about 34 nm, about 35 nm, about 36 nm, about 37 nm, about 38 nm, about 39 nm, about 40 nm, about 41 nm, about 42 nm, about 43 nm, about 44 nm, about 45 nm, about 46 nm, about 47 nm, about 48 nm, about 49 nm, about 50 nm, about 51 nm, about 52 nm, about 53 nm, about 54 nm, about 55 nm, about 56 nm, about 57 nm, about 58 nm, about 59 nm, about 60 nm, about 61 nm, about 62 nm, about 63 nm, about 64 nm, about 65 nm, about 66 nm, about 67 nm, about 68 nm, about 69 nm, about 70 nm, about 71 nm, about 72 nm, about 73 nm, about 74 nm, about 75 nm, about 76 nm, about 77 nm, about 78 nm, about 79 nm, about 80 nm, about 81 nm, about 82 nm, about 83 nm, about 84 nm, about 85 nm, about 86 nm, about 87 nm, about 88 nm, about 89 nm, about 90 nm, about 91 nm, about 92 nm, about 93 nm, about 94 nm, about 95 nm, about 96 nm, about 97 nm, about 98 nm, about 99 nm, and about 100 nm. In some embodiments, the diameter of a surface-modified nanoparticle, a capped nanoparticle, or both, including a substantially organic shell, is measured by dynamic light scattering (DLS).

In some embodiments, the volume fraction of the substantially inorganic core in the surface-modified nanoparticles, the capped nanoparticles, or both, ranges from about 60% to about 90%. In some embodiments, the volume fraction of the substantially inorganic core in the surface-modified nanoparticles, the capped nanoparticles, or both, is selected from about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, and about 90%. In some embodiments, the volume fraction of the substantially organic shell in the surface-modified nanoparticles, the capped nanoparticles, or both, ranges from about 10% to about 40%. In some embodiments, the volume fraction of the substantially organic shell in the surface-modified nanoparticles, the capped nanoparticles, or both, is selected from about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, and about 40%.

In some embodiments, the second refractive index ranges from 2.00 to 2.61. In some embodiments, the second refractive index is selected from about 2.00, about 2.01, about 2.02, about 2.03, about 2.04, about 2.05, about 2.06, about 2.07, about 2.08, about 2.09, about 2.10, about 2.11, about 2.12, about 2.13, about 2.14, about 2.15, about 2.16, about 2.17, about 2.18, 2.19, about 2.20, about 2.21, about 2.22, about 2.23, about 2.24, about 2.25, about 2.26, about 2.27, about 2.28, about 2.29, about 2.30, about 2.31, about 2.32, about 2.33, about 2.34, about 2.35, about 2.36, about 2.37, about 2.38, about 2.39, about 2.40, about 2.41, about 2.42, about 2.43, about 2.44, about 2.45, about 2.46, about 2.47, about 2.48, about 2.49, about 2.50, about 2.51, about 2.52, about 2.53, about 2.54, about 2.55, about 2.56, about 2.57, about 2.58, about 2.59, about 2.60, and about 2.61.

The disclosure also provides a cured NIL material including a substantially cured resin component and a nanoparticles component ranging from 45 wt. % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component.

In some embodiments, the nanoparticles component ranges from 45 wt. % to 85 wt. %, from 45 wt. % to 80 wt. %, or from 45 wt. % to 75 wt. % of the cured NIL material. In some embodiments, the nanoparticles component is about 45 wt. %, about 46 wt. %, about 47 wt. %, about 48 wt. %, about 49 wt. %, about 50 wt. %, about 51 wt. %, about 52 wt. %, about 53 wt. %, about 54 wt. %, about 55 wt. %, about 56 wt. %, about 57 wt. %, about 58 wt. %, about 59 wt. %, about 60 wt. %, about 61 wt. %, about 62 wt. %, about 63 wt. %, about 64 wt. %, about 65 wt. %, about 66 wt. %, about 67 wt. %, about 68 wt. %, about 69 wt. %, about 70 wt. %, about 71 wt. %, about 72 wt. %, about 73 wt. %, about 74 wt. %, or about 75 wt. % of the cured NIL material. In some embodiments, the third refractive index ranges from 1.75 to 2.00. In some embodiments, the third refractive index is selected from about 1.75, about 1.76, about 1.77, about 1.78, about 1.79, about 1.80, 1.81, about 1.82, about 1.83, about 1.84, about 1.85, about 1.86, about 1.87, about 1.88, about 1.89, about 1.90, about 1.91, about 1.92, about 1.93, about 1.94, about 1.95, about 1.96, about 1.97, about 1.98, about 1.99, and about 2.00.

The disclosure also provides a NIL grating comprising a cured NIL material including a substantially cured resin component and a nanoparticles component ranging from 45 wt. to % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component.

In some embodiments, the third refractive index ranges from 1.75 to 2.00. In some embodiments, the grating is a slanted grating or a non-slanted grating. In some embodiments, the grating has a duty cycle ranging from 10% to 90%. In some embodiments, the grating has a duty cycle ranging from 30% to 90%. In some embodiments, the grating has a duty cycle ranging from 35% to 90%. In some embodiments, a slanted grating includes at least one slant angle ranging from more than 0° to 70°. In some embodiments, a slanted grating includes at least one slant angle greater than 30°. In some embodiments, a slanted grating includes at least one slant angle greater than 35°. In some embodiments, the grating has a depth greater than 100 nm. In some embodiments, the grating has an aspect ratio greater than 3:1.

The disclosure also provides an optical component comprising a NIL grating including a cured NIL material including a substantially cured resin component and a nanoparticles component ranging from 45 wt. to % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component.

The disclosure also provides a method of modulating the third refractive index of a cured NIL material including a substantially cured resin component and a nanoparticles component ranging from 45 wt. % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component, the method comprising modulating the first refractive index of the base resin component of the NIL precursor material. In some embodiments, decreasing the first refractive index of the base resin component of the NIL precursor material results in an increase of the third refractive index of the cured NIL material.

The disclosure also provides a method of forming a NIL grating including a cured NIL material including a substantially cured resin component and a nanoparticles component ranging from 45 wt. to % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component, the method comprising imprinting the NIL precursor material using a NIL process.

The disclosure also provides a method of forming an optical component comprising a NIL grating including a cured NIL material including a substantially cured resin component and a nanoparticles component ranging from 45 wt. to % 90 wt. % of the cured NIL material, where the cured NIL material has a third refractive index, and where the cured material is made by exposing to a light source a nanoimprint lithography (NIL) precursor material including a base resin component having a first refractive index ranging from 1.45 to 1.80, and a nanoparticles component having a second refractive index greater than the first refractive index of the base resin component, the method including imprinting the NIL precursor material using a NIL process.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example artificial reality system environment including a near-eye display according to certain embodiments.

FIG. 2 is a perspective view of an example near-eye display in the form of a head-mounted display (HMD) device for implementing some of the examples disclosed herein.

FIG. 3 is a perspective view of an example near-eye display in the form of a pair of glasses for implementing some of the examples disclosed herein.

FIG. 4 illustrates an example optical see-through augmented reality system using a waveguide display according to certain embodiments.

FIG. 5. illustrates an example slanted grating coupler in an example waveguide display according to certain embodiments.

FIGS. 6A and 6B illustrate an example process for fabricating a slanted surface-relief grating by molding according to certain embodiments. FIG. 6A shows a molding process. FIG. 6B shows a demolding process.

FIGS. 7A-7D illustrate an example process for fabricating a soft stamp used to make a slanted surface-relief grating according to certain embodiments. FIG. 7A shows a master mold.

FIG. 7B illustrates the master mold coated with a soft stamp material layer. FIG. 7C illustrates a lamination process for laminating a soft stamp foil onto the soft stamp material layer. FIG. 7D illustrates a delamination process, where the soft stamp including the soft stamp foil and the attached soft stamp material layer is detached from the master mold.

FIGS. 8A-8D illustrate an example process for fabricating a slanted surface-relief grating using a soft stamp according to certain embodiments. FIG. 8A shows a waveguide coated with an imprint resin layer. FIG. 8B shows the lamination of the soft stamp onto the imprint resin layer. FIG. 8C shows the delamination of the soft stamp from the imprint resin layer. FIG. 8D shows an example of an imprinted slanted grating formed on the waveguide.

FIG. 9 is a simplified flow chart illustrating an example method of fabricating a slanted surface-relief grating using nanoimprint lithography according to certain embodiments.

FIGS. 10A-10D are plots showing the nanoimprint lithography (NIL) material refractive index versus light wavelength for various NIL materials having different base resin materials and varying nanoparticle loadings.

FIG. 11 is a plot showing the NIL material refractive index for visible light at 589 nm versus nanoparticle loading for the various NIL materials of FIGS. 10A-10D.

FIG. 12A is a plot showing the NIL material refractive index for visible light at 589 nm versus nanoparticle loading.

FIG. 12B is a plot showing the NIL material refractive index for visible light at 589 nm versus weight percentage of the component nanoparticles.

FIG. 13 is a plot showing the NIL material refractive index versus light wavelength for various NIL materials having different base resin materials and the same nanoparticle loading.

FIG. 14 is a simplified block diagram of an example electronic system of an example near-eye display according to certain embodiments.

FIG. 15 illustrates a cross-sectional view of an example nanoparticle, showing the structure of the nanoparticle in accordance with some embodiments.

FIGS. 16A and 16B illustrate a non-slanted grating 16A and a slanted grating 16B in accordance with some embodiments.

FIG. 17 is a plot showing that the refractive index of various imprinting formulations comprising 75% TiO₂ nanoparticles increases as the viscosity of the base resin component decreases, in accordance with some embodiments.

FIG. 18 is a plot showing that the refractive index of various imprinting formulations comprising 75% TiO₂ nanoparticles increases as the viscosity of the base resin component decreases, in accordance with some embodiments.

FIG. 19 illustrates the results of slanted imprinting processes for the various imprinting formulations of FIG. 18 in accordance with some embodiments.

FIGS. 20A and 20B illustrate the impact of various post-exposure bake processes on the refractive index and optics of a surface-relief grating using an example imprinting formulation of FIG. 18 in accordance with some embodiments.

FIG. 21 illustrates the impact of various post-exposure bake processes on the refractive index of a surface-relief grating using an example imprinting formulation of FIG. 18 in accordance with some embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

### Introduction

This disclosure relates generally to waveguide-based near-eye display system. More specifically, and without limitation, this disclosure relates to curable nanoimprint materials with high refractive index for nanoimprinting surface-relief structures, such as slanted or non-slanted surface-relief gratings used in a near-eye display system.

The slanted surface-relief structures may be fabricated using many different nanofabrication techniques, including nanoimprint lithography (NIL) molding techniques. NIL molding may significantly reduce the cost of the slanted surface-relief structures. In NIL molding, a substrate may be coated with a layer of a NIL material, which may include a mixture of a base resin, high refractive index nanoparticles, solvent, and other additives. A NIL stamp with slanted structures may be pressed against the NIL material layer for molding a slanted grating in the NIL material layer. The NIL material layer may be cured subsequently using, for example, ultraviolet (UV) light and/or heat. The NIL mold may then be detached from the NIL material layer, and slanted structures may be formed in the NIL material layer.

Generally, it is desirable to use a NIL material with a high refractive index (e.g., greater than 1.78 or higher) for imprinting the slanted surface-relief structure in order to achieve, for example, high efficiency, low artifact, and angular selectivity. However, it may be very difficult and/or more expensive to obtain base resins with a high refractive index (e.g., 1.7 or higher). Using high refractive index nanoparticles (e.g., comprising zirconium oxide (ZrOₓ), hafnium oxide (interchangeably, HfOₓ), titanium oxide (interchangeably, TiOₓ or TiO₂), etc.) and/or increasing the loading of the high refractive index nanoparticles in a NIL material mixture can increase the refractive index of the NIL material mixture. However, a NIL-molded grating with a high refractive index may not be obtained by merely increasing the weight percentage of the nanoparticles in the NIL material mixture. A certain amount of base resin needs to be maintained for the NIL material mixture to be hardened to maintain the molded shape or structure, which is achieved by curing the base resin that acts as a binder in the NIL material. Further, when the molded structure includes a high aspect ratio and/or inclined surfaces, the NIL material mixture needs to have certain viscosity and/or elasticity at the imprinting temperature (e.g., room temperature) so that the NIL material mixture can flow inside the mold and conform to the shape of the mold for carrying out the NIL molding process. Additionally, photocatalytical effect may occur when certain nanoparticles, such as titanium oxide nanoparticles, are included in the NIL material and the NIL material is exposed to low wavelength UV light. Such photocatalytical effect may cause degradation of the base resin over time, which can further affect the refractive index of the cured NIL-molded grating. Therefore, it can be challenging to obtain curable formulations that are stable, yield a high refractive index in the NIL-molded grating, and are also suitable for NIL molding.

The present disclosure provides a nanoimprint lithography (NIL) precursor material comprising a base resin component having a first refractive index ranging from 1.45 to 1.80, and a nanoparticles component having a second refractive index greater than the first refractive index of the base resin component. Some embodiments of the present disclosure further provide a cured NIL material made by curing the NIL precursor material, a NIL grating comprising the cured NIL material, an optical component comprising the NIL grating, and methods for forming the NIL grating and the optical component using a NIL process.

According to some embodiments, a NIL precursor material may be provided for NIL molding of a slanted grating having a refractive index greater than 1.75, greater than 1.78, greater than 1.8, greater than 1.85, greater than 1.9, greater than 1.93, greater than 1.95, or greater than 2. The NIL precursor material may include an electromagnetic radiation sensitive material or, more specifically, a light sensitive or light-curable optical material. For example, the NIL precursor material may include a light-sensitive base resin that includes a base material having a functional group for polymerization during photo-curing (e.g., UV-curing). The NIL precursor material may also include nanoparticles having relatively high refractive indices for increasing the refractive index of the NIL precursor material as well as the refractive index of the cured NIL material. The NIL precursor material may also include some optional additives, one or more radical and/or acid generators, one or more crosslinking agents, and one or more solvents. In general, the base resin material, the functional group, the nanoparticle material, and/or the loading of the nanoparticles can be selected to tune the refractive index of the moldable NIL precursor material.

According to some embodiments, a NIL material may be provided for molding a slanted grating having a refractive index greater than 1.78, greater than 1.8, greater than 1.85, greater than 1.9, greater than 1.93, greater than 1.95, or greater than 2. In some embodiments, the NIL material includes nanoparticles and a base resin characterized by a refractive index greater than 1.55, such as from about 1.58 to about 1.77. The weight percentage of the nanoparticles may range from 45% to 90%, 45% to 85%, 45% to 80%, or 45% to 75%, depending on the types of the nanoparticles utilized to maintain sufficient imprintability for carrying out NIL molding and the cured NIL material to be achieved. In some embodiments, the NIL material includes nanoparticles and an organic base resin. The organic base resin may be characterized by a refractive index ranging from 1.45 to 1.8. The nanoparticle loading percentage may range from 45% to 90%, 45% to 85%, 45% to 80%, or 45% to 75%.

According to certain embodiments, the NIL material may include a light-curable optical material for molding a slanted grating having a refractive index greater than 1.78, greater than 1.8, greater than 1.85, greater than 1.9, greater than 1.93, greater than 1.95, or greater than 2. The base resin refractive index may range between 1.58 and 1.77. The nanoparticles may include titanium oxide nanoparticles. The nanoparticle weight percentage may range from 45% to 90%, 45% to 85%, 45% to 80%, or 45% to 75%. In some embodiments, the NIL material may be formulated with a combination of (A) base resin refractive index and (B) nanoparticle loading percentage, such that a decrease in the base resin refractive index corresponds to an increase in the refractive index of the cured NIL material.

The various NIL materials disclosed herein can be used to imprint or NIL mold surface-relief structures, such as slanted surface-relief gratings with large slanted angles, small critical dimensions, wide ranges of grating duty cycles, varying periods, and/or high depths at a high fabrication speed and yield. In some embodiments, the NIL-molded surface-relief structures may include slanted surface-relief gratings having a wide range of grating duty cycles (e.g., from about 0.1 to about 0.9), large slant angles (e.g., greater than 10°, 20°, 30°, 40°, 50°, 60°, 70° or larger), varying periods (e.g., 300 nm to 600 nm), and/or high depths (e.g., greater than 100 nm). The NIL materials provided herein are non-limiting and do not preclude any alternative embodiments or substitutions as will be apparent to one skilled in the art.

Near-Eye Displays for Artificial Reality Systems:

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

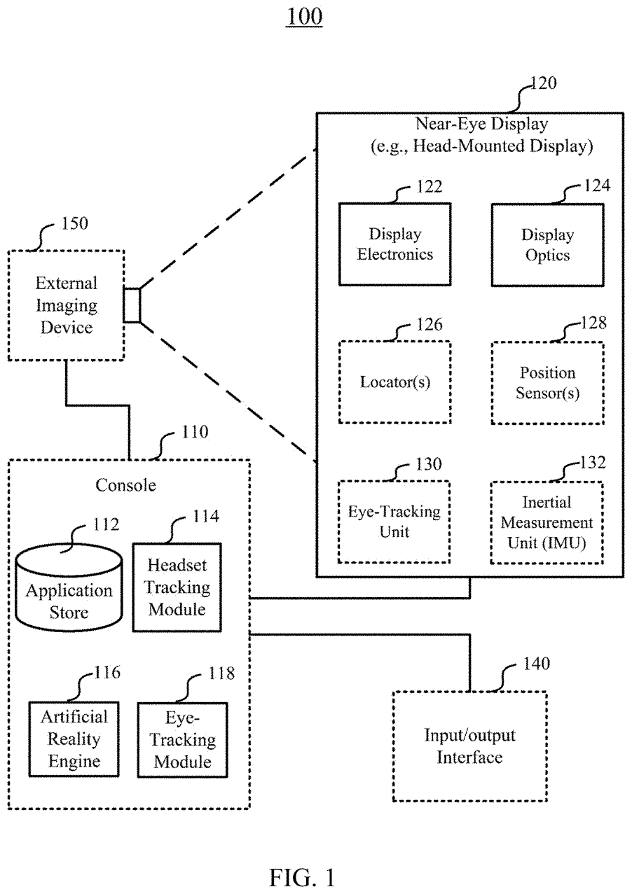

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140 that may each be coupled to an optional console 110. While FIG. 1 shows example artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

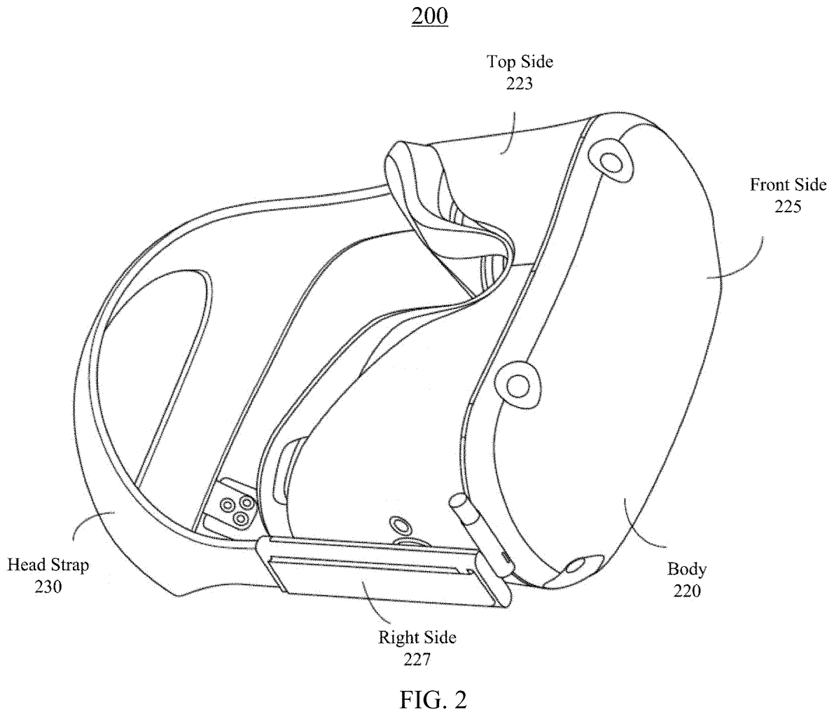

Near-eye display 120 may be a head-mounted display that presents content to a user. Examples of content presented by near-eye display 120 include one or more of images, videos, audios, or some combination thereof. In some embodiments, audios may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form factor, including a pair of glasses. Some embodiments of near-eye display 120 are further described below with respect to FIGS. 2-4. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of these elements or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (mLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or a combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, chromatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be a light emitting diode (LED), a corner cube reflector, a reflective marker, a type of light source that contrasts with an environment in which near-eye display 120 operates, or some combinations thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may generate slow calibration data based on calibration parameters received from console 110. Slow calibration data may include one or more images showing observed positions of locators 126 that are detectable by external imaging device 150. External imaging device 150 may include one or more cameras, one or more video cameras, any other device capable of capturing images including one or more of locators 126, or some combinations thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or some combinations thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or some combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or some combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or some combination thereof, to predict a future location of near-eye display 120. Headset tracking module 114 may provide the estimated or predicted future position of near-eye display 120 to artificial reality engine 116.

Headset tracking module 114 may calibrate the artificial reality system environment 100 using one or more calibration parameters, and may adjust one or more calibration parameters to reduce errors in determining the position of near-eye display 120. For example, headset tracking module 114 may adjust the focus of external imaging device 150 to obtain a more accurate position for observed locators on near-eye display 120. Moreover, calibration performed by headset tracking module 114 may also account for information received from IMU 132. Additionally, if tracking of near-eye display 120 is lost (e.g., external imaging device 150 loses line of sight of at least a threshold number of locators 126), headset tracking module 114 may re-calibrate some or all of the calibration parameters.

Artificial reality engine 116 may execute applications within artificial reality system environment 100 and receive position information of near-eye display 120, acceleration information of near-eye display 120, velocity information of near-eye display 120, predicted future positions of near-eye display 120, or some combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

In some embodiments, eye-tracking module 118 may store a mapping between images captured by eye-tracking unit 130 and eye positions to determine a reference eye position from an image captured by eye-tracking unit 130. Alternatively or additionally, eye-tracking module 118 may determine an updated eye position relative to a reference eye position by comparing an image from which the reference eye position is determined to an image from which the updated eye position is to be determined. Eye-tracking module 118 may determine eye position using measurements from different imaging devices or other sensors. For example, eye-tracking module 118 may use measurements from a slow eye-tracking system to determine a reference eye position, and then determine updated positions relative to the reference eye position from a fast eye-tracking system until a next reference eye position is determined based on measurements from the slow eye-tracking system.

Eye-tracking module 118 may also determine eye calibration parameters to improve precision and accuracy of eye tracking. Eye calibration parameters may include parameters that may change whenever a user dons or adjusts near-eye display 120. Example eye calibration parameters may include an estimated distance between a component of eye-tracking unit 130 and one or more parts of the eye, such as the eye's center, pupil, cornea boundary, or a point on the surface of the eye. Other example eye calibration parameters may be specific to a particular user and may include an estimated average eye radius, an average corneal radius, an average sclera radius, a map of features on the eye surface, and an estimated eye surface contour. In embodiments where light from the outside of near-eye display 120 may reach the eye (as in some augmented reality applications), the calibration parameters may include correction factors for intensity and color balance due to variations in light from the outside of near-eye display 120.

Eye-tracking module 118 may use eye calibration parameters to determine whether the measurements captured by eye-tracking unit 130 would allow eye-tracking module 118 to determine an accurate eye position (also referred to herein as “valid measurements”). Invalid measurements, from which eye-tracking module 118 may not be able to determine an accurate eye position, may be caused by the user blinking, adjusting the headset, or removing the headset, and/or may be caused by near-eye display 120 experiencing greater than a threshold change in illumination due to external light. In some embodiments, at least some of the functions of eye-tracking module 118 may be performed by eye-tracking unit 130.

FIG. 2 is a perspective view of an example of a near-eye display in the form of a head-mounted display (HMD) device 200 for implementing some of the examples disclosed herein. HMD device 200 may be a part of, e.g., a virtual reality (VR) system, an augmented reality (AR) system, a mixed reality (MR) system, or some combinations thereof. HMD device 200 may include a body 220 and a head strap 230. FIG. 2 shows a top side 223, a front side 225, and a right side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temples tips as shown in, for example, FIG. 2, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audios, or some combinations thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, a liquid crystal display (LCD), an organic light emitting diode (OLED) display, an inorganic light emitting diode (ILED) display, a micro light emitting diode (mLED) display, an active-matrix organic light emitting diode (AMOLED) display, a transparent organic light emitting diode (TOLED) display, some other display, or some combinations thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or some combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

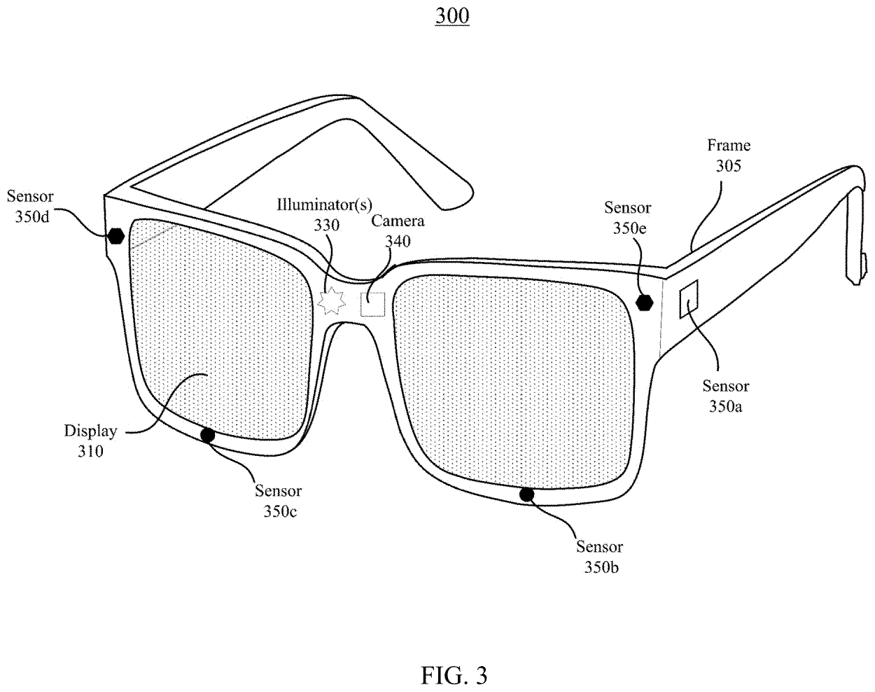

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light pattern onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

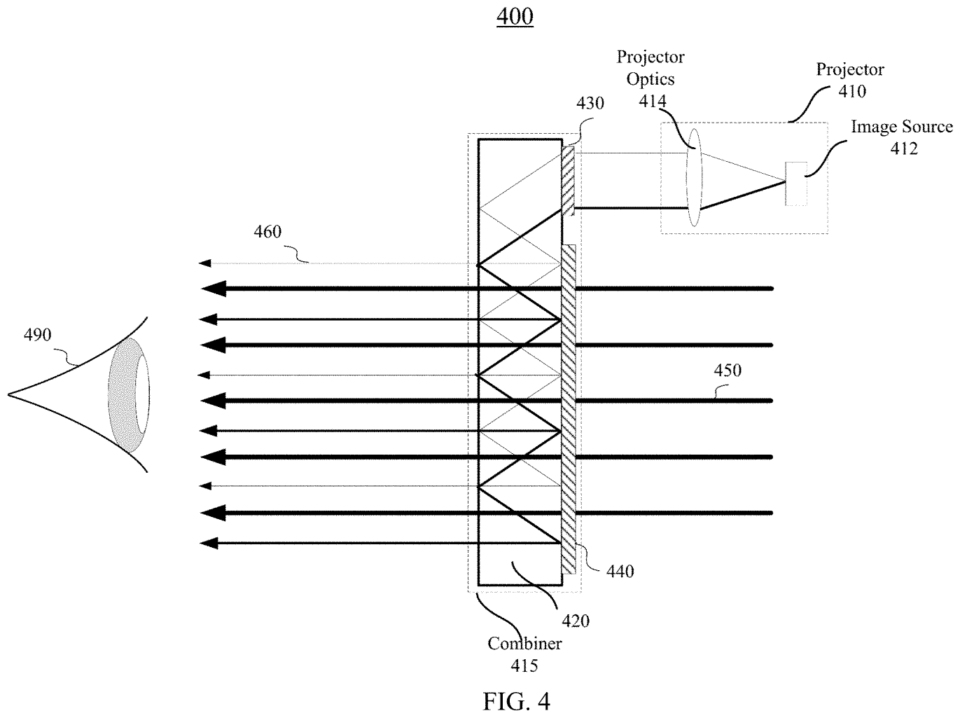

FIG. 4 illustrates an example of an optical see-through augmented reality system 400 using a waveguide display according to certain embodiments. Augmented reality system 400 may include a projector 410 and a combiner 415. Projector 410 may include a light source or image source 412 and projector optics 414. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, and/or a light emitting diode. In some embodiments, image source 412 may include a plurality of light sources each emitting a monochromatic image light corresponding to a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Input coupler 430 may include a volume holographic grating, a diffractive optical element (DOE) (e.g., a surface-relief grating), or a refractive coupler (e.g., a wedge or a prism). Input coupler 430 may have a coupling efficiency of greater than 30%, 50%, 75%, 90%, or higher for visible light. As used herein, visible light may refer to light with a wavelength between about 380 nm to about 750 nm. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of substrate 420 may range from, for example, less than about 1 mm to about 10 mm or more. Substrate 420 may be transparent to visible light. A material may be “transparent” to a light beam if the light beam can pass through the material with a high transmission rate, such as larger than 50%, 40%, 75%, 80%, 90%, 95%, or higher, where a small portion of the light beam (e.g., less than 50%, 40%, 25%, 20%, 10%, 5%, or less) may be scattered, reflected, or absorbed by the material. The transmission rate (i.e., transmissivity) may be represented by either a photopically weighted or an unweighted average transmission rate over a range of wavelengths, or the lowest transmission rate over a range of wavelengths, such as the visible wavelength range.

Substrate 420 may include or may be coupled to a plurality of output couplers 440 configured to extract at least a portion of the light guided by and propagating within substrate 420 from substrate 420, and direct extracted light 460 to an eye 490 of the user of augmented reality system 400. As input coupler 430, output couplers 440 may include grating couplers (e.g., volume holographic gratings or surface-relief gratings), other DOEs, prisms, etc. Output couplers 440 may have different coupling (e.g., diffraction) efficiencies at different locations. Substrate 420 may also allow light 450 from environment in front of combiner 415 to pass through with little or no loss. Output couplers 440 may also allow light 450 to pass through with little loss. For example, in some implementations, output couplers 440 may have a low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 to certain desired directions (i.e., diffraction angles) with little loss. As a result, the user may be able to view combined images of the environment in front of combiner 415 and virtual objects projected by projector 410.

Surface-Relief Structures:

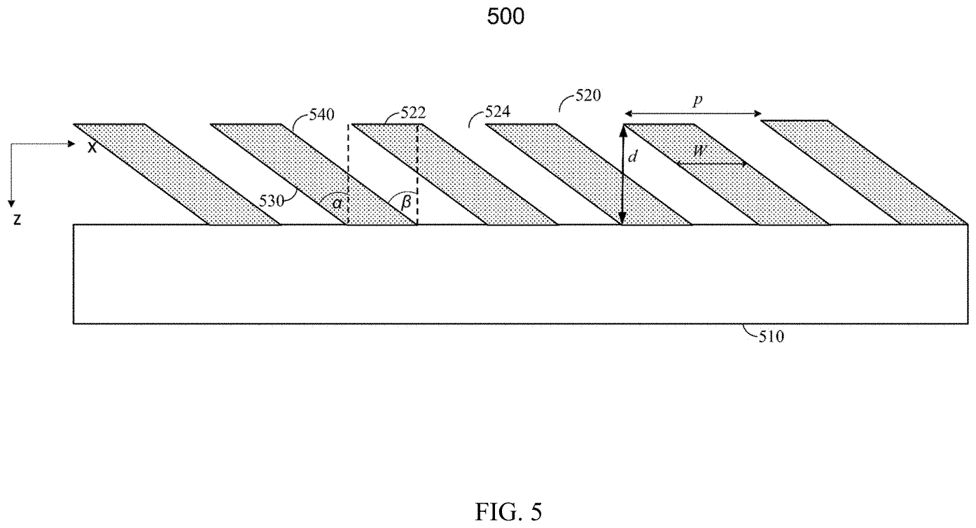

FIG. 5 illustrates an example slanted grating 520 in an example waveguide display 500 according to certain embodiments. Waveguide display 500 may include slanted grating 520 on a waveguide 510, such as substrate 420. Slanted grating 520 may act as a grating coupler for coupling light into or out of waveguide 510. In some embodiments, slanted grating 520 may include a structure with a period p. For example, slanted grating 520 may include a plurality of ridges 522 and grooves 524 between ridges 522. Ridges 522 may be made of a material with a refractive index of n_{g1}, such as silicon containing materials (e.g., SiO₂, Si₃N₄, SiC, SiOₓN_{y}, or amorphous silicon), organic materials (e.g., polymers, spin on carbon (SOC) or amorphous carbon layer (ACL) or diamond like carbon (DLC)), inorganic metal oxide layers (e.g., TiOₓ, AlOₓ, TaOₓ, HfOₓ, etc.), or a combination thereof.

Each period of slanted grating 520 may include a ridge 522 and a groove 524, which may be an air gap or a region filled with a material with a refractive index n_{g2}. In some embodiments, the period p of the slanted grating may vary from one area to another on slanted grating 520, or may vary from one period to another (i.e., chirped) on slanted grating 520. The ratio between the width W of a ridge 522 and the grating period p may be referred to as the duty cycle. Slanted grating 520 may have a duty cycle ranging, for example, from about 10% to about 90% or greater. In some embodiments, the duty cycle may vary from period to period. In some embodiments, the depth d or height of ridges 522 may be greater than 50 nm, 100 nm, 200 nm, 300 nm, or higher.

Each ridge 522 may include a leading edge 530 with a slant angle α and a trailing edge 540 with a slant angle β. Slant angle α and slant angle β may be greater than 10°, 20°, 30°, 40°, 50°, 60°, 70°, or higher. In some embodiments, leading edge 530 and training edge 540 of each ridge 522 may be parallel to each other. In other words, slant angle α is approximately equal to slant angle β. In some embodiments, slant angle α may be different from slant angle β. In some embodiments, slant angle α may be approximately equal to slant angle β. For example, the difference between slant angle α and slant angle β may be less than 20%, 10%, 5%, 1%, or less.

In some implementations, grooves 524 between ridges 522 may be over-coated or filled with a material having a refractive index n_{g2} higher or lower than the refractive index of the material of ridges 522. For example, in some embodiments, a high refractive index material, such as Hafnia, Titania, Tantalum oxide, Tungsten oxide, Zirconium oxide, Gallium sulfide, Gallium nitride, Gallium phosphide, silicon, or a high refractive index polymer, may be used to fill grooves 524. In some embodiments, a low refractive index material, such as silicon oxide, alumina, porous silica, or fluorinated low index monomer (or polymer), may be used to fill grooves 524. As a result, the difference between the refractive index of ridges 522 and the refractive index of grooves 524 may be greater than 0.1, 0.2, 0.3, 0.5, 1.0, or higher.

The slanted grating, such as slanted grating 520 shown in FIG. 5, may be fabricated using many different nanofabrication techniques. The nanofabrication techniques generally include a patterning process and a post-patterning (e.g., over-coating) process. The patterning process may be used to form slanted ridges of the slanted grating. There may be many different nanofabrication techniques for forming the slanted ridges. For example, in some implementations, the slanted grating may be fabricated using lithographic techniques including slanted etching. In some implementations, the slanted grating may be fabricated using nanoimprint lithography (NIL) molding techniques. The post-patterning process may be used to over-coat the slanted ridges and/or to fill the gaps between the slanted ridges with a material having a different refractive index than the slanted ridges. The post-patterning process may be independent from the patterning process. Thus, a same post-patterning process may be used on slanted gratings fabricated using any pattering technique.

Techniques and processes for fabricating the slanted grating described below are for illustration purposes only and are not intended to be limiting. A person skilled in the art would understand that various modifications may be made to the techniques described below. For example, in some implementations, some operations described below may be omitted. In some implementations, additional operations may be performed to fabricate the slanted grating. Techniques disclosed herein may also be used to fabricate other slanted structures on various materials.

As described above, in some implementations, the slanted grating may be fabricated using NIL molding techniques. In NIL molding, a substrate may be coated with a NIL material layer. The NIL material may include an electromagnetic radiation sensitive material or, more specifically, a light-curable optical material. For example, the NIL material may include a light-sensitive base resin that includes a base polymer and a functional group for polymerization during photo-curing (e.g., UV-curing). The NIL material mixture may also include metal oxide nanoparticles (e.g., titanium oxide, zirconium oxide, etc.) for increasing the refractive index of the mixture. The mixture may also include some optional additives and solvent. In general, the base resin material, e.g., the base polymer and the functional group of the base resin material, the nanoparticle material, and/or the loading of the nanoparticles (i.e., weight percentage of the nanoparticles in the cured NIL material) can be selected to tune the refractive index of the moldable NIL material.

A NIL mold (e.g., a hard stamp, a soft stamp including a polymeric material, a hard-soft stamp, or any other working stamp) with a slanted structure may be pressed against the NIL material layer for molding a slanted surface-relief structure in the NIL material layer. A soft stamp (e.g., made of polymers) may offer more flexibility than a hard stamp during the molding and demolding processes. The NIL material layer may be cured subsequently using, for example, heat and/or ultraviolet (UV) light. The NIL mold may then be detached from the NIL material layer, and a slanted structure that is complementary to the slanted structure in the NIL mold may be formed in the NIL material layer.

In various embodiments, different generations of NIL stamps may be made and used as the working stamp to mold the slanted gratings. For example, in some embodiments, a master mold (which may be referred to as a generation 0 mold) may be fabricated (e.g., etched) in, for example, a semiconductor substrate, a quartz, or a metal plate. The master mold may be a hard stamp and may be used as the working stamp to mold the slanted grating directly, which may be referred to as hard stamp NIL or hard NIL. In such case, the slanted structure on the mold may be complimentary to the desired slanted structure of the slanted grating used as the grating coupler on a waveguide display.

In some embodiments, in order to protect the master NIL mold, the master NIL mold may be fabricated first, and a hybrid stamp (which may be referred to as generation 1 mold or stamp) may then be fabricated using the master NIL mold. The hybrid stamp may be used as the working stamp for nanoimprinting. The hybrid stamp may include a hard stamp, a soft stamp, or a hard-soft stamp. Nanoimprinting using a soft stamp may be referred to as soft stamp NIL or soft NIL. In some embodiments, the hybrid mold may include a plastic backplane with soft or hard patterned polymer (e.g., having a Young's modulus about 1 GPa). In some embodiments, the hybrid mold may include a glass backplane with soft or hard patterned polymer (e.g., having a Young's modulus about 1 GPa). In some embodiments, the hybrid mold may include a glass/plastic laminated backplane with soft or hard patterned polymer.

In some embodiments, a generation 2 hybrid mold may be made from the generation 1 mold, and may then be used as the working stamp for the nanoimprinting. In some embodiments, generation 3 hybrid molds, generation 4 hybrid molds, and the like, may be made and used as the working stamp. NIL molding may significantly reduce the cost of making the slanted surface-relief structures because the molding process may be much shorter than the etching process and no expensive reactive ion etching equipment may be needed.

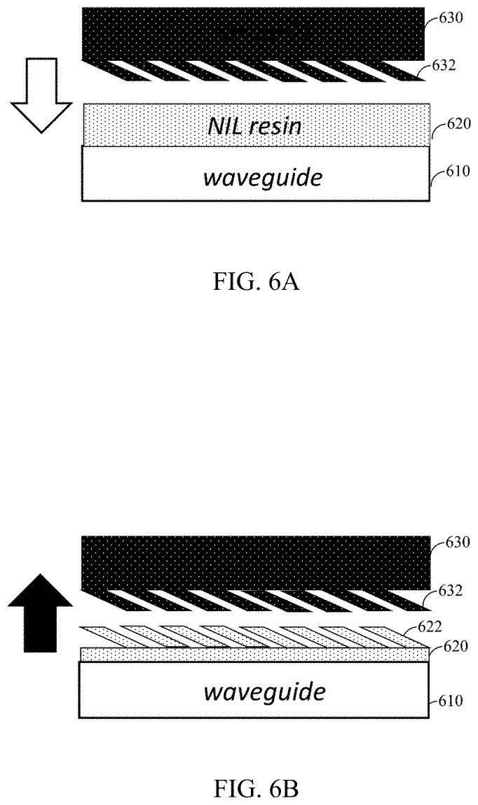

FIGS. 6A and 6B illustrate an example process for fabricating a slanted surface-relief grating by direct molding according to certain embodiments. In FIG. 6A, a waveguide 610 may be coated with a NIL material layer 620. NIL material layer 620 may be deposited on waveguide 610 by, for example, spin-coating, lamination, or ink injection. A NIL mold 630 with slanted ridges 632 may be pressed against NIL material layer 620 and waveguide 610 for molding a slanted grating in NIL material layer 620. NIL material layer 620 may be cured subsequently (e.g., crosslinked) using heat and/or ultraviolet (UV) light.

FIG. 6B shows the demolding process, during which NIL mold 630 is detached from NIL material layer 620 and waveguide 610. As shown in FIG. 6B, after NIL mold 630 is detached from NIL material layer 620 and waveguide 610, a slanted grating 622 that is complementary to slanted ridges 632 in NIL mold 630 may be formed in NIL material layer 620 on waveguide 610.

In some embodiments, a master NIL mold (e.g., a hard mold including a rigid material, such as Si, SiO₂, Si₃N₄, or a metal) may be fabricated first using, for example, slanted etching, micromachining, or 3-D printing. A soft stamp may be fabricated using the master NIL mold, and the soft stamp may then be used as the working stamp to fabricate the slanted grating. In such a process, the slanted grating structure in the master NIL mold may be similar to the slanted grating of the grating coupler for the waveguide display, and the slanted grating structure on the soft stamp may be complementary to the slanted grating structure in the master NIL mold and the slanted grating of the grating coupler for the waveguide display. Compared with a hard stamp or hard mold, a soft stamp may offer more flexibility during the molding and demolding processes.

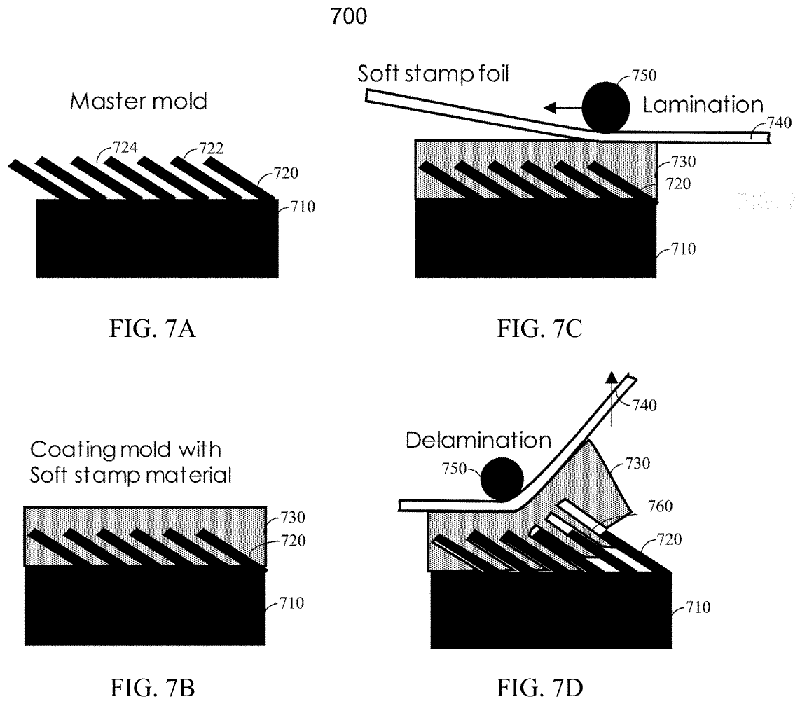

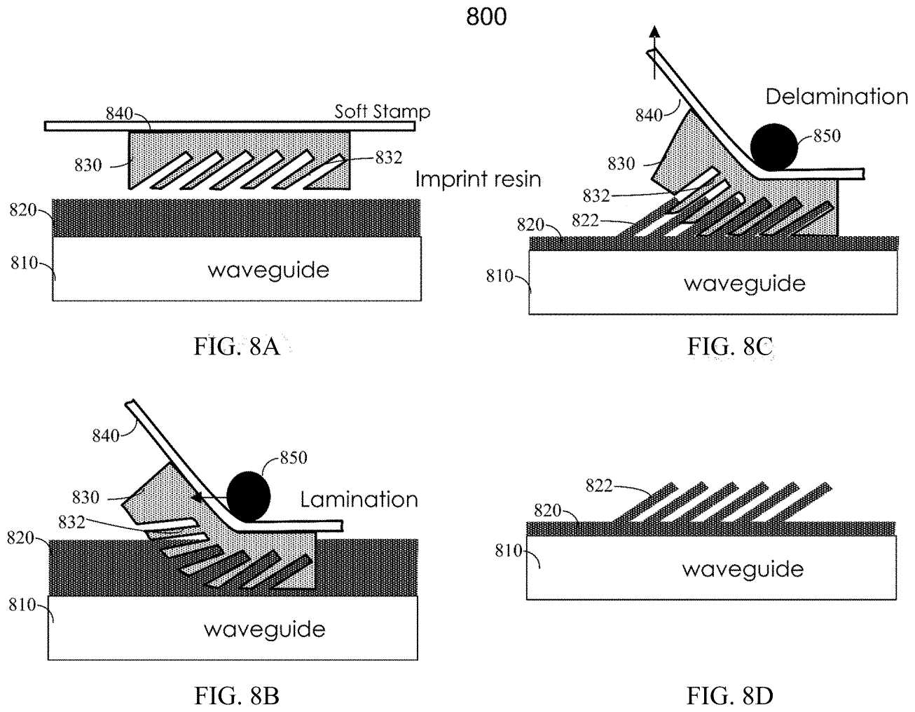

FIGS. 7A-7D illustrate an example process for fabricating a soft stamp used for making a slanted surface-relief grating according to certain embodiments. FIG. 7A shows a master mold 710 (e.g., a hard mold or hard stamp). Master mold 710 may include a rigid material, such as a semiconductor substrate (e.g., Si or GaAs), an oxide (e.g., SiO₂, Si₃N₄, TiOₓ, AlOₓ, TaOₓ, or HfOₓ), or a metal plate. Master mold 710 may be fabricated using, for example, a slanted etching process using reactive ion beams or chemically assisted reactive ion beams, a micromachining process, or a 3-D printing process. As shown in FIG. 7A, master mold 710 may include a slanted grating 720 that may in turn include a plurality of slanted ridges 722 with gaps 724 between slanted ridges 722.

FIG. 7B illustrates master mold 710 coated with a soft stamp material layer 730. Soft stamp material layer 730 may include, for example, a resin material or a curable polymer material. In some embodiments, soft stamp material layer 730 may include polydimethylsiloxane (PDMS) or another silicone elastomer or silicon-based organic polymer. In some embodiment, soft stamp material layer 730 may include ethylene tetrafluoroethylene (ETFE), perfluoropolyether (PFPE), or other fluorinated polymer materials. In some embodiments, soft stamp material layer 730 may be coated on master mold 710 by, for example, spin-coating or ink injection.

FIG. 7C illustrates a lamination process for laminating a soft stamp foil 740 onto soft stamp material layer 730. A roller 750 may be used to press soft stamp foil 740 against soft stamp material layer 730. The lamination process may also be a planarization process to make the thickness of soft stamp material layer 730 substantially uniform. After the lamination process, soft stamp foil 740 may be tightly or securely attached to soft stamp material layer 730.

FIG. 7D illustrates a delamination process, where a soft stamp including soft stamp foil 740 and attached soft stamp material layer 730 is detached from master mold 710. Soft stamp material layer 730 may include a slanted grating structure that is complementary to the slanted grating structure on master mold 710. Because the flexibility of soft stamp foil 740 and attached soft stamp material layer 730, the delamination process may be relatively easy compared with a demolding process using a hard stamp or mold. In some embodiments, a roller (e.g., roller 750) may be used in the delamination process to ensure a constant or controlled delamination speed. In some embodiments, roller 750 may not be used during the delamination. In some implementations, an anti-sticking layer may be formed on master mold 710 before soft stamp material layer 730 is coated on master mold 710. The anti-sticking layer may also facilitate the delamination process (e.g., between the slanted grating and the soft stamp 760). After the delamination of the soft stamp from master mold 710, the soft stamp may be used to mold the slanted grating on a waveguide of a waveguide display.

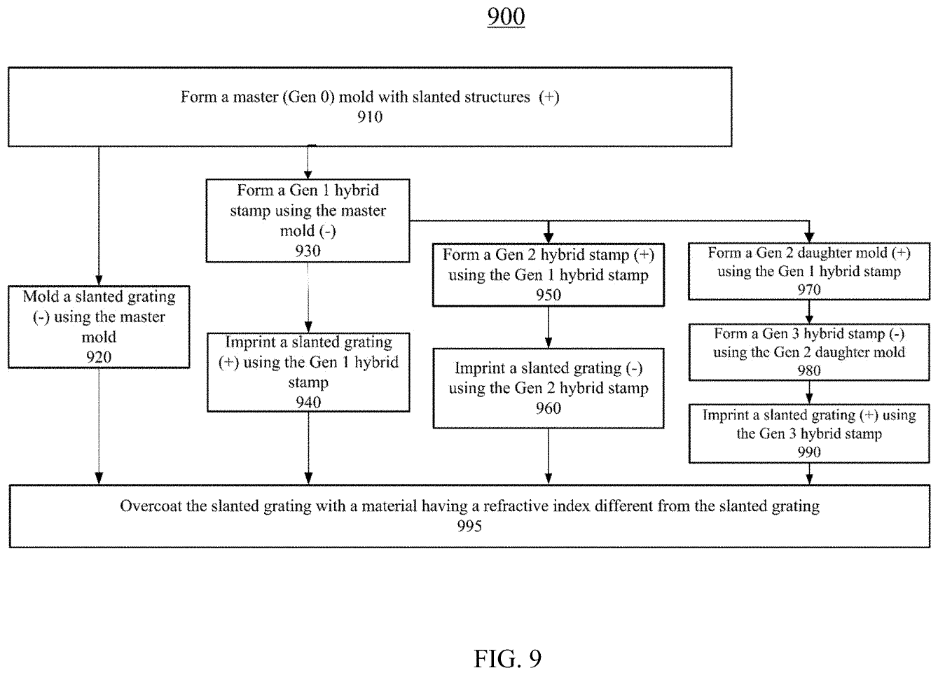

FIGS. 8A-8D illustrate an example process for fabricating a slanted surface-relief grating using a soft stamp according to certain embodiments. FIG. 8A shows a waveguide 810 coated with a NIL material layer 820. NIL material layer 820 may be deposited on waveguide 810 by, for example, spin-coating, lamination, or ink injection. A soft stamp 830 including slanted ridges 832 attached to a soft stamp foil 840 may be used for the imprint.

FIG. 8B shows the lamination of soft stamp 830 onto NIL material layer 820. Soft stamp 830 may be pressed against NIL material layer 820 and waveguide 810 using a roller 850, such that slanted ridges 832 may be pressed into NIL material layer 820. NIL material layer 820 may be cured subsequently. For example, NIL material layer 820 may be crosslinked using heat and/or ultraviolet (UV) light.

FIG. 8C shows the delamination of soft stamp 830 from NIL material layer 820. The delamination may be performed by lifting soft stamp foil 840 to detach slanted ridges 832 of soft stamp 830 from NIL material layer 820. NIL material layer 820 may now include a slanted grating 822, which may be used as the grating coupler or may be over-coated to form the grating coupler for the waveguide display. As described above, because of the flexibility of soft stamp 830, the delamination process may be relatively easy compared with a demolding process using a hard stamp or mold. In some embodiments, a roller (e.g., roller 850) may be used in the delamination process to ensure a constant or controlled delamination speed. In some embodiments, roller 850 may not be used during the delamination.

FIG. 8D shows an example imprinted slanted grating 822 formed on waveguide 810 using soft stamp 830. As described above, slanted grating 822 may include ridges and gaps between the ridges and thus may be over-coated with a material having a refractive index different from NIL material layer 820 to fill the gaps and form the grating coupler for the waveguide display.

In various embodiments, the period of the slanted grating may vary from one area to another on slanted grating 822, or may vary from one period to another (i.e., chirped) on slanted grating 822. Slanted grating 822 may have a duty cycle ranging, for example, from about 10% to about 90% or greater. In some embodiments, the duty cycle may vary from period to period. In some embodiments, the depth or height of the ridges of slanted grating 822 may be greater than 50 nm, 100 nm, 200 nm, 300 nm, or higher. The slant angles of the leading edges of the ridges of slanted grating 822 and the slant angles of the trailing edges of the ridges of slanted grating 822 may be greater than 10°, 20°, 30°, 40°, 50°, 60°, 70°, or higher. In some embodiments, the leading edge and training edge of each ridge of slanted grating 822 may be parallel to each other. In some embodiments, the difference between the slant angle of the leading edge of a ridge of slanted grating 822 and the slant angle of the trailing edge of the ridge of slanted grating 822 may be less than 20%, 10%, 5%, 1%, or less.

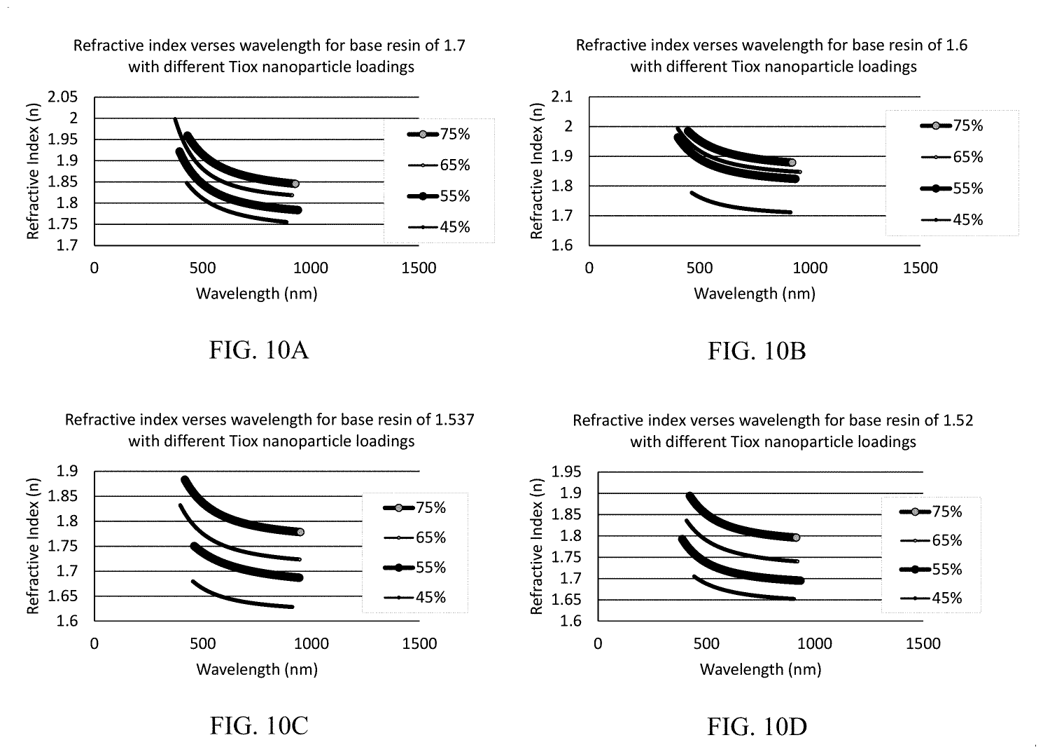

FIG. 9 is a simplified flow chart 900 illustrating example methods of fabricating a slanted surface-relief grating using nanoimprint lithography according to certain embodiments. As described above, different generations of NIL stamps may be made and used as the working stamp to mold the slanted gratings. For example, in some embodiments, a master mold (i.e., generation 0 mold, which may be a hard mold) may be used as the working stamp to mold the slanted grating directly. In some embodiments, a hybrid stamp (e.g., a generation 1 hybrid mold or stamp) may be fabricated using the master mold and may be used as the working stamp for nanoimprinting. In some embodiments, a generation 2 hybrid mold (or stamp) may be made from the generation 1 mold, and may be used as the working stamp for the nanoimprinting. In some embodiments, a generation 3 mold, a generation 4 mold, and so on, may be made and used as the working stamp.

At block 910, a master mold with a slanted structure may be fabricated using, for example, a slanted etching process that uses reactive ion beams or chemically-assisted reactive ion beams, a micromachining process, or a 3-D printing process. The master mold may be referred to as the generation 0 (or Gen 0) mold. The master mold may include quartz, fused silica, silicon, other metal-oxides, or plastic compounds. The slanted structure of the master mold may be referred to as having a positive (+) tone. The master mold may be used as a working stamp for molding the slanted grating directly (i.e., hard NIL) at block 920. As described above, when the master mold is used as the working stamp, the slanted structure of the master mold may be complementary to the desired slanted grating. Alternatively, the master mold may be used to make a hybrid stamp as the working stamp for molding the slanted grating. The slanted structure of the hybrid stamp may be similar to the desired slanted grating or may be complementary to the desired slanted grating, depending on the generation of the hybrid stamp.

At block 920, a slanted grating may be molded in, for example, a moldable layer, such as a NIL material layer, using the master mold as described above with respect to, for example, FIGS. 6A and 6B. The moldable layer may be coated on a waveguide substrate. The master mold may be pressed against the moldable layer. The moldable layer may then be cured to fix the structure formed within the moldable layer by the master mold. The master mold may be detached from the moldable layer to form a slanted grating within the moldable layer. The slanted grating within the moldable layer may have a negative (−) tone compared with the slanted structure of the master mold.

Alternatively, at block 930, a hybrid stamp (e.g., a hard stamp, a soft stamp, or a hard-soft stamp) with a slanted structure may be fabricated using the master mold as described above with respect to, for example, FIGS. 7A-7D or the process described with respect to, for example, FIGS. 8A-8D. For example, the process of fabricating the hybrid stamp may include coating the master mold with a soft stamp material, such as a resin material described above. A soft stamp foil may then be laminated on the soft stamp material, for example, using a roller. The soft stamp foil and the attached soft stamp material may be securely attached to each other and may be detached from the master mold to form the soft stamp. The hybrid stamp fabricated at block 930 may be referred to as a generation 1 (or Gen 1) stamp. The slanted grating within the Gen 1 stamp may have a negative (−) tone compared with the slanted structure of the master mold.

At block 940, a slanted surface-relief grating may be imprinted using the Gen 1 stamp as described above with respect to, for example, FIGS. 8A-8D. For example, a waveguide substrate may be coated with a NIL material layer. The Gen 1 stamp may be laminated on the NIL material layer using, for example, a roller. After the NIL material layer is cured, the Gen 1 stamp may be delaminated from the NIL material layer to form a slanted grating within the NIL material layer. The slanted grating within the NIL material layer may have a positive tone.

Alternatively, in some embodiments, at block 950, a second generation hybrid stamp (Gen 2 stamp) may be fabricated using the Gen 1 stamp using a process similar to the process for fabricating the Gen 1 stamp as described above with respect to, for example, FIGS. 7A-8D. The slanted structure within the Gen 2 stamp may have a positive tone.

At block 960, a slanted surface-relief grating may be imprinted using the Gen 2 stamp as described above with respect to, for example, FIGS. 8A-8D. For example, a waveguide substrate may be coated with a NIL material layer. The Gen 2 stamp may be laminated on the NIL material layer using, for example, a roller. After the NIL material layer is cured, the Gen 2 stamp may be delaminated from the NIL material layer to form a slanted grating within the NIL material layer. The slanted grating within the NIL material layer may have a negative tone.

Alternatively, in some embodiments, at block 970, a second generation (Gen 2) daughter mold may be fabricated using the Gen 1 stamp using a process similar to the process for fabricating the Gen 1 stamp as described above with respect to, for example, FIGS. 7A-8D. The slanted structure within the Gen 2 daughter mold may have a positive tone.

At block 980, a third generation hybrid stamp (Gen 3 stamp) may be fabricated using the Gen 2 daughter mold using a process similar to the process for fabricating the Gen 1 stamp or the Gen 2 daughter mold as described above with respect to, for example, FIGS. 7A-8D. The slanted structure within the Gen 3 stamp may have a negative tone.

At block 990, a slanted surface-relief grating may be imprinted using the Gen 3 stamp as described above with respect to, for example, FIGS. 8A-8D. For example, a waveguide substrate may be coated with a NIL material layer. The Gen 3 stamp may be laminated on the NIL material layer using, for example, a roller. After the NIL material layer is cured, the Gen 3 stamp may be delaminated from the NIL material layer to form a slanted grating within the NIL material layer. The slanted grating within the NIL material layer may have a positive tone.

Even though not shown in FIG. 9, in some embodiments, a fourth generation hybrid stamp, a fifth generation hybrid stamp, and so on, may be fabricated using a similar process, and may be used as the working stamp for imprinting the slanted grating.

Optionally, at block 995, the slanted grating may be over-coated with a material having a refractive index different from the slanted grating (e.g., the NIL material layer). For example, in some embodiments, a high refractive index material, such as Hafnia, Titania, Tungsten oxide, Zirconium oxide, Gallium sulfide, Gallium nitride, Gallium phosphide, silicon, or a high refractive index polymer, may be used to over-coat the slanted grating and fill the gaps between the slanted grating ridges. In some embodiments, a low refractive index material, such as silicon oxide, magnesium fluoride, porous silica, or fluorinated low index monomer (or polymer), and the like, may be used to over-coat the slanted grating and fill the gaps between the slanted grating ridges.

### Definitions

Unless defined otherwise, all technical and scientific terms used herein have the same meaning as is commonly understood by one of skill in the art to which this disclosure belongs. All patents and publications referred to herein are incorporated by reference in their entireties.

As used herein, the terms “crosslinkable moiety” or “polymerizable moiety” refer to a chemical group capable of participating in a crosslinking or polymerization reaction, at any level, for example, initiation, propagation, etc. Crosslinkable or polymerizable moieties include, but are not limited to, addition crosslinkable or polymerizable moieties and condensation crosslinkable or polymerizable moieties. Crosslinkable or polymerizable moieties include, but are not limited to, double bonds, triple bonds, and the like.

As used herein, the term “inhibitor” refers to one or more compositions, compounds, molecules, etc., that are capable of inhibiting or substantially inhibiting the polymerization of the polymerizable component when the photoinitiating light source is on or off. Polymerization inhibitors typically react very quickly with radicals and effectively stop a polymerization reaction. Inhibitors cause an inhibition time during which little to no photopolymer forms, e.g., only very small chains. Typically, photopolymerization occurs only after nearly 100% of the inhibitor is reacted.

As used herein, the term “oligomer” refers to a polymer having a limited number of repeating units, for example, but without limitation, approximately 30 repeat units or less, or any large molecule able to diffuse at least about 100 nm in approximately 2 minutes at room temperature when dissolved in an article of the present disclosure. Such oligomers may contain one or more crosslinkable or polymerizable groups whereby the crosslinkable or polymerizable groups may be the same or different from other possible monomers in the crosslinkable or polymerizable component. Furthermore, when more than one crosslinkable or polymerizable group is present on the oligomer, they may be the same or different. Additionally, oligomers may be dendritic. Oligomers are considered herein to be photoactive monomers, although they are sometimes referred to as “photoactive oligomer(s)”.

As used herein, the terms “photo acid generators,” “photo base generators,” and “photo radical generators,” refer to one or more compositions, compounds, molecules, etc., that, when exposed to a light source, generate one or more compositions, compounds, molecules, etc., that are acidic, basic, or a free radical.

As used herein, the term “about” means that dimensions, sizes, formulations, parameters, shapes and other quantities and characteristics are not and need not be exact, but may be approximate and/or larger or smaller, as desired, reflecting tolerances, conversion factors, rounding off, measurement error and the like, and other factors known to those of skill in the art. In general, a dimension, size, formulation, parameter, shape or other quantity or characteristic is “about” or “approximate” whether or not expressly stated to be such. It is noted that embodiments of very different sizes, shapes and dimensions may employ the described arrangements.

Unless otherwise stated, the chemical structures depicted herein are intended to include compounds which differ only in the presence of one or more isotopically enriched atoms. For example, compounds where one or more hydrogen atoms is replaced by deuterium or tritium, or where one or more carbon atoms is replaced by ¹³C- or ¹⁴C-enriched carbons, are within the scope of this disclosure.

“Alkyl” refers to a straight or branched hydrocarbon chain radical consisting solely of carbon and hydrogen atoms, containing no unsaturation, having from one to ten carbon atoms (e.g., (C₁₋₁₀)alkyl or C₁₋₁₀ alkyl). Whenever it appears herein, a numerical range such as “1 to 10” refers to each integer in the given range—e.g., “1 to 10 carbon atoms” means that the alkyl group may consist of 1 carbon atom, 2 carbon atoms, 3 carbon atoms, etc., up to and including 10 carbon atoms, although the definition is also intended to cover the occurrence of the term “alkyl” where no numerical range is specifically designated. Typical alkyl groups include, but are in no way limited to, methyl, ethyl, propyl, isopropyl, n-butyl, isobutyl, sec-butyl isobutyl, tertiary butyl, pentyl, isopentyl, neopentyl, hexyl, septyl, octyl, nonyl and decyl. The alkyl moiety may be attached to the rest of the molecule by a single bond, such as for example, methyl (Me), ethyl (Et), n-propyl (Pr), 1-methylethyl (isopropyl), n-butyl, n-pentyl, 1,1-dimethylethyl (t-butyl) and 3-methylhexyl. Unless stated otherwise specifically in the specification, an alkyl group is optionally substituted by one or more of substituents which are independently heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂ where each R^{a} is independently hydrogen, fluoroalkyl, carbocyclyl, carbocyclylalkyl, aryl, aralkyl, heterocycloalkyl, heterocycloalkylalkyl, heteroaryl or heteroarylalkyl.

“Alkenyl” refers to a straight or branched hydrocarbon chain radical group consisting solely of carbon and hydrogen atoms, containing at least one double bond, and having from two to ten carbon atoms (i.e., (C₂₋₁₀)alkenyl or C₂₋₁₀ alkenyl). Whenever it appears herein, a numerical range such as “2 to 10” refers to each integer in the given range—e.g., “2 to 10 carbon atoms” means that the alkenyl group may consist of 2 carbon atoms, 3 carbon atoms, etc., up to and including 10 carbon atoms. The alkenyl moiety may be attached to the rest of the molecule by a single bond, such as for example, ethenyl (i.e., vinyl), prop-1-enyl (i.e., allyl), but-1-enyl, pent-1-enyl and penta-1,4-dienyl. Unless stated otherwise specifically in the specification, an alkenyl group is optionally substituted by one or more substituents which are independently alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Alkynyl” refers to a straight or branched hydrocarbon chain radical group consisting solely of carbon and hydrogen atoms, containing at least one triple bond, having from two to ten carbon atoms (i.e., (C₂₋₁₀)alkynyl or C₂₋₁₀ alkynyl). Whenever it appears herein, a numerical range such as “2 to 10” refers to each integer in the given range—e.g., “2 to 10 carbon atoms” means that the alkynyl group may consist of 2 carbon atoms, 3 carbon atoms, etc., up to and including 10 carbon atoms. The alkynyl may be attached to the rest of the molecule by a single bond, for example, ethynyl, propynyl, butynyl, pentynyl and hexynyl. Unless stated otherwise specifically in the specification, an alkynyl group is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Carboxaldehyde” refers to a —(C═O)H radical.

“Carboxyl” refers to a —(C═O)OH radical.

“Cyano” refers to a —CN radical.

“Cycloalkyl” refers to a monocyclic or polycyclic radical that contains only carbon and hydrogen, and may be saturated, or partially unsaturated. Cycloalkyl groups include groups having from 3 to 10 ring atoms (i.e. (C₃₋₁₀)cycloalkyl or C₃₋₁₀ cycloalkyl). Whenever it appears herein, a numerical range such as “3 to 10” refers to each integer in the given range—e.g., “3 to 10 carbon atoms” means that the cycloalkyl group may consist of 3 carbon atoms, etc., up to and including 10 carbon atoms. Illustrative examples of cycloalkyl groups include, but are not limited to the following moieties: cyclopropyl, cyclobutyl, cyclopentyl, cyclopentenyl, cyclohexyl, cyclohexenyl, cycloheptyl, cyclooctyl, cyclononyl, cyclodecyl, norbornyl, and the like. Unless stated otherwise specifically in the specification, a cycloalkyl group is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

The term “alkoxy” refers to the group —O-alkyl, including from 1 to 8 carbon atoms of a straight, branched, cyclic configuration and combinations thereof attached to the parent structure through an oxygen. Examples include, but are not limited to, methoxy, ethoxy, propoxy, isopropoxy, cyclopropyloxy and cyclohexyloxy. “Lower alkoxy” refers to alkoxy groups containing one to six carbons.

The term “substituted alkoxy” refers to alkoxy wherein the alkyl constituent is substituted (i.e —O-(substituted alkyl)). Unless stated otherwise specifically in the specification, the alkyl moiety of an alkoxy group is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, —N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Amino” or “amine” refers to a —N(R^{a})₂ radical group, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl, unless stated otherwise specifically in the specification. When a —N(R^{a})₂ group has two R^{a} substituents other than hydrogen, they can be combined with the nitrogen atom to form a 4-, 5-, 6- or 7-membered ring. For example, —N(R^{a})₂ is intended to include, but is not limited to, 1-pyrrolidinyl and 4-morpholinyl. Unless stated otherwise specifically in the specification, an amino group is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Aromatic” or “aryl” or “Ar” refers to an aromatic radical with six to ten ring atoms (e.g., C₆-C₁₀ aromatic or C₆-C₁₀ aryl) which has at least one ring having a conjugated pi electron system which is carbocyclic (e.g., phenyl, fluorenyl, and naphthyl). Bivalent radicals formed from substituted benzene derivatives and having the free valences at ring atoms are named as substituted phenylene radicals. Bivalent radicals derived from univalent polycyclic hydrocarbon radicals whose names end in “-yl” by removal of one hydrogen atom from the carbon atom with the free valence are named by adding “-idene” to the name of the corresponding univalent radical, e.g., a naphthyl group with two points of attachment is termed naphthylidene. Whenever it appears herein, a numerical range such as “6 to 10” refers to each integer in the given range; e.g., “6 to 10 ring atoms” means that the aryl group may consist of 6 ring atoms, 7 ring atoms, etc., up to and including 10 ring atoms. The term includes monocyclic or fused-ring polycyclic (i.e., rings which share adjacent pairs of ring atoms) groups. Unless stated otherwise specifically in the specification, an aryl moiety is optionally substituted by one or more substituents which are independently alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Aralkyl” or “arylalkyl” refers to an (aryl)alkyl-radical where aryl and alkyl are as disclosed herein and which are optionally substituted by one or more of the substituents described as suitable substituents for aryl and alkyl respectively.

“Ester” refers to a chemical radical of formula —COOR, where R is selected from the group consisting of alkyl, cycloalkyl, aryl, heteroaryl (bonded through a ring carbon) and heteroalicyclic (bonded through a ring carbon). The procedures and specific groups to make esters are known to those of skill in the art and can readily be found in seminal sources such as Greene and Wuts, Protective Groups in Organic Synthesis, 3^{rd} Ed., John Wiley & Sons, New York, N.Y., 1999, which is incorporated herein by reference in its entirety. Unless stated otherwise specifically in the specification, an ester group is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Halo,” “halide,” or, alternatively, “halogen” is intended to mean fluoro, chloro, bromo or iodo. The terms “haloalkyl,” “haloalkenyl,” “haloalkynyl,” and “haloalkoxy” include alkyl, alkenyl, alkynyl and alkoxy structures that are substituted with one or more halo groups or with combinations thereof. For example, the terms “fluoroalkyl” and “fluoroalkoxy” include haloalkyl and haloalkoxy groups, respectively, in which the halo is fluorine.

“Heteroalkyl,” “heteroalkenyl,” and “heteroalkynyl” refer to optionally substituted alkyl, alkenyl and alkynyl radicals and which have one or more skeletal chain atoms selected from an atom other than carbon, e.g., oxygen, nitrogen, sulfur, phosphorus or combinations thereof. A numerical range may be given—e.g., C₁-C₄ heteroalkyl which refers to the chain length in total, which in this example is 4 atoms long. A heteroalkyl group may be substituted with one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, nitro, oxo, thioxo, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Heteroaryl” or “heteroaromatic” or “HetAr” or “Het” refers to a 5- to 18-membered aromatic radical (e.g., C₅-C₁₃ heteroaryl) that includes one or more ring heteroatoms selected from nitrogen, oxygen and sulfur, and which may be a monocyclic, bicyclic, tricyclic or tetracyclic ring system. Whenever it appears herein, a numerical range such as “5 to 18” refers to each integer in the given range—e.g., “5 to 18 ring atoms” means that the heteroaryl group may consist of 5 ring atoms, 6 ring atoms, etc., up to and including 18 ring atoms. Bivalent radicals derived from univalent heteroaryl radicals whose names end in “-yl” by removal of one hydrogen atom from the atom with the free valence are named by adding “-idene” to the name of the corresponding univalent radical—e.g., a pyridyl group with two points of attachment is a pyridylidene. A N-containing “heteroaromatic” or “heteroaryl” moiety refers to an aromatic group in which at least one of the skeletal atoms of the ring is a nitrogen atom. The polycyclic heteroaryl group may be fused or non-fused. The heteroatom(s) in the heteroaryl radical are optionally oxidized. One or more nitrogen atoms, if present, are optionally quaternized. The heteroaryl may be attached to the rest of the molecule through any atom of the ring(s). Examples of heteroaryls include, but are not limited to, azepinyl, acridinyl, benzimidazolyl, benzindolyl, 1,3-benzodioxolyl, benzofuranyl, benzooxazolyl, benzo[d]thiazolyl, benzothiadiazolyl, benzo[b][1,4]dioxepinyl, benzo[b][1,4]oxazinyl, 1,4-benzodioxanyl, benzonaphthofuranyl, benzoxazolyl, benzodioxolyl, benzodioxinyl, benzoxazolyl, benzopyranyl, benzopyranonyl, benzofuranyl, benzofuranonyl, benzofurazanyl, benzothiazolyl, benzothienyl(benzothiophenyl), benzothieno[3,2-d]pyrimidinyl, benzotriazolyl, benzo[4,6]imidazo[1,2-a]pyridinyl, carbazolyl, cinnolinyl, cyclopenta[d]pyrimidinyl, 6,7-dihydro-5H-cyclopenta[4,5]thieno[2,3-d]pyrimidinyl, 5,6-dihydrobenzo[h]quinazolinyl, 5,6-dihydrobenzo[h]cinnolinyl, 6,7-dihydro-5H-benzo[6,7]cyclohepta[1,2-c]pyridazinyl, dibenzofuranyl, dibenzothiophenyl, furanyl, furazanyl, furanonyl, furo[3,2-c]pyridinyl, 5,6,7,8,9,10-hexahydrocycloocta[d]pyrimidinyl, 5,6,7,8,9,10-hexahydrocycloocta[d]pyridazinyl, 5,6,7,8,9,10-hexahydrocycloocta[d]pyridinyl, isothiazolyl, imidazolyl, indazolyl, indolyl, indazolyl, isoindolyl, indolinyl, isoindolinyl, isoquinolyl, indolizinyl, isoxazolyl, 5,8-methano-5,6,7,8-tetrahydroquinazolinyl, naphthyridinyl, 1,6-naphthyridinonyl, oxadiazolyl, 2-oxoazepinyl, oxazolyl, oxiranyl, 5,6,6a,7,8,9,10,10a-octahydrobenzo[h]quinazolinyl, 1-phenyl-1H-pyrrolyl, phenazinyl, phenothiazinyl, phenoxazinyl, phthalazinyl, pteridinyl, purinyl, pyranyl, pyrrolyl, pyrazolyl, pyrazolo[3,4-d]pyrimidinyl, pyridinyl, pyrido[3,2-d]pyrimidinyl, pyrido[3,4-d]pyrimidinyl, pyrazinyl, pyrimidinyl, pyridazinyl, pyrrolyl, quinazolinyl, quinoxalinyl, quinolinyl, isoquinolinyl, tetrahydroquinolinyl, 5,6,7,8-tetrahydroquinazolinyl, 5,6,7,8-tetrahydrobenzo[4,5]thieno[2,3-d]pyrimidinyl, 6,7,8,9-tetrahydro-5H-cyclohepta[4,5]thieno[2,3-d]pyrimidinyl, 5,6,7,8-tetrahydropyrido[4,5-c]pyridazinyl, thiazolyl, thiadiazolyl, thiapyranyl, triazolyl, tetrazolyl, triazinyl, thieno[2,3-d]pyrimidinyl, thieno[3,2-d]pyrimidinyl, thieno[2,3-c]pyridinyl, and thiophenyl (i.e., thienyl). Unless stated otherwise specifically in the specification, a heteroaryl moiety is optionally substituted by one or more substituents which are independently: alkyl, heteroalkyl, alkenyl, alkynyl, cycloalkyl, heterocycloalkyl, aryl, arylalkyl, heteroaryl, heteroarylalkyl, hydroxy, halo, cyano, nitro, oxo, thioxo, trimethylsilanyl, —OR^{a}, —SR^{a}, —OC(O)R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

Substituted heteroaryl also includes ring systems substituted with one or more oxide (—O—) substituents, such as, for example, pyridinyl N-oxides.

“Heteroarylalkyl” refers to a moiety having an aryl moiety, as described herein, connected to an alkylene moiety, as described herein, wherein the connection to the remainder of the molecule is through the alkylene group.

“Heterocycloalkyl” refers to a stable 3- to 18-membered non-aromatic ring radical that comprises two to twelve carbon atoms and from one to six heteroatoms selected from nitrogen, oxygen and sulfur. Whenever it appears herein, a numerical range such as “3 to 18” refers to each integer in the given range—e.g., “3 to 18 ring atoms” means that the heterocycloalkyl group may consist of 3 ring atoms, 4 ring atoms, etc., up to and including 18 ring atoms. Unless stated otherwise specifically in the specification, the heterocycloalkyl radical is a monocyclic, bicyclic, tricyclic or tetracyclic ring system, which may include fused or bridged ring systems. The heteroatoms in the heterocycloalkyl radical may be optionally oxidized. One or more nitrogen atoms, if present, are optionally quaternized. The heterocycloalkyl radical is partially or fully saturated. The heterocycloalkyl may be attached to the rest of the molecule through any atom of the ring(s). Examples of such heterocycloalkyl radicals include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, quinuclidinyl, thiazolidinyl, tetrahydrofuryl, trithianyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocycloalkyl moiety is optionally substituted by one or more substituents which independently are: alkyl, heteroalkyl, alkenyl, alkynyl, cycloalkyl, heterocycloalkyl, aryl, arylalkyl, heteroaryl, heteroarylalkyl, hydroxy, halo, cyano, nitro, oxo, thioxo, trimethylsilanyl, —OR^{a}, —SR^{a}, —OC(O)—R^{a}, —SC(O)—R^{a}, —N(R^{a})₂, —C(O)R^{a}, —C(O)OR^{a}, —C(O)SR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O)ₜR^{a} (where t is 1 or 2), —S(O)ₜR^{a} (where t is 1 or 2), —S(O)ₜOR^{a} (where t is 1 or 2), —S(O)ₜN(R^{a})₂ (where t is 1 or 2), or PO₃(R^{a})₂, where each R^{a} is independently hydrogen, alkyl, fluoroalkyl, carbocyclyl, carbocyclylalkyl, aryl, aralkyl, heterocycloalkyl, heterocycloalkylalkyl, heteroaryl or heteroarylalkyl.

“Heterocycloalkyl” also includes bicyclic ring systems wherein one non-aromatic ring, usually with 3 to 7 ring atoms, contains at least 2 carbon atoms in addition to 1-3 heteroatoms independently selected from oxygen, sulfur, and nitrogen, as well as combinations comprising at least one of the foregoing heteroatoms; and the other ring, usually with 3 to 7 ring atoms, optionally contains 1-3 heteroatoms independently selected from oxygen, sulfur, and nitrogen and is not aromatic.

“Nitro” refers to the —NO₂ radical.

“Oxa” refers to the —O— radical.

“Oxo” refers to the ═O radical.

“Moiety” refers to a specific segment or functional group of a molecule. Chemical moieties are often recognized chemical entities embedded in or appended to a molecule.

“Substituted” means that the referenced group may have attached one or more additional groups, radicals or moieties individually and independently selected from, for example, acyl, alkyl, alkylaryl, cycloalkyl, aralkyl, aryl, carbohydrate, carbonate, heteroaryl, heterocycloalkyl, hydroxy, alkoxy, aryloxy, mercapto, alkylthio, arylthio, cyano, halo, carbonyl, ester, thiocarbonyl, isocyanato, thiocyanato, isothiocyanato, nitro, oxo, perhaloalkyl, perfluoroalkyl, phosphate, silyl, sulfinyl, sulfonyl, sulfonamidyl, sulfoxyl, sulfonate, urea, and amino, including mono- and di-substituted amino groups, and protected derivatives thereof. The substituents themselves may be substituted, for example, a cycloalkyl substituent may itself have a halide substituent at one or more of its ring carbons. The term “optionally substituted” means optional substitution with the specified groups, radicals or moieties.

“Sulfanyl” refers to groups that include —S-(optionally substituted alkyl), —S-(optionally substituted aryl), —S-(optionally substituted heteroaryl) and —S-(optionally substituted heterocycloalkyl).

Compounds of the present disclosure also include crystalline and amorphous forms of those compounds, including, for example, polymorphs, pseudopolymorphs, solvates, hydrates, unsolvated polymorphs (including anhydrates), conformational polymorphs, and amorphous forms of the compounds, as well as mixtures thereof. “Crystalline form” and “polymorph” are intended to include all crystalline and amorphous forms of the compound, including, for example, polymorphs, pseudopolymorphs, solvates, hydrates, unsolvated polymorphs (including anhydrates), conformational polymorphs, and amorphous forms, as well as mixtures thereof, unless a particular crystalline or amorphous form is referred to.

### Specific Embodiments of the Disclosure

Next-generation artificial reality (e.g., augmented reality (AR), virtual reality (VR), or mixed reality (MR)) devices require a large field-of-view and high see-through quality. One way to achieve such performance is to use nanoimprinting lithography (NIL) to fabricate surface-relief gratings with a high refractive index.

As discussed above, it can be challenging to obtain curable formulation that is stable, yields high refractive index in the NIL-molded grating, and that is also suitable for NIL molding. Provided below are various embodiments of curable NIL materials and formulations (e.g., comprising value ranges for refractive index and/or viscosity, among other parameters) that address these challenges (e.g., providing high refractive index in the cured NIL material for making NIL-molded gratings and waveguides).

According to some embodiments, an NIL material may be provided for molding a slanted grating having a refractive index between about 1.7 and about 3.4. The NIL material or NIL material mixture may include a base resin, nanoparticles, and radical or acid generator. Optionally, the NIL material may further include additives for modifying the properties of the NIL material and solvent for facilitating the mixing of the various components. The NIL material may be applied or deposited by, for example, spin-coating, lamination, or ink injection on a substrate or waveguide to form an NIL material layer. The NIL material layer may then be molded using any of the NIL processes described herein and cured by light to form an NIL-molded nanostructure, such as a slanted surface-relief grating.

The present disclosure provides a nanoimprint lithography (NIL) precursor material comprising a base resin component having a first refractive index ranging from 1.45 to 1.80, and a nanoparticles component having a second refractive index greater than the first refractive index of the base resin component. In some embodiments, the base resin component has a refractive index between about 1.5 and about 1.8. In some embodiments, the base resin component has a refractive index between about 1.55 and about 1.8 or between about 1.6 and about 1.8.

(a) Base Resin Component

In some embodiments, the base resin component comprises one or more resins. In some embodiments, the base resin component comprises an electromagnetic radiation sensitive material. In some embodiments, the base resin component is light-sensitive. For example, in some embodiments, a light-sensitive material comprises a photoinitiator and/or a photoactive polymerizable material (e.g., a monomer, polymer, and/or a combination thereof). The photoinitiator causes light-initiated crosslinking or polymerization of the photoactive polymerizable material (e.g., light-initiated curing) upon exposure to a wavelength of light that activates the photoinitiator (e.g., a photoinitiating light source). In some embodiments, the light-sensitive material comprises a combination of components, some of which individually are not light-sensitive, yet in combination are capable of activating the photoactive monomer or polymer (e.g., a dye/amine, a sensitizer/iodonium salt, a dye/borate salt, etc.). In some embodiments, a light-sensitive material comprises a single photoinitiator or a combination of two or more photoinitiators. For example, in some embodiments, two or more photoinitiators are used to allow light-initiated crosslinking or polymerization of the photoactive monomer or polymer upon exposure to two or more different wavelengths of light. In some embodiments, a light-sensitive material comprises a photoactive polymerizable material that comprises one or more functional groups that undergo curing. In some embodiments, a light-sensitive material comprises one or more photoactive polymerizable materials that are also photoinitiators (e.g., N-methylmaleimide, derivatized acetophenones, etc.).

In some embodiments, the light-sensitive base resin component undergoes a process upon exposure to one or more wavelengths of light that changes one or more properties of the base resin component. In some embodiments, the light-sensitive base resin component undergoes a crosslinking and/or polymerizing process that hardens the base resin component upon exposure to one or more wavelengths of light (e.g., curing). For example, referring to FIG. 8B, in some embodiments, curing is used to set a soft material into a rigid material, such as in a desired shape (e.g., in the shape of a mold). In some embodiments, the photoinitiating light source is a wavelength of light that is in the visible light spectrum. In some embodiments, the photoinitiating light source is a wavelength of light that is ultraviolet light (UV). In some embodiments, the base resin component is chemically curable, heat curable, electron beam curable, and/or light curable. In some embodiments, the base resin component is UV curable.

In some embodiments, the base resin component is cured for a duration that is between 1 second and 10 seconds, between 10 seconds and 30 seconds, between 30 seconds and 1 minute, between 1 minute and 2 minutes, between 2 minutes and 5 minutes, between 5 minutes and 10 minutes, between 10 minutes and 30 minutes, between 30 minutes and 1 hour, or more than 1 hour. In some embodiments, the base resin component is cured for about 10 seconds, about 20 seconds, about 30 seconds, about 40 seconds, about 50 seconds, or about 1 minute.

In some embodiments, the curing is performed at room temperature (e.g., between 15 and 25° C.). For example, in some embodiments, the NIL precursor material and/or the base resin component is flowable or in liquid form (e.g., a liquid) at room temperature, thus allowing the NIL precursor material to be molded or imprinted at an imprinting temperature close to room temperature. In other words, in some such embodiments, the NIL precursor can be molded or imprinted without heat treatment to the NIL precursor material and/or to the substrate upon which the NIL precursor material is applied. In some alternative embodiments, heat is applied to the NIL precursor material and/or to the substrate during other aspects of the NIL molding process, including the curing (e.g., crosslinking or polymerization) of the NIL precursor material. In some embodiments, the curing comprises a temperature between 25 and 40° C., between 40 and 80° C., between 80 and 120° C., between 120 and 200° C., or higher than 200° C. In some embodiments, the curing comprises a temperature between 100° C. and 150° C., between 100° C. and 140° C., or between 110° C. and 140° C. Additionally, in some embodiments, thermal treatment is implemented during the imprinting of the NIL precursor material so as to further reduce the viscosity of the NIL precursor material to facilitate the flow of the NIL precursor material inside the mold.

In some embodiments, the first refractive index of the NIL precursor material (e.g., the refractive index of the base resin component) ranges from 1.4 to 1.8, from 1.45 to 1.7, and/or from 1.5 to 1.7. In some embodiments, the first refractive index ranges from 1.52 to 1.73, from 1.52 to 1.71, from 1.52 to 1.70, from 1.55 to 1.77, from 1.58 to 1.77, from 1.55 to 1.73, from 1.50 to 1.73, from 1.58 to 1.73, from 1.60 to 1.77, and/or from 1.60 to 1.73. In some embodiments, the first refractive index ranges from 1.50 to 1.80, from 1.55 to 1.80, from 1.57 to 1.80, from 1.58 to 1.77, from 1.58 to 1.70, or from 1.60 to 1.70. In some embodiments, the first refractive index is selected from about 1.50, about 1.51, about 1.52, about 1.53, about 1.54, about 1.55, about 1.56, about 1.57, about 1.58, about 1.59, about 1.60, about 1.61, about 1.62, about 1.63, about 1.64, about 1.65, about 1.66, about 1.67, about 1.68, about 1.69, about 1.70, about 1.71, about 1.72, about 1.73, about 1.74, about 1.75, about 1.76, and about 1.77.

In some embodiments, the first refractive index (e.g., the refractive index of the base resin component) is further affected by the functional groups of the base resin. For example, in some embodiments, different base resin materials comprising a common base material but different functional groups can have different refractive indices. In some embodiments, a base resin component comprises one or more functional groups, including but not limited to crosslinking or polymerizing functional groups, such as those described in more detail below.

In some embodiments, the first refractive index is measured at 589 nm. In some embodiments, the first refractive index is measured at a wavelength in the visible light spectrum (e.g., between about 380 nm to 750 nm). In some embodiments, the first refractive index is measured at about 380 nm, about 390 nm, about 400 nm, about 410 nm, about 420 nm, about 430 nm, about 440 nm, about 450 nm, about 460 nm, about 470 nm, about 480 nm, about 490 nm, about 500 nm, about 510 nm, about 520 nm, about 530 nm, about 540 nm, about 550 nm, about 560 nm, about 570 nm, about 580 nm, about 590 nm, about 600 nm, about 610 nm, about 620 nm, about 630 nm, about 640 nm, about 650 nm, about 660 nm, about 670 nm, about 680 nm, about 690 nm, about 700 nm, about 710 nm, about 720 nm, about 730 nm, about 740 nm, or about 750 nm. In some embodiments, the first refractive index is measured at a wavelength in the infrared (IR) band (e.g., about 750 nm to 1 mm), in the ultraviolet (UV) band (e.g., about 10 nm to about 380 nm), in another portion of the electromagnetic spectrum, and/or in any combination of portions of the electromagnetic spectrum.

In some embodiments, the refractive index of the NIL precursor material and/or the NIL-molded grating are determined at least partly based on the refractive index of the base resin component. In some embodiments, the refractive index of the NIL precursor material and/or the NIL-molded grating are determined at least partly based on a parameter of the base resin component other than the refractive index of the base resin component, such as the viscosity of the base resin component and/or the one or more component resins.

In some embodiments, the base resin component has a viscosity ranging from 0.5 cps to 400 cps. In some embodiments, the viscosity value refers to the base resin component that can be crosslinked and/or polymerized, rather than to an alternate mixture comprising a base resin component and one or more solvents, nanoparticles component, and/or optional additives (e.g. a dilution of the base resin component), where the alternate mixture does not polymerize well or does not polymerize at all. As described above, in some embodiments, the viscosity indicates the elasticity or liquidity of the NIL precursor material and/or the base resin component at the imprinting temperature (e.g., at room temperature). Specifically, in some embodiments, the viscosity of the various NIL precursor material and/or the base resin component described herein is sufficiently low so as to allow for the various NIL precursor material to flow to conform to the shape of the mold during the NIL molding process. Further, in some embodiments, the shrinkage of the NIL material mixture upon curing is limited due to the use of nanoparticles and the base resin as a combination to form the NIL material.

In some implementations, the base resin component has a viscosity below 150 cps, below 80 cps, or below 50 cps. In some embodiments, the base resin component has a viscosity ranging from 2 cps to 100 cps, from 10 cps to 100 cps, or from 10 cps to 60 cps. In some embodiments, the base resin component has a viscosity selected from about 1 cps, about 2 cps, about 3 cps, about 4 cps, about 5 cps, about 6 cps, about 7 cps, about 8 cps, about 9 cps, about 10 cps, about 11 cps, about 12 cps, about 13 cps, about 14 cps, about 15 cps, about 16 cps, about 17 cps, about 18 cps, about 19 cps, about 20 cps, about 21 cps, about 22 cps, about 23 cps, about 24 cps, about 25 cps, about 26 cps, about 27 cps, about 28 cps, about 29 cps, about 30 cps, about 31 cps, about 32 cps, about 33 cps, about 34 cps, about 35 cps, about 36 cps, about 37 cps, about 38 cps, about 39 cps, about 40 cps, about 41 cps, about 42 cps, about 43 cps, about 44 cps, about 45 cps, about 46 cps, about 47 cps, about 48 cps, about 49 cps, about 50 cps, about 51 cps, about 52 cps, about 53 cps, about 54 cps, about 55 cps, about 56 cps, about 57 cps, about 58 cps, about 59 cps, and about 60 cps.

In some embodiments, the viscosity is measured in the absence of the nanoparticles component. In some alternative embodiments, the viscosity is measured in the presence of the nanoparticles component. In some embodiments, the viscosity is measured in the absence of a solvent. In some alternative embodiments, the viscosity is measured in the presence of a solvent. In some embodiments, as described above, the viscosity is measured in the absence of both solvent and the nanoparticles component, such that the viscosity refers only to the base resin component that can be crosslinked and/or polymerized. In some embodiments, the viscosity is measured using a NIL precursor material comprising the base resin component, a nanoparticles component, one or more radical and/or acid generators, one or more crosslinking agents, one or more optional additives, and/or one or more solvents. In some embodiments, the viscosity of the NIL precursor material is the same as the viscosity of the base resin component. In some embodiments, the viscosity of the NIL precursor material is different from the viscosity of the base resin component.

In some embodiments, the base resin component is a liquid at room temperature (e.g., between 15 and 25° C.). In some embodiments, the base resin component is a liquid at a temperature between 20 and 25° C. In some such embodiments, the viscosity is measured at room temperature. In some embodiments, as described above, the curing is performed at a temperature that is higher than room temperature, and the base resin component and/or the one or more component resins are solid at room temperature but liquid at a temperature that is at least higher than room temperature. In some such embodiments, the viscosity is measured at a temperature that is at least higher than room temperature at which the base resin component and/or the one or more component resins are a liquid. In some such embodiments, the viscosity is measured at the curing temperature.

In some embodiments, as described above, the imprinting is performed at a temperature that is higher than room temperature to facilitate the flow of the NIL precursor material inside the mold, and the base resin component and/or the one or more component resins are solid at room temperature but liquid at a temperature that is at least higher than room temperature. In some such embodiments, the viscosity is measured at a temperature that is at least higher than room temperature at which the base resin component and/or the one or more component resins are a liquid. In some such embodiments, the viscosity is measured at the imprinting temperature.

In some embodiments, the viscosity is measured at a temperature that is below the curing temperature and/or the imprinting temperature. In some embodiments, the viscosity is measured at a temperature that is between 25 and 40° C., between 40 and 80° C., between 80 and 120° C., between 120 and 200° C., or higher than 200° C. In some embodiments, the viscosity is measured at at temperature that is between 100° C. and 150° C., between 100° C. and 140° C., or between 110° C. and 140° C. In some embodiments, the base resin component is a solid at room temperature, and the viscosity is measured at a temperature that is at least as high as the lowest temperature at which the base resin component is a liquid.

In some embodiments, the base resin component comprises a mixture of one or more resins. In some embodiments, the base resin component further comprises additives (e.g., for modifying the properties of the NIL precursor material) and solvent (e.g., for facilitating the mixing of the various components). In some such embodiments, the the base resin component is generated by mixing the various components together. In some embodiments, the base resin component comprises a first component comprising a first one or more resins and a second component comprising a second one or more resins, a nanoparticles component, one or more radical and/or acid generators, one or more crosslinking agents, one or more optional additives, and/or one or more solvents, where the first component is a solid at a respective temperature prior to mixing but becomes liquid at the respective temperature after mixing with the second component. In some such embodiments, the viscosity is measured after mixing the first and second components in the base resin component.

In some embodiments, the base resin component comprises one or more organic resins that are carbon-based and/or comprise hydrogen, sulfur, oxygen, nitrogen, or various other elements in the one or more resins. In some embodiments, the base resin component comprises acrylate, methyl acrylate, vinyl (e.g., olefin or heterocyclic) groups, and/or a mixture of such.

In some embodiments, the base resin component comprises one or more reactive molecules, monomers, oligomers, and/or polymers. In some embodiments, the base resin component comprises of 1, 2, 3, 4, 5, 6, 7, 8, 9, 10, or more than 10 unique types of reactive molecules, monomers, oligomers, and/or polymers. Specifically, in some embodiments, the base resin component comprises one or more crosslinkable monomers, one or more polymerizable monomers, or both. In some embodiments, the crosslinkable monomers or the polymerizable monomers comprise one or more crosslinkable or polymerizable moieties. In some embodiments, the base resin component comprises no less than 2 unique types of crosslinkable or polymerizable moieties.

Depending on the application, in some embodiments, a respective resin in the one or more resins in the base resin component may be selected based on, inter alia, its refractive index, its interaction with other components in the NIL precursor material, and/or the associated processing techniques or mechanisms for curing (e.g., crosslinking or polymerizing) the base resin component. Although in some embodiments the base resin components described herein are curable by UV light, by light wavelengths ranging from about 254 nm to about 415 nm or by other curing methods (e.g., electron beam curing, etc.), in some alternative embodiments, a respective one or more resins having different functional groups are cured using different curing mechanisms and/or under different operating conditions. Thus, in some embodiments, the one or more resins in the base resin component are selected based on the desired processing parameters for NIL molding (e.g. of a slanted or non-slanted surface-relief grating), depending on the functional groups present on the one or more resins.

For example, in some embodiments, the crosslinkable or polymerizable moieties are selected from an ethylenically unsaturated group, an oxirane ring, and a heterocyclic group. In some embodiments, a base resin component comprising an oxirane ring has a higher refractive index than a base resin component comprising an ethylenically unsaturated group. In some embodiments, the refractive index of a base resin component comprising an oxirane ring is greater than the refractive index of a base resin component comprising an ethylenically unsaturated group by at least about 0.01, at least about 0.02, at least about 0.03, at least about 0.04, at least about 0.05, at least about 0.06, or greater. In some embodiments, the crosslinkable or polymerizable moieties are selected from vinyl, allyl, epoxide, acrylate, and methacrylate. In some embodiments, the crosslinkable or polymerizable moieties are selected from optionally substituted alkenyl, optionally substituted cycloalkenyl, optionally substituted alkynyl, optionally substituted acrylate, optionally substituted methacrylate, optionally substituted styrene, optionally substituted epoxide, optionally substituted thiirane, optionally substituted lactone, and optionally substituted carbonate.

In some embodiments, a base resin material is selected based on its refractive index, its interaction with other components of the NIL material, the associated processing techniques or mechanisms for cross-linking or curing the base resin, etc. Although the base resin materials described herein can generally be cured by UV-light or light having wavelengths ranging from about 254 nm to about 415 nm or other curing methods (e.g., electron beam curing, etc.), the base resin materials having different functional groups may be cured or cross-linked using different cross-linking mechanisms and/or under different operating conditions, and thus may be selected based on the various processing parameters for NIL molding the slanted grating.

In some embodiments, the crosslinkable or polymerizable moieties are selected from:

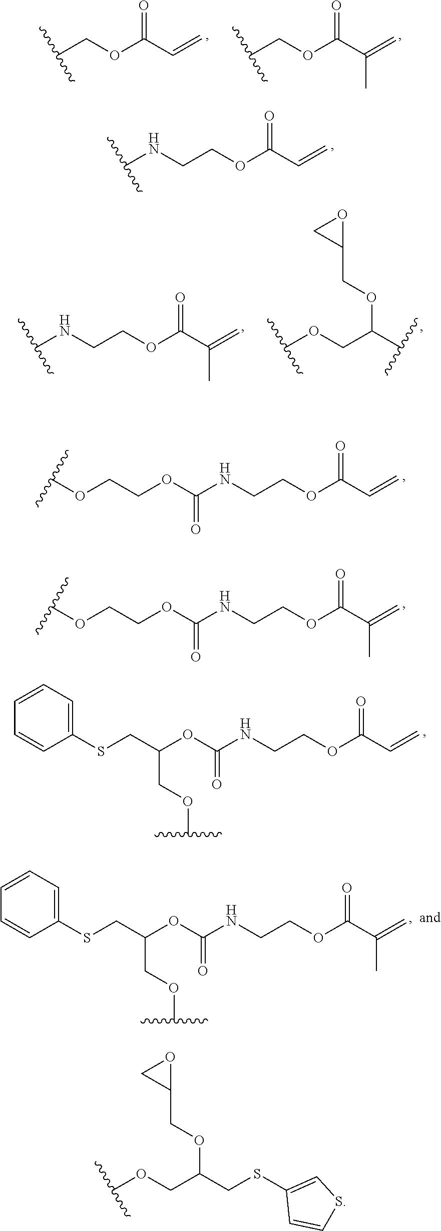

In some embodiments, the crosslinkable monomers or the polymerizable monomers comprise one or more moieties selected from optionally substituted alkyl, optionally substituted heteroalkyl, optionally substituted alkenyl, optionally substituted alkynyl, optionally substituted cycloalkyl, optionally substituted heterocycloalkyl, optionally substituted aryl, optionally substituted arylalkyl, optionally substituted heteroaryl, and optionally substituted heteroarylalkyl. In some embodiments, the crosslinkable monomers or the polymerizable monomers comprise one or more moieties selected from fluorene, cardo fluorene, spiro fluorene, thianthrene, thiophosphate, anthraquinone, and lactam. In some embodiments, the crosslinkable monomers or the polymerizable monomers comprise one or more linking groups selected from —C₁₋₁₀ alkyl-, —O—C₁₋₁₀ alkyl-, —C₁₋₁₀ alkenyl-, —O—C₁₋₁₀ alkenyl-, —C₁₋₁₀ cycloalkenyl-, —O—C₁₋₁₀ cycloalkenyl-, —C₁₋₁₀ alkynyl-, —O—C₁₋₁₀ alkynyl-, —C₁₋₁₀ aryl-, —O—C₁₋₁₀—, -aryl-, —O—, —S—, —C(O)—, —C(O)O—, —OC(O)—, —OC(O)O—, —N(R^{b})—, —C(O)N(R^{b})—, —N(R^{b})C(O)—, —OC(O)N(R^{b})—, —N(R^{b})C(O)O—, —SC(O)N(R^{b})—, —N(R^{b})C(O)S—, —N(R^{b})C(O)N(R^{b})—, —N(R^{b})C(NR^{b})N(R^{b})—, —N(R^{b})S(O)_{w}—, —S(O)_{w}N(R^{b})—, —OS(O)_{w}O—, —O(O)P(OR^{b})O—, (O)P(O—)₃, —O(S)P(OR^{b})O—, and (S)P(O—)₃, where w is 1 or 2, and R^{b} is independently hydrogen, optionally substituted alkyl, or optionally substituted aryl.

In some embodiments, the crosslinkable monomers or the polymerizable monomers comprise one or more terminal groups selected from optionally substituted thiophenyl, optionally substituted thiopyranyl, optionally substituted thienothiophenyl, and optionally substituted benzothiophenyl. In some embodiments, the base resin component comprises one or more derivatives of bisfluorene, dithiolane, thianthrene, biphenol, o-phenylphenol, phenoxy benzyl, bisphenol A, bisphenol F, benzyl, or phenol. In some embodiments, the base resin component comprises one or more of (2,7-bis[(2-acryloyloxyethl)-sulfanyl]thianthrene), benzyl methacrylate, 1,6-hexanediol diacrylate, 1,4-butanediol diacrylate, acryloxypropylsilsesquioxane, or methylsilsesquioxane.

In some embodiments, the base resin component comprises one or more of trimethylolpropane (EO)n triacrylate, caprolactone acrylate, polypropylene glycol monomethacrylate, cyclic trimethylolpropane formal acrylate, phenoxy benzyl acrylate, 3,3,5-trimethyl cyclohexyl acrylate, isobornyl acrylate, o-phenylphenol EO acrylate, 4-tert-butylcyclohexyl acrylate, benzyl acrylate, benzyl methacrylate, biphenylmethyl acrylate, lauryl acrylate, lauryl methacrylate, tridecyl acrylate, lauryl tetradecyl methacrylate, isodecyl acrylate, isodecyl methacrylate, phenol (EO) acrylate, phenoxyethyl methacrylate, phenol (EO)2 acrylate, phenol (EO)4 acrylate, tetrahydrofurfuryl acrylate, tetrahydrofurfuryl methacrylate, nonyl phenol (PO)2 acrylate, nonyl phenol (EO)4 acrylate, nonyl phenol (EO)8 acrylate, ethoxy ethoxy ethyl acrylate, stearyl acrylate, stearyl methacrylate, methoxy PEG600 methacrylate, 1,6-hexanediol diacrylate, 1,6-hexanediol dimethacrylate, 1,6-hexanediol (EO)n diacrylate, polypropylene glycol 400 diacrylate, 1,4-butanediol dimethacrylate, polypropylene glycol 700 (EO)6 dimethacrylate, 1,6-Hexanediol (EO)n diacrylate, hydroxy pivalic acid neopentyl glycol diacrylate, bisphenol A (EO)10 diacrylate, bisphenol A (EO)10 dimethacrylate, neopentyl glycol dimethacrylate, neopentyl glycol (PO)2 diacrylate, tripropylene glycol diacrylate, ethylene glycol dimethacrylate, dipropylene glycol diacrylate, bisphenol A (EO)30 diacrylate, bisphenol A (EO)30 dimethacrylate, diethylene glycol dimethacrylate, triethylene glycol diacrylate, triethylene glycol dimethacrylate, tetraethylene glycol dimethacrylate, bisphenol A (EO)4 diacrylate, bisphenol A (EO)4 dimethacrylate, bisphenol A (EO)3 diacrylate, bisphenol A (EO)3 dimethacrylate, 1,3-butylene glycol dimethacrylate, tricyclodecane dimethanol diacrylate, tetraethylene glycol diacrylate, polyethylene glycol 400 diacrylate, polyethylene glycol 400 dimethacrylate, polyethylene glycol 200 diacrylate, polyethylene glycol 200 dimethacrylate, polyethylene glycol 300 diacrylate, polyethylene glycol 600 diacrylate, polyethylene glycol 600 dimethacrylate, bisphenol F (EO)4 diacrylate, trimethylolpropane triacrylate, trimethylolpropane trimethacrylate, trimethylolpropane (EO)3 triacrylate, trimethylolpropane (EO)15 triacrylate, trimethylolpropane (EO)6 triacrylate, trimethylolpropane (EO)9 triacrylate, glycerine (PO)3 triacrylate, pentaerythritol triacrylate, trimethylolpropane (PO)3 triacrylate, tris(2-hydroxyethyl)isocyanurate triacrylate, pentaerythritol (EO)n tetraacrylate, ditrimethylolpropane tetraacrylate, pentaerythritol tetraacrylate, dipentaerythritol pentaacrylate, and dipentaerythritol hexaacrylate.

In some embodiments, the base resin component comprises one or more of a phosphate methacrylate, an amine acrylate, an acrylated amine synergist, a carboxylethyl acrylate, a modified epoxy acrylate, a bisfluorene diacrylate, a modified bisphenol fluorene diacrylate, a modified bisphenol fluorene type, a butadiene acrylate, an aromatic difunctional acrylate, an aliphatic multifunctional acrylate, a polyester acrylate, a trifunctional polyester acrylate, a tetrafunctional polyester acrylate, a phenyl epoxy acrylate, a bisphenol A epoxy acrylate, a water soluble acrylate, an aliphatic alkyl epoxy acrylate, a bisphenol A epoxy methacrylate, a soybean oil epoxy acrylate, a difunctional polyester acrylate, a trifunctional polyester acrylate, a tetrafunctional polyester acrylate, a chlorinated polyester acrylate, a hexafunctional polyester acrylate, an aliphatic difunctional acrylate, an aliphatic difunctional methacrylate, an aliphatic trifunctional acrylate, an aliphatic trifunctional methacrylate, an aromatic difunctional acrylate, an aromatic tetrafunctional acrylate, an aliphatic tetrafunctional acrylate, an aliphatic hexafunctional acrylate, an aromatic hexafunctional acrylate, an acrylic acrylate, a polyester acrylate, a sucrose benzoate, a caprolactone methacrylate, a caprolactone acrylate, a phosphate methacrylate, an aliphatic multifunctional acrylate, a phenol novolac epoxy acrylate, a cresol novolac epoxy acrylate, an alkali strippable polyester acrylate, a melamine acrylate, a silicone polyester acrylate, a silicone urethane acrylate, a dendritic acrylate, an aliphatic tetrafunctional methacrylate, a water dispersion urethane acrylate, a water soluble acrylate, an aminated polyester acrylate, a modified epoxy acrylate, or a trifunctional polyester acrylate.

In some embodiments, the base resin component comprises one or more of:

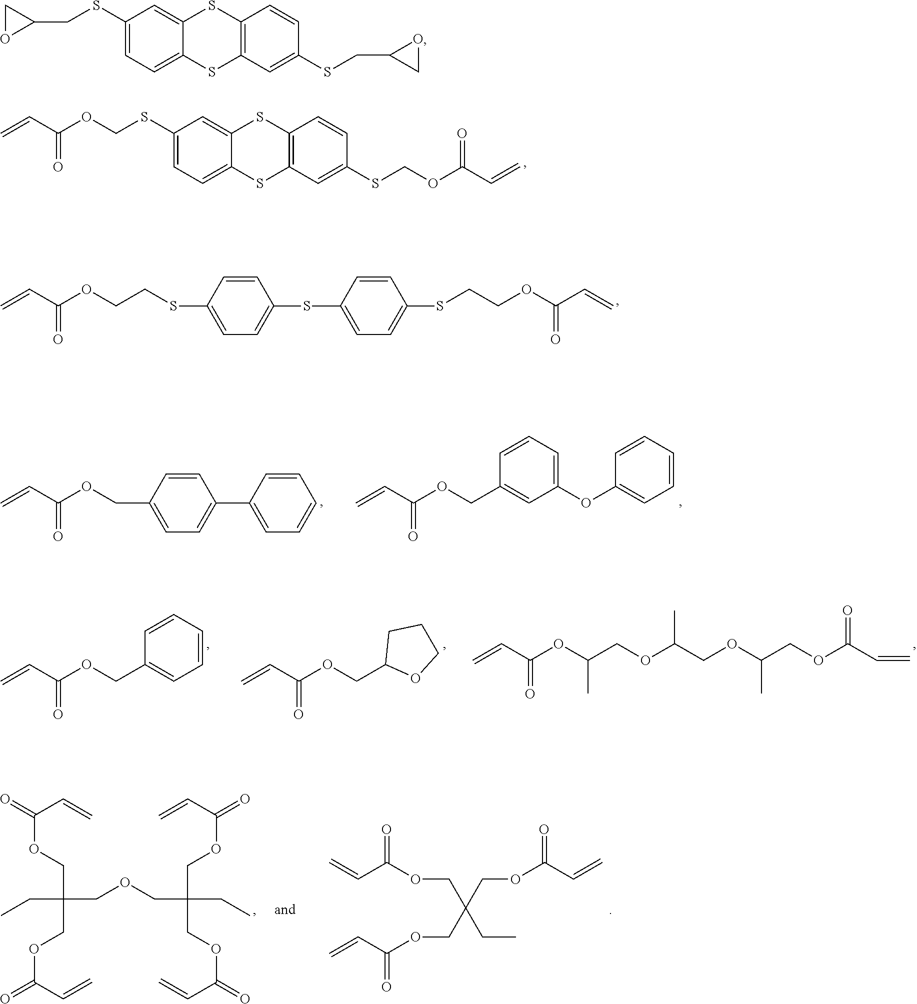

In some embodiments, the base resin component comprises one or more of:

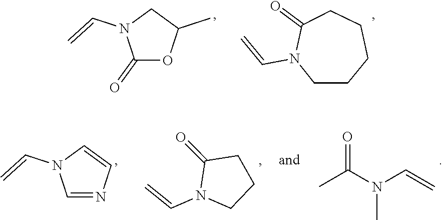

In some embodiments, the base resin component comprises one or more fluorinated compounds. In some embodiments, the one or more fluorinated compounds are selected from: 2,2,3,3,4,4,5,5,6,6,7,7-dodecafluoroheptyl acrylate, 3,3,4,4,5,5,6,6,7,7,8,8,9,9,10,10,11,11,12,12,12-heneicosafluorododecyl acrylate, 3,3,4,4,5,5,6,6,7,7,8,8,9,9,10,10,10-heptadecafluorodecyl methacrylate, 2,2,3,3,4,4,4-heptafluorobutyl acrylate, 2,2,3,3,4,4,4-heptafluorobutyl methacrylate, 2,2,3,4,4,4-hexafluorobutyl acrylate, 2,2,3,4,4,4-hexafluorobutyl methacrylate, 1,1,1,3,3,3-hexafluoroisopropyl acrylate, 1,1,1,3,3,3-hexafluoroisopropyl methacrylate, 2,2,3,3,4,4,5,5-octafluoropentyl acrylate, 2,2,3,3,4,4,5,5-octafluoropentyl methacrylate, 2,2,3,3,3-pentafluoropropyl acrylate, 2,2,3,3,3-pentafluoropropyl methacrylate, 1H,1H,2H,2H-perfluorodecyl acrylate, 2,2,3,3-tetrafluoropropyl methacrylate, 3,3,4,4,5,5,6,6,7,7,8,8,8-tridecafluorooctyl acrylate, 3,3,4,4,5,5,6,6,7,7,8,8,8-tridecafluorooctyl methacrylate, 2,2,2-trifluoroethyl methacrylate, and 2-[(1′,1′,1′-trifluoro-2′-(trifluoromethyl)-2′-hydroxy)propyl]-3-norbornyl methacrylate.

In some embodiments, the one or more resins in the base resin component are provided as commercially available compounds. In some embodiments, the one or more resins in the base resin component are synthesized by various methods. Specifically, in some embodiments, the one or more resins in the base resin component are synthesized such that the resulting resins comprise the desired parameters disclosed herein (e.g., refractive index, viscosity, functional groups, etc.). Non-limiting embodiments of base resin components are provided below in the Examples in Table 26.

In some embodiments, the base resin component further comprises one or more solvents. In some embodiments, the one or more solvents are selected from 2-(1-methoxy)propyl acetate, propylene glycol monomethyl ether acetate, propylene glycol methyl ether, ethyl acetate, xylene, and toluene.

In some embodiments, the base resin component is mixed with one or more solvents prior to the application of the NIL precursor material and/or the base resin component to a substrate (e.g., a spin-coating step), such that the addition of solvent decreases the viscosity of the NIL precursor material and/or the base resin component to allow an even application onto the substrate (e.g., a film). In some embodiments, the solvents are removed from the NIL precursor material after the spin-coating step. In some embodiments, the percentage of solvent remaining in the base resin component after the spin-coating step and removal of the solvent is less than 5%.

In some embodiments, the properties (e.g., refractive index, viscosity, etc.) of the base resin component are measured prior to application onto a substrate (e.g., spin-coating), and the properties of the film are measured after application onto a substrate, and the measurements are compared. In some such embodiments, the measurements are performed in the absence of solvent. For example, in some such implementations, if the refractive index of the base resin component in the absence of solvent is low, then the refractive index of the resultant film in the absence of solvent will be high. Conversely, in some such implementations, if the refractive index of the base resin component in the absence of solvent is high, then the refractive index of the resultant film in the absence of solvent will be low.

In some embodiments, the base resin component further comprises one or more of a photo radical generator, a photo acid generator, or both. In some embodiments, depending on the crosslinking functional group or groups that the base resin component comprises, the base resin component is crosslinked or polymerized via radical photopolymerization (e.g., free radical photopolymerization or controlled radical photopolymerization), acid photopolymerization, ionic photopolymerization (e.g., cationic photopolymerization or anionic photopolymerization), and/or a mixture of such. For example, a base resin component comprising an ethylenically unsaturated group can be crosslinked or polymerized via radical photopolymerization (e.g., free radical photopolymerization). To facilitate the polymerization of a base resin component containing the ethylenically unsaturated group, the NIL precursor material further includes one or more photo radical generators (PRGs). Under UV radiation, the PRGs generate radicals that initiate the polymerization or crosslinking process of the ethylenically unsaturated group of the base resin component molecules. In another example, a base resin component comprising an oxirane ring can be crosslinked or polymerized via ionic photopolymerization (e.g., cationic photopolymerization). To facilitate the polymerization of the base resin component comprising the oxirane ring, the NIL precursor material further includes one or more photo acid generators (PAGs). Under UV radiation, the PAGs generate cations or acid that initiate the polymerization or crosslinking process of the oxirane ring of the base resin component molecules.

In some embodiments, the various base resin materials described herein are generally flowable or in liquid form, and thus allow the NIL material mixture to be molded or imprinted at an imprinting temperature close to room temperature, which may include a temperature from about 15° C. to about 50° C. In some embodiments, the various base resin materials described herein may generally allow the NIL material mixture to be molded or imprinted without applying heat to the NIL material mixture or the substrate upon which the NIL material mixture is applied, although thermal processing may be involved in other operations (e.g., polymerization) of the NIL molding process. In some embodiments, thermal treatment may nonetheless be implemented during molding so as to further reduce the viscosity of the NIL material mixture to facilitate the flow of the NIL material mixture inside the mold.

In some embodiments, the base resin component further comprises one or more inhibitors. In some embodiments, the one or more inhibitors are selected from monomethyl ether hydroquinone and 4-tert-butylcatechol. The one or more inhibitors refers to one or more compositions, compounds, molecules, etc., that are capable of inhibiting or substantially inhibiting the crosslinking or polymerization of the crosslinkable or polymerizable component when the photoinitiating light source is on or off. In some embodiments, the one or more inhibitors stabilize the base resin component to prevent crosslinking or polymerization prior to the curing.

The base resin components comprising one or more organic resins or organic elements embodied herein are not intended to exclude further embodiments of base resin components comprising inorganic or metal elements. Rather, in some embodiments, the organic base resin components described herein include carbon elements as well as other non-carbon elements (e.g., hydrogen, sulfur, oxygen, nitrogen, etc.). In some embodiments, the organic base resin includes one or more derivatives from bisfluorene, dithiolane, thianthrene, biphenol, o-phenylphenol, phenoxy benzyl, bisphenol A, bisphenol F, benzyl, phenol, and the like. The organic base resin may have a refractive index greater than or about 1.45, greater than or about 1.5, greater than or about 1.55, greater than or about 1.57, greater than or about 1.58, or greater than or about 1.6. For example, the organic base resin may include a refractive index ranging from 1.45 to 1.8, from 1.5 to 1.8, from 1.55 to 1.8, from 1.57 to 1.8, from 1.58 to 1.77, from 1.58 to 1.73, or from 1.6 to 1.73 in various embodiments.

Additionally, in some embodiments, the base resin component comprises silicone-based base resin components that include an inorganic silicon-oxygen backbone chain. For example, in some embodiments, the base resin component further comprises one or more siloxane derivative compounds. In some embodiments, the base resin component further comprises one or more surfactants. In some implementations, a base resin component includes a surfactant that comprises a main chain of a siloxane skeleton comprising an inorganic silicon-oxygen backbone chain (e.g., X-12-2430C fluorine contained type), a high number of functional groups and at least one fluorine. In some such embodiments, the surfactant provides increased benefits to the base resin component, including but not limited to increased durability against heat and light, high hardness, anti-stain properties, and/or water and oil repellency. In some embodiments, the weight percentage (wt. %) of the surfactant to the base resin component is between 0.1% and 5%. In some embodiments, the one or more surfactants are selected from a fluorinated surfactant, a crosslinkable surfactant, and a non-crosslinkable surfactant. In some embodiments, the base resin does not include silicone-based base resin components that include an inorganic silicon-oxygen backbone chain.

In some embodiments, the one or more surfactants is a crosslinkable, fluorinated acrylic (e.g., 2,2,3,3,4,4,5,5,6,6,7,7-Dodecafluoroheptyl acrylate; 3,3,4,4,5,5,6,6,7,7,8,8,9,9,10,10,11,11,12,12,12-Heneicosafluorododecyl acrylate; 3,3,4,4,5,5,6,6,7,7,8,8,9,9,10,10,10-Heptadecafluorodecyl methacrylate containing MEHQ as inhibitor; 2,2,3,3,4,4,4-Heptafluorobutyl acrylate; 2,2,3,3,4,4,4-Heptafluorobutyl methacrylate; 2,2,3,4,4,4-Hexafluorobutyl acrylate; 2,2,3,4,4,4-Hexafluorobutyl methacrylate; 1,1,1,3,3,3-Hexafluoroisopropyl acrylate; 1,1,1,3,3,3-Hexafluoroisopropyl methacrylate; 2,2,3,3,4,4,5,5-Octafluoropentyl acrylate containing 100 ppm monomethyl ether hydroquinone as inhibitor; 2,2,3,3,4,4,5,5-Octafluoropentyl methacrylate containing 100 ppm MEHQ as inhibitor; 2,2,3,3,3-Pentafluoropropyl acrylate containing 100 ppm 4-tert-butylcatechol as inhibitor; 2,2,3,3,3-Pentafluoropropyl methacrylate containing 100 ppm 4-tert-butylcatechol as inhibitor; 1H,1H,2H,2H-Perfluorodecyl acrylate containing 100 ppm tert-butylcatechol as inhibitor; 2,2,3,3-Tetrafluoropropyl methacrylate; 3,3,4,4,5,5,6,6,7,7,8,8,8-Tridecafluorooctyl acrylate containing inhibitor; 3,3,4,4,5,5,6,6,7,7,8,8,8-Tridecafluorooctyl methacrylate containing 100 ppm 4-tert-butylcatechol as inhibitor; 2,2,2-Trifluoroethyl methacrylate containing 50-200 ppm MEHQ as inhibitor; and/or 2-[(1′,1′,1′-Trifluoro-2′-(trifluoromethyl)-2′-hydroxy)propyl]-3-norbornyl methacrylate).

In some embodiments, a silicone-based resin has a refractive index that is lower than the refractive index of an organic-based resin. In some embodiments, a silicone-based resin has a refractive index of 1.55 or lower. In some such embodiments, the refractive index of the silicone-based resin is measured at 589 nm. In some embodiments, the base resin component does not include silicon.

(b) Nanoparticles Component

In some embodiments, the NIL precursor material further includes nanoparticles for increasing the refractive index of the NIL precursor material. In some embodiments, the nanoparticles comprise one or more metal oxides having relatively high refractive indices.

For example, in some embodiments, certain classes of inorganic nanoparticles such as zirconium oxide (ZrOₓ), hafnium oxide (HfOₓ), and/or titanium oxide (TiOₓ or TiO₂) may have higher refractive indices than the refractive index of the base resin component, such that the addition of the nanoparticles component to the NIL precursor material increases the overall refractive index of the NIL precursor material. In contrast, in some embodiments, certain classes of organic nanoparticles may have lower refractive indices than the refractive index of the base resin component.

In some embodiments, the weight percentage loading (wt. %) of the nanoparticles component to the NIL precursor material ranges from 40 wt. % to 95 wt. %, from 50 wt. % to 90 wt. %, or from 55 wt. % to 85 wt. %. In some embodiments, the weight percentage loading of the nanoparticles component to the NIL precursor material is about 55%, about 56%, about 57%, about 58%, about 59%, about 60%, about 61%, about 62%, about 63%, about 64%, about 65%, about 66%, is about 67%, about 68%, about 69%, about 70%, about 71%, about 72%, about 73%, about 74%, about 75%, about 76%, is about 77%, about 78%, about 79%, about 80%, about 81%, about 82%, about 83%, about 84%, or about 85%. In some embodiments, increasing the loading (e.g., the weight or mass percentage) of high refractive index nanoparticles further increases the refractive index of the NIL precursor material.

In some embodiments, the nanoparticles component comprises one or more of titanium oxide, zirconium oxide, hafnium oxide, tungsten oxide, zinc tellurium, gallium phosphide, or any combination or derivative thereof. In some embodiments, the nanoparticles component comprises titanium oxide nanoparticles. In some embodiments, the nanoparticles component comprises zirconium oxide nanoparticles. In some embodiments, the nanoparticles component comprises more than one type of nanoparticles to form a blend of nanoparticles. In some embodiments, the nanoparticles component comprises a mixture of titanium oxide nanoparticles and zirconium oxide nanoparticles. In some embodiments, the nanoparticles may have a refractive index between about 1.7 and about 3.4, between about 1.75 and about 3.4, or between about 1.8 and about 3.4.

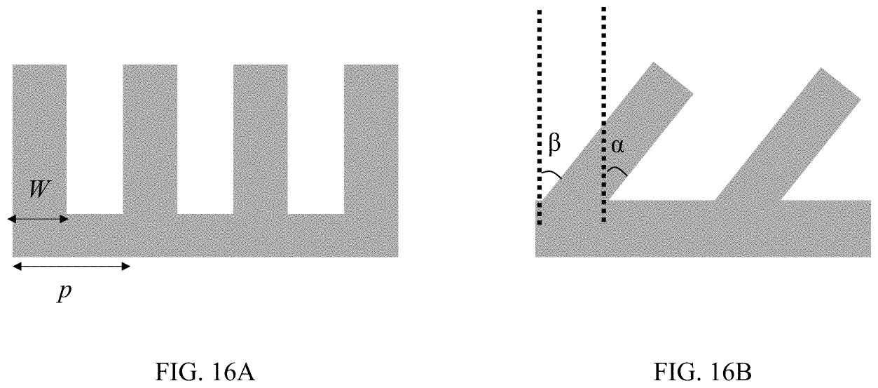

In some embodiments, the nanoparticles component comprises a plurality of surface-modified nanoparticles, a plurality of capped nanoparticles, or both. In some embodiments, the surface-modified nanoparticles, the capped nanoparticles, or both, comprise a substantially inorganic core, and a substantially organic shell. FIG. 15 illustrates a cross-sectional view of an exemplary nanoparticle, showing the structure of the nanoparticle in accordance with some embodiments. In some such embodiments, the substantially inorganic core is represented by the inner circle, with a diameter indicated by r₁, and the substantially organic shell is represented by the outer circle, with a diameter indicated by r₂=r₁+1. For example, in FIG. 15, the substantially inorganic core comprises TiO₂.

In some embodiments, the substantially organic shell comprises one or more crosslinkable or polymerizable moieties. For example, FIG. 15 illustrates the substantially organic shell comprising a plurality of ligands. In some embodiments, the crosslinkable or polymerizable moieties are covalently bonded to the substantially organic shell of the surface-modified nanoparticles, the capped nanoparticles, or both. In some embodiments, the one or more crosslinkable or polymerizable moieties are linked to the substantially inorganic core.

In some embodiments, the nanoparticles component comprises one or more crosslinkable or polymerizable moieties (e.g., metal oxide ligands) capable of reacting with the crosslinkable or polymerizable moieties of the base resin component. In some embodiments, the reactivity of the crosslinkable or polymerizable moieties of the nanoparticles component with the corresponding crosslinkable or polymerizable moieties of the base resin component allows the nanoparticles to crosslink or polymerize with the base resin component during the curing step, resulting in a cured NIL material with high mechanic strength sufficient to withstand the various steps of the molding process (e.g., the delamination step). Conversely, in some embodiments, a NIL precursor material comprising a non-reactive nanoparticles component where the nanoparticles are suspended in but do not crosslink or polymerize with the base resin component, results in a cured NIL material with low mechanic strength and greater fragility.

In some such embodiments, the crosslinkable or polymerizable ligands are acrylate, methyl acrylate and derivatives, vinyl groups (e.g., olefin or heterocyclic) and derivatives, and/or a mixture of such.

For example, a nanoparticles component comprising an acrylate group can, in some embodiments, crosslink with a base resin component comprising an acrylate resin. A byproduct of nanoparticle synthesis is the presence of functional groups on the surface of the nanoparticle, such as the presence of —OH groups caused by hydrolysis and condensation during the synthesis of titanium oxide nanoparticles. These —OH groups can be functionalized with other functional groups (e.g., silane) that are subsequently bound to crosslinkable or polymerizable moieties (e.g., acrylate and/or methacrylate). By thus modifying the reactivity of the ligands present on the surface of the nanoparticles, the crosslinkable or polymerizable moieties of the nanoparticles (e.g., acrylate and/or methacrylate) are able to form covalent bonds with the crosslinkable or polymerizable moieties in the base resin component (e.g., acrylate and/or methacrylate) upon exposure to electromagnetic radiation (e.g., a wavelength of UV light).

In some embodiments, the functional groups that link the substantially organic shell of the nanoparticles with the crosslinkable or polymerizable moieties are selected depending on their reactivity (e.g., ability to form covalent bonds) with the crosslinkable or polymerizable moieties. In some embodiments, the crosslinkable or polymerizable moieties of the substantially organic shell of the nanoparticles are selected depending on their reactivity with the crosslinkable or polymerizable moieties of the base resin component. In some embodiments, the crosslinkable or polymerizable ligands comprise no less than 2 unique types of crosslinkable or polymerizable functional groups.

For example, in some embodiments, the crosslinkable or polymerizable moieties comprise one or more of an ethylenically unsaturated group, an oxirane ring, or a heterocyclic group. In some embodiments, the crosslinkable or polymerizable moieties comprise one or more of vinyl, allyl, epoxide, acrylate, and methacrylate.

In some embodiments, the crosslinkable or polymerizable moieties comprise one or more of optionally substituted alkenyl, optionally substituted cycloalkenyl, optionally substituted alkynyl, optionally substituted acrylate, optionally substituted methacrylate, optionally substituted styrene, optionally substituted epoxide, optionally substituted thiirane, optionally substituted lactone, and optionally substituted carbonate.

In some embodiments, the crosslinkable or polymerizable moieties comprise one or more linking groups selected from —Si(—O—)₃, —C₁₋₁₀ alkyl-, —O—C₁₋₁₀ alkyl-, —C₁₋₁₀ alkenyl-, —O—C₁₋₁₀ alkenyl-, —C₁₋₁₀ cycloalkenyl-, —O—C₁₋₁₀ cycloalkenyl-, —C₁₋₁₀ alkynyl-, —O—C₁₋₁₀ alkynyl-, —C₁₋₁₀ aryl-, —O—C₁₋₁₀—, -aryl-, —O—, —S—, —C(O)—, —C(O)O—, —OC(O)—, —OC(O)O—, —N(R^{b})—, —C(O)N(R^{b})—, —N(R^{b})C(O)—, —OC(O)N(R^{b})—, —N(R^{b})C(O)O—, —SC(O)N(R^{b})—, —N(R^{b})C(O)S—, —N(R^{b})C(O)N(R^{b})—, —N(R^{b})C(NR^{b})N(R^{b})—, —N(R^{b})S(O)_{w}—, —S(O)_{w}N(R^{b})—, —S(O)_{w}O—, —OS(O)_{w}—, —OS(O)_{w}O—, —O(O)P(OR^{b})O—, (O)P(O—)₃, —O(S)P(OR^{b})O—, and (S)P(O—)₃, where w is 1 or 2, and R^{b} is independently hydrogen, optionally substituted alkyl, or optionally substituted aryl.

In some embodiments, the substantially organic shell comprises one or more of an organosilane or a corresponding organosilanyl substituent, an organoalcohol or a corresponding organoalkoxy substituent, or an organocarboxylic acid or a corresponding organocarboxylate substituent. In some embodiments, the organosilane is selected from n-propyltrimethoxysilane, n-propyltriethoxysilane, n-octyltrimethoxysilane, n-octyltriethoxysilane, phenylrimethoxysilane, 2-methoxy(polyethyleneoxy)propyl-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanatopropyltriethoxysilane, 3-isocyanatopropyltrimethoxysilane, and glycidoxypropyltrimethoxysilane. In some embodiments, the organoalcohol is selected from heptanol, hexanol, octanol, benzyl alcohol, phenol, ethanol, propanol, butanol, oleylalcohol, dodecylalcohol, octadecanol and triethylene glycol monomethyl ether. In some embodiments, the organocarboxylic acid is selected from octanoic acid, acetic acid, propionic acid, 2-2-(2-methoxyethoxy)ethoxyacetic acid, oleic acid, and benzoic acid.

In some embodiments, the substantially organic shell comprises one or more of 3-(methacryloyloxy)propyl trimethoxysilane, 3-(methacryloyloxy)propyl dimethoxysilyl, or 3-(methacryloyloxy)propyl methoxysiloxyl.

In some embodiments, the diameter of a substantially inorganic core ranges from about 1 nm to about 25 nm. For illustration, in FIG. 15, the diameter of a substantially inorganic core is represented by r₁. In some embodiments, the diameter of a substantially inorganic core is selected from about 1 nm, about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, and about 25 nm. In some embodiments, the diameter of a substantially inorganic core is between 0.1 nm to 1 nm. In some embodiments, the diameter of a substantially inorganic core is between 25 nm and 1 μm.

In some embodiments, the diameter of a substantially inorganic core is measured by transmission electron microscopy (TEM).

In some embodiments, the diameter of a surface-modified nanoparticle, a capped nanoparticle, or both, including a substantially organic shell, ranges from about 5 nm to about 100 nm. For example, in FIG. 15, the diameter of an exemplary nanoparticle including a substantially organic shell is represented by r₂=r₁+l. In some embodiments, the diameter of a surface-modified nanoparticle, a capped nanoparticle, or both, including a substantially organic shell, ranges from about 10 nm to about 50 nm. In some embodiments, the diameter of a surface-modified nanoparticle, a capped nanoparticle, or both, including a substantially organic shell, is between 0.1 nm and 5 nm. In some embodiments, the diameter of a surface-modified nanoparticle, a capped nanoparticle, or both, including a substantially organic shell, is between 100 nm and 1 μm.

In some embodiments, the diameter of a surface-modified nanoparticle, a capped nanoparticle, or both, including a substantially organic shell, is selected from about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, and about 25 nm, about 26 nm, about 27 nm, about 28 nm, about 29 nm, about 30 nm, about 31 nm, about 32 nm, about 33 nm, about 34 nm, about 35 nm, about 36 nm, about 37 nm, about 38 nm, about 39 nm, about 40 nm, about 41 nm, about 42 nm, about 43 nm, about 44 nm, about 45 nm, about 46 nm, about 47 nm, about 48 nm, about 49 nm, about 50 nm, about 51 nm, about 52 nm, about 53 nm, about 54 nm, about 55 nm, about 56 nm, about 57 nm, about 58 nm, about 59 nm, about 60 nm, about 61 nm, about 62 nm, about 63 nm, about 64 nm, about 65 nm, about 66 nm, about 67 nm, about 68 nm, about 69 nm, about 70 nm, about 71 nm, about 72 nm, about 73 nm, about 74 nm, about 75 nm, about 76 nm, about 77 nm, about 78 nm, about 79 nm, about 80 nm, about 81 nm, about 82 nm, about 83 nm, about 84 nm, about 85 nm, about 86 nm, about 87 nm, about 88 nm, about 89 nm, about 90 nm, about 91 nm, about 92 nm, about 93 nm, about 94 nm, about 95 nm, about 96 nm, about 97 nm, about 98 nm, about 99 nm, and about 100 nm.

In some embodiments, the diameter of a surface-modified nanoparticle, a capped nanoparticle, or both, including a substantially organic shell, is measured by dynamic light scattering (DLS).

In some embodiments, the diameter of a substantially inorganic core or a nanoparticle (e.g., a surface-modified nanoparticle, a capped nanoparticle, or both, including a substantially organic shell), is measured by transmission electron microscopy (TEM), dynamic light scattering (DLS), laser diffraction, field flow fractionation, particle tracking analysis, size exclusion chromatography, centrifugal sedimentation, and atomic force microscopy, X-ray diffraction, hydrodynamic chromatography, static light scattering, multiangle light scattering, nephelometry, laser-induced breakdown detection, ultraviolet-visible spectroscopy, near-field scanning optical microscopy, confocal laser scanning microscopy, capillary electrophoresis, ultracentrifugation, cross-flow filtration, small-angle X-ray scattering, and differential mobility analysis. In some embodiments, the diameter and/or size of a substantially inorganic core or a nanoparticle (e.g., a surface-modified nanoparticle, a capped nanoparticle, or both, including a substantially organic shell), is calculated from physical properties such as settling velocity, diffusion rate or coefficient, and electrical mobility, or from measured parameters such as Feret diameter, Martin diameter and projected area diameters.

In some embodiments, the volume fraction of the substantially inorganic core in the surface-modified nanoparticles, the capped nanoparticles, or both, ranges from about 60% to about 90%. Referring to FIG. 15, in some embodiments, the volume fraction of the substantially inorganic core in the surface-modified nanoparticles, the capped nanoparticles, or both, is determined using Rytov's formula

$${γ}_{c} = \frac{{r}_{1}^{3}}{{( {r}_{1} + l )}^{3}} ,$$

where γ_{c} is the volume fraction of the substantially inorganic core.

In some embodiments, the volume fraction of the substantially inorganic core in the surface-modified nanoparticles, the capped nanoparticles, or both, is selected from about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, and about 90%. In some embodiments, the volume fraction of the substantially inorganic core in the surface-modified nanoparticles, the capped nanoparticles, or both, is less than 60% or greater than 90%.

In some embodiments, the volume fraction of the substantially organic shell in the surface-modified nanoparticles, the capped nanoparticles, or both, ranges from about 10% to about 40%. Referring to FIG. 15, in some embodiments, the volume fraction of the substantially organic shell in the surface-modified nanoparticles, the capped nanoparticles, or both, is determined using Rytov's formula

$${γ}_{l} = \frac{l ( {l}^{2} + 3 {r}_{1} l + 3 {r}_{1}^{2} )}{{( {r}_{1} + l )}^{3}} ,$$

where γₗ is the volume fraction of the substantially organic shell.

In some embodiments, the volume fraction of the substantially organic shell in the surface-modified nanoparticles, the capped nanoparticles, or both, is selected from about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, and about 40%. In some embodiments, the volume fraction of the substantially organic shell in the surface-modified nanoparticles, the capped nanoparticles, or both, is less than 10% or greater than 40%.

In some embodiments, the second refractive index (e.g., of the nanoparticles component) ranges from 2.00 to 2.61.

In some embodiments, the second refractive index is selected from about 2.00, about 2.01, about 2.02, about 2.03, about 2.04, about 2.05, about 2.06, about 2.07, about 2.08, about 2.09, about 2.10, about 2.11, about 2.12, about 2.13, about 2.14, about 2.15, about 2.16, about 2.17, about 2.18, 2.19, about 2.20, about 2.21, about 2.22, about 2.23, about 2.24, about 2.25, about 2.26, about 2.27, about 2.28, about 2.29, about 2.30, about 2.31, about 2.32, about 2.33, about 2.34, about 2.35, about 2.36, about 2.37, about 2.38, about 2.39, about 2.40, about 2.41, about 2.42, about 2.43, about 2.44, about 2.45, about 2.46, about 2.47, about 2.48, about 2.49, about 2.50, about 2.51, about 2.52, about 2.53, about 2.54, about 2.55, about 2.56, about 2.57, about 2.58, about 2.59, about 2.60, and about 2.61.

In some embodiments, the second refractive index is greater than 2.61. In some embodiments, the second refractive index is between 1.7 and 3.4.

Referring to FIG. 15, in some embodiments, the second refractive index is determined using Rytov's formula n_{NP}=\sqrt{γ_{c}n_{c}²+γₗnₗ²}, where γ_{c} is the volume fraction of the substantially inorganic core, γₗ is the volume fraction of the substantially organic shell, n_{NP} is the refractive index of the nanoparticle, n_{c} is the refractive index of the substantially inorganic core, and nₗ is the refractive index of the substantially organic shell.

For example, in some embodiments, given n_{c}=2.5, nₗ=1.5, r₁=5 nm, and l=0.5 nm, then γ_{c}=0.75, γₗ=0.25, and n_{NP}=2.29. In some alternative embodiments, given n_{c}=2.5, nₗ=1.5, r₁=5 nm, and l=0.75 nm, then γ_{c}=0.66, γₗ=0.34, and n_{NP}=2.21. In some alternative embodiments, given n_{c}=2.5, nₗ=1.5, r₁=5 nm, and l=1 nm, then γ_{c}=0.58, γₗ=0.42, and n_{NP}=2.14. Further embodiments of nanoparticle refractive index calculations are provided in Table 25 below.

In some embodiments, the nanoparticles component is provided as commercially available nanoparticles. In some embodiments, the nanoparticles component is synthesized by various methods. Specifically, in some embodiments, the nanoparticles component is synthesized such that the resulting nanoparticles comprise the desired parameters disclosed herein (e.g., refractive index, size, functional groups, etc.). Non-limiting embodiments of nanoparticles components are provided below in the Examples in Table 26.

In some embodiments, the nanoparticles component in combination with the base resin component reduces shrinkage of the NIL precursor material after curing.

(c) Applications of NIL Precursor Materials Formulations

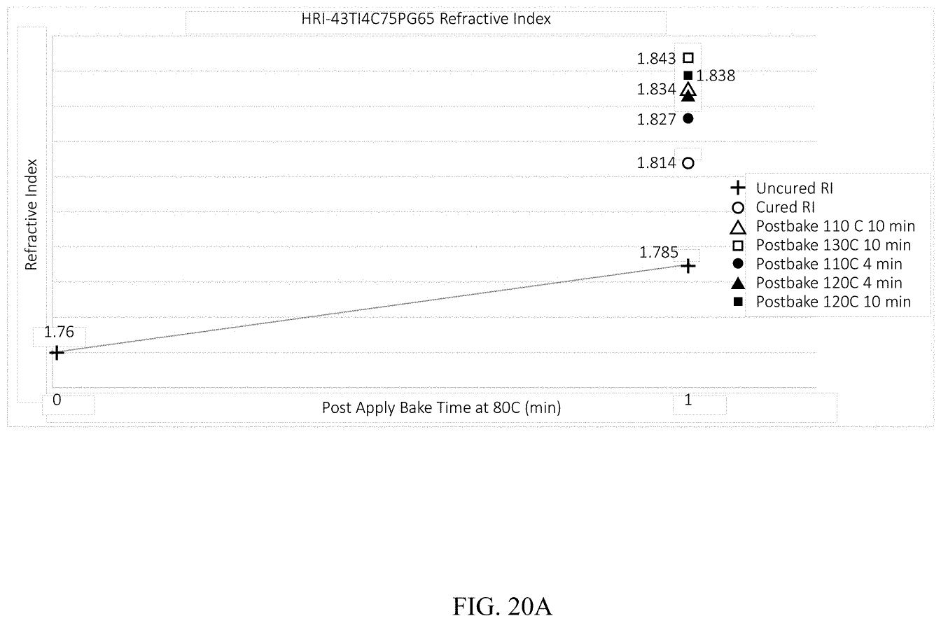

In some embodiments, the NIL precursor material is applied or deposited for NIL molding by, for example, spin-coating, lamination, and/or ink injection on a substrate or waveguide to form a NIL material layer (e.g., a film). In some embodiments, the NIL material layer undergoes heat treatment prior to curing (e.g., post-apply bake). In some embodiments, the NIL material layer is molded (e.g., imprinted, using any of the NIL processes described herein) and/or cured (e.g., by light) to form a NIL-molded nanostructure, such as a slanted surface-relief grating. In some embodiments, the cured NIL material undergoes heat treatment after curing (e.g., post-exposure bake). Specific embodiments of post-apply bake and post-exposure bake processes are detailed below in the Examples section and in FIGS. 19, 20A, 20B, and 21.

The disclosure also provides a cured NIL material comprising a substantially cured resin component and a nanoparticles component ranging from 45 wt. % to 90 wt. % (weight percentage) of the cured NIL material, where the cured NIL material has a third refractive index, and where the cured material is made by exposing to a light source any of the NIL precursor materials described herein. In some embodiments, the nanoparticles component ranges from 45 wt. % to 85 wt. %, from 45 wt. % to 80 wt. %, or from 45 wt. % to 75 wt. % of the cured NIL material. In some embodiments, the nanoparticles component ranges from 60 wt. % to 80 wt. % of the cured NIL material. In some embodiments, the nanoparticles component ranges from 60 wt. % to 70 wt. % of the cured NIL material. In some embodiments, the nanoparticles component is about 45 wt. %, about 46 wt. %, about 47 wt. %, about 48 wt. %, about 49 wt. %, about 50 wt. %, about 51 wt. %, about 52 wt. %, about 53 wt. %, about 54 wt. %, about 55 wt. %, about 56 wt. %, about 57 wt. %, about 58 wt. %, about 59 wt. %, about 60 wt. %, about 61 wt. %, about 62 wt. %, about 63 wt. %, about 64 wt. %, about 65 wt. %, about 66 wt. %, about 67 wt. %, about 68 wt. %, about 69 wt. %, about 70 wt. %, about 71 wt. %, about 72 wt. %, about 73 wt. %, about 74 wt. %, or about 75 wt. % of the cured NIL material.

In some embodiments, the curing is achieved via a process where the base resin component is crosslinked and/or polymerized, and the curing causes the base resin component to undergo shrinkage. In some such embodiments, the extent of shrinkage is modulated by the formulation of the base resin such that, for example, a base resin component comprising smaller molecules results in increased shrinkage, and a base resin component comprising larger molecules (e.g., oligomers) and/or fillers (e.g., nanoparticles) results in decreased shrinkage. As a result, in some embodiments, the weight percentage of the nanoparticles component to the cured NIL material after curing is different from the weight percentage of the nanoparticles component to the NIL precursor material prior to curing. In some alternative embodiments, the weight percentage of the nanoparticles component to the cured NIL material is the same as the weight percentage of the nanoparticles component to the NIL precursor material before curing.

In some embodiments, exposing the NIL precursor material to a light source (e.g., a UV light source) causes a photocatalytic effect that degrades the base resin component (e.g., a base resin component comprising either a low refractive index or a high refractive index). For example, in some embodiments, photocatalytic degradation occurs in a NIL precursor material loaded with TiO₂ nanoparticles by a mechanism where the absorption of UV light by TiO₂ nanoparticles generates radicals that can attack the organic backbone of a cured organic polymer. In some embodiments, the refractive index of the NIL precursor material is higher than the third refractive index of the cured NIL material.

In some embodiments, the base resin material, the functional group of the base resin material, the nanoparticle material, and/or the loading (e.g., wt. %) of the nanoparticles can be selected to tune the refractive index of the cured NIL material. In some embodiments, the third refractive index (e.g., of the cured NIL material) is between about 1.7 and about 3.4, between about 1.75 and about 3.2, or between about 1.75 and about 3.1, depending on the NIL material composition. For example, in some embodiments, the third refractive index is greater than or about 1.78, greater than or about 1.8, greater than or about 1.85, greater than or about 1.9, greater than or about 1.95, greater than or about 2, or greater.

In some embodiments, the third refractive index ranges from 1.75 to 2.00. In some embodiments, the third refractive index is selected from about 1.75, about 1.76, about 1.77, about 1.78, about 1.79, about 1.80, 1.81, about 1.82, about 1.83, about 1.84, about 1.85, about 1.86, about 1.87, about 1.88, about 1.89, about 1.90, about 1.91, about 1.92, about 1.93, about 1.94, about 1.95, about 1.96, about 1.97, about 1.98, about 1.99, and about 2.00.

In some embodiments, the third refractive index (e.g., of the cured NIL material) after curing is different from the refractive index of the NIL precursor material prior to curing. In some alternative embodiments, the refractive index of the cured NIL material is the same as the refractive index of the NIL precursor material before curing.

The disclosure also provides a NIL grating comprising any of the cured NIL materials described herein. In some embodiments, the third refractive index ranges from 1.75 to 2.00. In some embodiments, the NIL grating is formed using any of the methods described herein and/or depicted in FIGS. 5-9.

In some embodiments, a NIL-molded grating having a refractive index greater than 1.75, greater than 1.78, greater than 1.8, greater than 1.85, greater than 1.9, greater than 1.93, greater than 1.95, or greater than 2 is obtained by NIL molding a NIL material that includes a base resin having a refractive index greater than 1.55, greater than 1.58, or greater than 1.6 and a nanoparticle loading greater than about 45%. In some embodiments, the base resin may include a refractive index ranging from 1.58 to 1.77, from 1.58 to 1.7, from 1.58 to 1.65, from 1.6 to 1.7, or from 1.6 to 1.65. In some embodiments, the nanoparticle loading ranges from 45% to 90%, from 45% to 85%, from 45% to 80%, from 45% to 75%, from 45% to 70%, from 45% to 65%, from 45% to 60%, from 45% to 55%, or from 45% to 50%.

In some embodiments, an NIL-molded grating having a refractive index greater than 1.78, greater than 1.8, greater than 1.85, greater than 1.9, greater than 1.93, greater than 1.95, or greater than 2 is obtained by NIL molding a NIL material that includes an organic base resin and a nanoparticle loading ranging from 45% to 90%. In some embodiments, the nanoparticle loading is greater than or about 45%. For example, the nanoparticle loading ranges from 45% to 90%, from 45% to 85%, from 45% to 80%, from 45% to 75%, from 45% to 70%, from 45% to 65%, from 45% to 60%, from 45% to 55%, or from 45% to 50%.

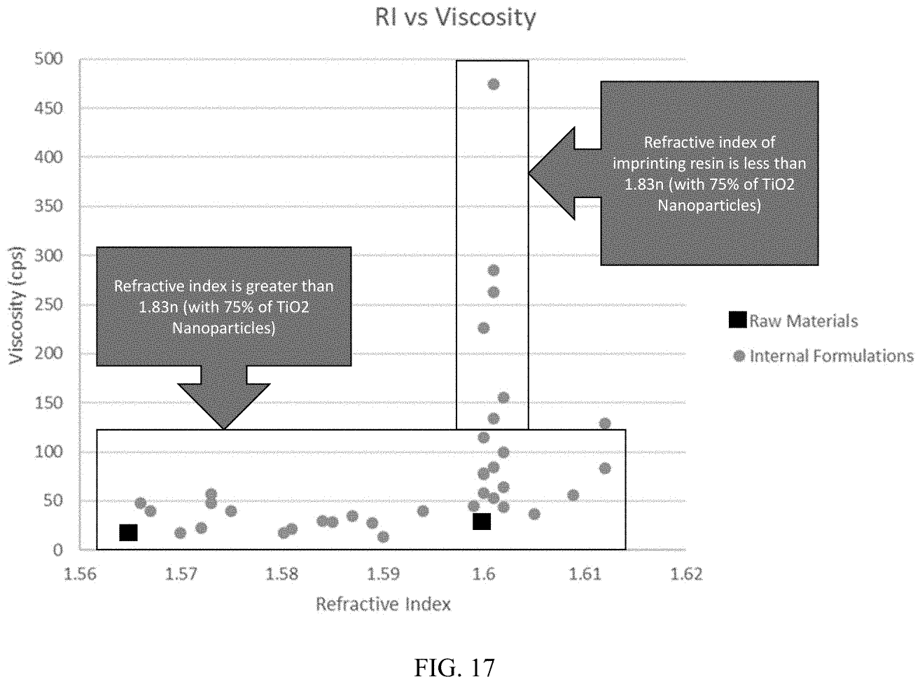

In some embodiments, the grating is a slanted grating or a non-slanted grating. In some embodiments, the grating has a duty cycle ranging from 10% to 90%. For example, FIGS. 16A and 16B illustrate a slanted grating and a non-slanted grating, respectively. Furthermore, as illustrated in FIG. 5 and FIG. 16A, the duty cycle is a ratio between the width of a ridge (e.g., W) and the grating period (e.g., p). In some embodiments, the grating has a small or large duty cycle (e.g., below 30% or greater than 70%). In some embodiments, the grating has a duty cycle of less than 10%. In some embodiments, the grating has a duty cycle ranging from 30% to 90%. In some embodiments, the grating has a duty cycle ranging from 35% to 90%. In some embodiments, the grating has a duty cycle of greater than 90%.

In some embodiments, the grating period is between 100 nm and 1 μm. In some embodiments, the grating period ranges between 100 and 300 nm, 300 and 500 nm, 500 and 700 nm, or between 700 nm and 1 μm. In some embodiments, the grating period is less than 100 nm or greater than 1 μm.

In some embodiments, a slanted grating comprises at least one slant angle ranging from more than 0° to 70°. As illustrated in FIG. 5 and FIG. 16B, the slant angle (e.g., “Slant”) is determined using the angle for the leading edge α and the angle for the trailing edge β, using the formula Slant=arctan[tan(α)+tan(β))*0.5]. In some embodiments, the NIL-molded grating has a slant angle that is greater than 10°, 20°, 30°, 40°, 50°, 60°, 70°, or higher. In some embodiments, a slanted grating comprises at least one slant angle greater than 30°. In some embodiments, a slanted grating comprises at least one slant angle greater than 35°.

In some embodiments, the grating has a depth greater than 100 nm. In some embodiments, the grating has a depth ranging between 10 and 50 nm, between 50 and 100 nm, between 100 and 200 nm, between 200 and 500 nm, between 500 nm and 1 μm, or higher than 1 μm.

In some embodiments, the grating has an aspect ratio greater than 3:1. In some embodiments, the grating has an aspect ratio of about 1:1, about 4:3, about 3:2, about 16:9, about 2:1, about 21:9, about 3:1, about 4:1, about 5:1, about 6:1, about 7:1, about 8:1, about 9:1, or about 10:1.

In some embodiments, the NIL materials disclosed herein are used to fabricate other slanted or non-slanted structures. In some embodiments, the grating is assessed for imprintability and/or optical performance (e.g. haze, RI, absorption of resins, etc.) after spin-coating, curing, and/or delamination.

In some embodiments, the NIL precursor materials disclosed herein are used to fabricate surface-relief structures (e.g., slanted or non-slanted surface-relief gratings), where at least one component of the surface-relief structure such as the base resin component is removed by a process and substituted for another material. In some such embodiments, the substitution of the base resin component after the initial fabrication of the surface-relief grating allows for the modulation of the third refractive index based on the refractive properties of the substituted material and provides greater flexibility in the method of forming the NIL grating.

The disclosure also provides an optical component comprising any of the NIL gratings described herein. In some embodiments, the optical components include a diffractive optical element (e.g., a surface-relief grating) that allows light of projected images to be coupled into or out of the waveguide for optical display.

The disclosure also provides a method of modulating the third refractive index of the cured NIL material described herein, the method comprising modulating the first refractive index of the base resin component of the NIL precursor material. In some embodiments, decreasing the first refractive index of the base resin component of the NIL precursor material results in an increase of the third refractive index of the cured NIL material. In some embodiments, the refractive index of a compound is determined using the formula: RI=RIᵣₑₛᵢₙ*Vᵣₑₛᵢₙ %+RI_{NP}*V_{NP %}.

The disclosure also provides a method of forming any of the NIL gratings described herein, the method comprising imprinting the NIL precursor material using a NIL process.

The disclosure also provides a method of forming the optical component described herein, the method comprising imprinting the NIL precursor material using a NIL process. In some embodiments, the method of forming the NIL grating and/or the optical component described herein comprises any of the NIL processes described in the present disclosure and/or illustrated in FIGS. 6-9.

### EXAMPLES

Further described below are some examples of the NIL materials having various base resins and varying nanoparticle loading percentages. The examples are described for illustration purposes only and are not intended to be limiting. A person skilled in the art would understand that the composition of the various NIL materials may be varied and/or modified while achieving desired properties of the NIL materials, such as improved moldability or imprintability of the NIL material mixture, improved refractive index of the cured NIL material, etc. In some implementations, some components of the various NIL materials may be omitted or substituted, while additives or additional components may be included to modify the properties of the NIL material mixture and/or the cured NIL material.

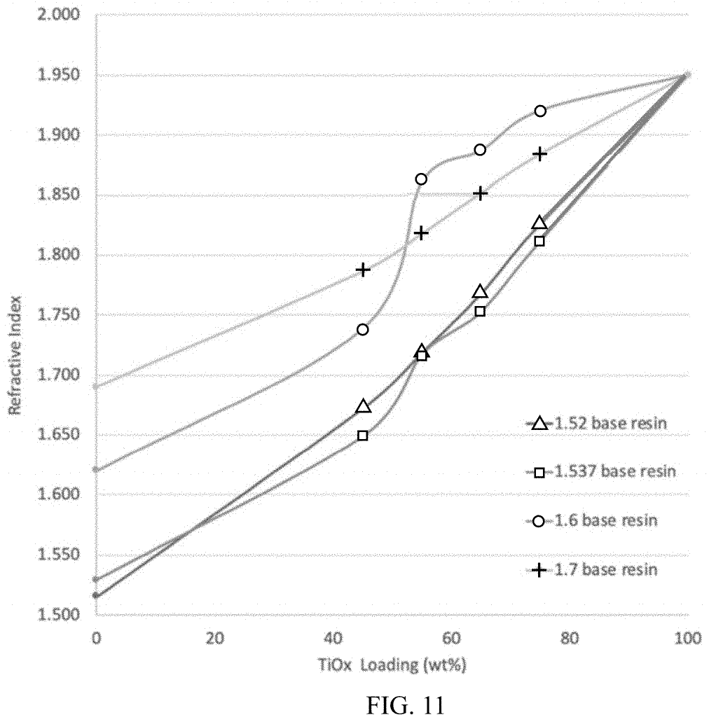

FIGS. 10A-10D are plots showing the NIL material refractive index versus light wavelength for various NIL materials having different base resin materials and varying nanoparticle loadings. The NIL material refractive indices refer to the refractive indices of the cured NIL materials. The nanoparticles of the various NIL materials plotted in FIGS. 10A-10D are titanium oxide nanoparticles, such as titanium oxide nanoparticles dispersed in PGMEA provided by Pixelligent® under the part number PTPG-2A-50-PGA. The varying nanoparticle loadings, i.e., 45%, 55%, 65%, and 75%, refer to the weight percentage (wt. %) of the nanoparticles in the cured NIL material (i.e., without PGMEA solvent).

FIG. 10A is the plot for various NIL materials each having a base resin material that has a refractive index of about 1.7. The base resin material used in the NIL materials plotted in FIG. 10A includes thianthrene diacrylate, such as thianthrene diacrylate provided by TCI America. FIG. 10B is the plot for various NIL materials each having a base resin material that has a refractive index of about 1.6. The base resin material used in the NIL materials plotted in FIG. 10B includes a combination of base resin materials, such as bisfluorene and ortho-phenyl phenoxyl ethyl acrylate (OPPEA) provided by Miwon Specialty Chemical Co., Ltd. under the part number of Miramer HR6042 and biphenylmethyl acrylate (BPMA) provided by Miwon Specialty Chemical Co., Ltd. under the part number of Miramer 1192. FIG. 10C is the plot for various NIL materials each having a base resin material that has a refractive index of about 1.537. The base resin material used in the NIL materials plotted in FIG. 10C includes, e.g, Ormoclad® provided by MicroChem Corp. FIG. 10D is the plot for various NIL materials each having a base resin material that has a refractive index of about 1.52. The base resin material used in the NIL materials plotted in FIG. 10D includes, e.g., Ormocomp® provided by MicroChem Corp. The various NIL materials of FIGS. 10A-10D each further include a photo radical generator (PRG), such as a 50/50 blend of diphenyl(2,4,6 trimethylbenzoyl)phosphine oxide and 2-hydroxy-2-methylpropiophenone provided by Sigma-Aldrich Corp.

Tables 1A-16B below list the composition or formulation of the various NIL materials of FIGS. 10A-10D. In particular, Tables 1A-4B below list the composition or formulation of the various NIL materials of FIG. 10A. Tables 1A and 1B list the composition of the NIL material having 75 wt. % of titanium oxide nanoparticle loading, i.e., the cured NIL material (without PMGEA solvent) including 75 wt. % titanium oxide nanoparticles. Tables 2A and 2B list the composition of the NIL material having 65 wt. % of titanium oxide nanoparticle loading, i.e., the cured NIL material (without PMGEA solvent) including 65 wt. % titanium oxide nanoparticles. Tables 3A and 3B list the composition of the NIL material having 55 wt. % of titanium oxide nanoparticle loading, i.e., the cured NIL material (without PMGEA solvent) including 55 wt. % titanium oxide nanoparticles. Tables 4A and 4B list the composition of the NIL material having 45 wt. % of titanium oxide nanoparticle loading, i.e., the cured NIL material (without PMGEA solvent) including 45 wt. % titanium oxide nanoparticles. Because the titanium oxide nanoparticles are dispersed in PMGEA solvent, and mixed with other component materials of the NIL material in additional PMGEA solvent, Tables 1A, 2A, 3A, and 4A list the compositions of the various NIL materials in weight percentage (wt. %) pre-mixing, whereas Tables 1B, 2B, 3B, and 4B list the compositions of the various NIL materials in weight percentage (wt. %) after being mixed by combining the added PMGEA solvent and the PMGEA solvent in the nanoparticles.

Tables 5A-8B list the composition or formulation of the various NIL materials of FIG. 10B. Similar to Tables 1A-4B, Tables 5A-5B, Tables 6A-6B, Tables 7A-7B, and Tables 8A-8B list the compositions of various NIL materials having 75 wt. %, 65 wt. %, 55 wt. %, and 45 wt. % of titanium oxide nanoparticle loading, respectively. Tables 5A, 6A, 7A, and 8A list the compositions of the various NIL materials in weight percentage (wt. %) pre-mixing, and Tables 5B, 6B, 7B, and 8B list the compositions of the various NIL materials in weight percentage (wt. %) post-mixing.

Tables 9A-12B list the composition or formulation of the various NIL materials of FIG. 10C. Tables 9A-9B, Tables 10A-10B, Tables 11A-11B, and Tables 12A-12B list the compositions of various NIL materials having 75 wt. %, 65 wt. %, 55 wt. %, and 45 wt. % of titanium oxide nanoparticle loading, respectively. Tables 9A, 10A, 11A, and 12A list the compositions of the various NIL materials in weight percentage (wt. %) pre-mixing, and Tables 9B, 10B, 11B, and 12B list the compositions of the various NIL materials in weight percentage (wt. %) post-mixing.

Tables 13A-16B list the composition or formulation of the various NIL materials of FIG. 10D. Tables 13A-13B, Tables 14A-14B, Tables 15A-15B, and Tables 16A-16B list the compositions of various NIL materials having 75 wt. %, 65 wt. %, 55 wt. %, and 45 wt. % of titanium oxide nanoparticle loading, respectively. Tables 13A, 14A, 15A, and 16A list the compositions of the various NIL materials in weight percentage (wt. %) pre-mixing, and Tables 13B, 14B, 15B, and 16B list the compositions of the various NIL materials in weight percentage (wt. %) post-mixing.

TABLE 1A
1^{st} exemplary nanoimprint lithography (NIL) material

| Formu- | | Amount (wt. %) | |
|---|---|---|---|
| lation | | | Exam- |
| ID | Composition | Range | ple |
| PW | Thianthrene diacrylate | 3-40 | 5.20 |
| 1.7-T75 | Photo radical generator (PRG) | 0.2-8 | 0.40 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 60.59 |
| | acetate) | | |
| | Titanium oxide blend | 5-90 | 33.81 |
| | (50 wt. % Titanium oxide nanoparticles | | |
| | in PGMEA) | | |

TABLE 1B
1^{st} exemplary nanoimprint lithography (NIL) material

| | | | | PRG to Resin | | (Resin + PRG) to | |
|---|---|---|---|---|---|---|---|
| Formulation | | Amount (wt. %) | | wt % Ratio | | Nanoparticles wt % Ratio | |
| ID | Composition | Range | Example | Range | Example | Range | Example |
| PW 1.7-T75 | Resin + PRG | 3-10 | 5.60 | 1:99 | 7.08:92.92 | 10:90 | 24.88:75.12 |
| | Titanium oxide | 10-22 | 16.91 | to 20:80 | | to 40:60 | |
| | PGMEA | 40-95 | 77.50 | | | | |

TABLE 2A
2^{nd} exemplary nanoimprint lithography (NIL) material

| Formu- | | Amount (wt. %) | |
|---|---|---|---|
| lation | | | Exam- |
| ID | Composition | Range | ple |
| PW | Thianthrene diacrylate | 3-40 | 6.99 |
| 1.7-T65 | Photo radical generator (PRG) | 0.2-8 | 0.53 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 64.69 |
| | acetate) | | |
| | Titanium oxide blend | 5-90 | 27.80 |
| | (50 wt. % Titanium oxide nanoparticles | | |
| | in PGMEA) | | |

TABLE 2B
2^{nd} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.7-T65 | Resin + PRG | 4-13 | 7.51 | 1:99 | 7.03:92.97 | 20:80 | 35.09:64.91 |
| | Titanium oxide | 8-20 | 13.90 | to 20:80 | | to 50:50 | |
| | PGMEA | 40-95 | 78.59 | | | | |

TABLE 3A
3^{rd} exemplary nanoimprint lithography (NIL) material

| Formu- | | Amount (wt. %) | |
|---|---|---|---|
| lation | | | Exam- |
| ID | Composition | Range | ple |
| PW | Thianthrene diacrylate | 3-40 | 8.70 |
| 1.7-T55 | Photo radical generator (PRG) | 0.2-8 | 0.64 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 68.51 |
| | acetate) | | |
| | Titanium oxide blend | 5-90 | 22.15 |
| | (50 wt. % Titanium oxide nanoparticles | | |
| | in PGMEA) | | |

TABLE 3B
3^{rd} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.7-T55 | Resin + PRG | 5-15 | 9.34 | 1:99 | 6.87:93.13 | 30:70 | 45.76:54.24 |
| | Titanium oxide | 5-18 | 11.07 | to 20:80 | | to 60:40 | |
| | PGMEA | 40-95 | 79.58 | | | | |

TABLE 4A
4^{th} exemplary nanoimprint lithography (NIL) material

| Formu- | | Amount (wt. %) | |
|---|---|---|---|
| lation | | | Exam- |
| ID | Composition | Range | ple |
| PW | Thianthrene diacrylate | 3-40 | 10.08 |
| 1.7-T45 | Photo radical generator (PRG) | 0.2-8 | 0.77 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 71.90 |
| | acetate) | | |
| | Titanium oxide blend | 5-90 | 17.26 |
| | (50 wt. % Titanium oxide nanoparticles | | |
| | in PGMEA) | | |

TABLE 4B
4^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.7-T45 | Resin + PRG | 5-16 | 10.84 | 1:99 | 7.07:92.93 | 45:55 | 55.68:44.23 |
| | Titanium oxide | 4-14 | 8.63 | to 20:80 | | to 70:30 | |
| | PGMEA | 40-95 | 80.53 | | | | |

TABLE 5A
5^{th} exemplary nanoimprint lithography (NIL) material

| Formu- | | Amount (wt. %) | |
|---|---|---|---|
| lation | | | Exam- |
| ID | Composition | Range | ple |
| PW | Miramer HR6042 | 1.5-20 | 2.60 |
| 1.6-T75 | Miramer 1192 | 1.5-20 | 2.60 |
| | Photo radical generator (PRG) | 0.2-8 | 0.40 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 60.24 |
| | acetate) | | |
| | Titanium oxide blend | 5-90 | 34.15 |
| | (50 wt. % Titanium oxide nanoparticles | | |
| | in PGMEA) | | |

TABLE 5B
5^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.6-T75 | Resin + PRG | 3-10 | 5.61 | 1:99 | 7.14:92.86 | 10:90 | 24.73:75.27 |
| | Titanium oxide | 10-22 | 17.08 | to 20:80 | | to 40:60 | |
| | PGMEA | 40-95 | 77.31 | | | | |

TABLE 6A
6^{th} exemplary nanoimprint lithography (NIL) material

| Formu- | | Amount (wt. %) | |
|---|---|---|---|
| lation | | | Exam- |
| ID | Composition | Range | ple |
| PW | Miramer HR6042 | 1.5-20 | 3.49 |
| 1.6-T65 | Miramer 1192 | 1.5-20 | 3.49 |
| | Photo radical generator (PRG) | 0.2-8 | 0.54 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 64.42 |
| | acetate) | | |
| | Titanium oxide blend | 5-90 | 28.07 |
| | (50 wt. % Titanium oxide nanoparticles | | |
| | in PGMEA) | | |

TABLE 6B
6^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.6-T65 | Resin + PRG | 4-13 | 7.51 | 1:99 | 7.13:92.87 | 20:80 | 34.87:65.13 |
| | Titanium oxide | 8-20 | 14.03 | to 20:80 | | to 50:50 | |
| | PGMEA | 40-95 | 78.45 | | | | |

TABLE 7A
7^{th} exemplary nanoimprint lithography (NIL) material

| Formu- | | Amount (wt. %) | |
|---|---|---|---|
| lation | | | Exam- |
| ID | Composition | Range | ple |
| PW | Miramer HR6042 | 1.5-20 | 4.32 |
| 1.6-T55 | Miramer 1192 | 1.5-20 | 4.32 |
| | Photo radical generator (PRG) | 0.2-8 | 0.64 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 68.14 |
| | acetate) | | |
| | Titanium oxide blend | 5-90 | 22.59 |
| | (50 wt. % Titanium oxide nanoparticles | | |
| | in PGMEA) | | |

TABLE 7B
7^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.6-T55 | Resin + PRG | 5-15 | 9.27 | 1:99 | 6.93:93.07 | 30:70 | 45.09:54.91 |
| | Titanium oxide | 5-18 | 11.29 | to 20:80 | | to 60:40 | |
| | PGMEA | 40-95 | 79.43 | | | | |

TABLE 8A
8^{th} exemplary nanoimprint lithography (NIL) material

| Formu- | | Amount (wt. %) | |
|---|---|---|---|
| lation | | | Exam- |
| ID | Composition | Range | ple |
| PW | Miramer HR6042 | 1.5-20 | 5.02 |
| 1.6-T45 | Miramer 1192 | 1.5-20 | 5.02 |
| | Photo radical generator (PRG) | 0.2-8 | 0.77 |
| | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 71.72 |
| | acetate) | | |
| | Titanium oxide blend | 5-90 | 17.46 |
| | (50 wt. % Titanium oxide nanoparticles | | |
| | in PGMEA) | | |

TABLE 8B
8^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.6-T45 | Resin + PRG | 5-16 | 10.82 | 1:99 | 7.15:92.85 | 45:55 | 55.35:44.65 |
| | Titanium oxide | 4-14 | 8.73 | to 20:80 | | to 70:30 | |
| | PGMEA | 40-95 | 80.45 | | | | |

TABLE 9A
9^{th} exemplary nanoimprint lithography (NIL) material

| Formu- | | Amount (wt. %) | |
|---|---|---|---|
| lation | | | Exam- |
| ID | Composition | Range | ple |
| PW | Ormoclad | 3-40 | 5.23 |
| 1.537- | Photo radical generator (PRG) | 0.2-8 | 0.43 |
| T75 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 60.21 |
| | acetate) | | |
| | Titanium oxide blend | 5-90 | 34.13 |
| | (50 wt. % Titanium oxide nanoparticles | | |
| | in PGMEA) | | |

TABLE 9B
9^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.537- | Resin + PRG | 3-10 | 5.66 | 1:99 | 7.52:92.48 | 10:90 | 24.90:75.10 |
| T75 | Titanium oxide | 10-22 | 17.07 | to 20:80 | | to 40:60 | |
| | PGMEA | 40-95 | 77.27 | | | | |

TABLE 10A
10^{th} exemplary nanoimprint lithography (NIL) material

| Formu- | | Amount (wt. %) | |
|---|---|---|---|
| lation | | | Exam- |
| ID | Composition | Range | ple |
| PW | Ormoclad | 3-40 | 7.00 |
| 1.537- | Photo radical generator (PRG) | 0.2-8 | 0.55 |
| T65 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 64.28 |
| | acetate) | | |
| | Titanium oxide blend | 5-90 | 28.18 |
| | (50 wt. % Titanium oxide nanoparticles | | |
| | in PGMEA) | | |

TABLE 10B
10^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.537- | Resin + PRG | 4-13 | 7.54 | 1:99 | 7.23:92.77 | 20:80 | 34.86:65.14 |
| T65 | Titanium oxide | 8-20 | 14.09 | to 20:80 | | to 50:50 | |
| | PGMEA | 40-95 | 78.37 | | | | |

TABLE 11A
11^{th} exemplary nanoimprint lithography (NIL) material

| Formu- | | Amount (wt. %) | |
|---|---|---|---|
| lation | | | Exam- |
| ID | Composition | Range | ple |
| PW | Ormoclad | 3-40 | 8.47 |
| 1.537- | Photo radical generator (PRG) | 0.2-8 | 0.74 |
| T55 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 68.65 |
| | acetate) | | |
| | Titanium oxide blend | 5-90 | 22.13 |
| | (50 wt. % Titanium oxide nanoparticles | | |
| | in PGMEA) | | |

TABLE 11B
11^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.537- | Resin + PRG | 5-15 | 9.21 | 1:99 | 8.04:91.96 | 30:70 | 45.43:54.57 |
| T55 | Titanium oxide | 5-18 | 11.07 | to 20:80 | | to 60:40 | |
| | PGMEA | 40-95 | 79.72 | | | | |

TABLE 12A
12^{th} exemplary nanoimprint lithography (NIL) material

| Formu- | | Amount (wt. %) | |
|---|---|---|---|
| lation | | | Exam- |
| ID | Composition | Range | ple |
| PW | Ormoclad | 3-40 | 10.07 |
| 1.537- | Photo radical generator (PRG) | 0.2-8 | 0.78 |
| T45 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 71.66 |
| | acetate) | | |
| | Titanium oxide blend | 5-90 | 17.49 |
| | (50 wt. % Titanium oxide nanoparticles | | |
| | in PGMEA) | | |

TABLE 12B
12^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.537- | Resin + PRG | 5-16 | 10.85 | 1:99 | 7.19:92.81 | 45:55 | 55.39:44.61 |
| T45 | Titanium oxide | 4-14 | 8.74 | to 20:80 | | to 70:30 | |
| | PGMEA | 40-95 | 80.40 | | | | |

TABLE 13A
13^{th} exemplary nanoimprint lithography (NIL) material

| Formu- | | Amount (wt. %) | |
|---|---|---|---|
| lation | | | Exam- |
| ID | Composition | Range | ple |
| PW | Ormocomp | 3-40 | 5.18 |
| 1.52- | Photo radical generator (PRG) | 0.2-8 | 0.39 |
| T75 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 59.47 |
| | acetate) | | |
| | Titanium oxide blend | 5-90 | 34.96 |
| | (50 wt. % Titanium oxide nanoparticles | | |
| | in PGMEA) | | |

TABLE 13B
13^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.52- | Resin + PRG | 3-10 | 5.57 | 1:99 | 6.96:93.04 | 10:90 | 24.17:75.83 |
| T75 | Titanium oxide | 10-22 | 17.48 | to 20:80 | | to 40:60 | |
| | PGMEA | 40-95 | 76.95 | | | | |

TABLE 14A
14^{th} exemplary nanoimprint lithography (NIL) material

| Formu- | | Amount (wt. %) | |
|---|---|---|---|
| lation | | | Exam- |
| ID | Composition | Range | ple |
| PW | Ormocomp | 3-40 | 7.03 |
| 1.52- | Photo radical generator (PRG) | 0.2-8 | 0.57 |
| T65 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 64.37 |
| | acetate) | | |
| | Titanium oxide blend | 5-90 | 28.03 |
| | (50 wt. % Titanium oxide nanoparticles | | |
| | in PGMEA) | | |

TABLE 14B
14^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.52- | Resin + PRG | 4-13 | 7.60 | 1:99 | 7.51:92.49 | 20:80 | 35.17:64.83 |
| T65 | Titanium oxide | 8-20 | 14.01 | to 20:80 | | to 50:50 | |
| | PGMEA | 40-95 | 78.39 | | | | |

TABLE 15A
15^{th} exemplary nanoimprint lithography (NIL) material

| Formu- | | Amount (wt. %) | |
|---|---|---|---|
| lation | | | Exam- |
| ID | Composition | Range | ple |
| PW | Ormocomp | 3-40 | 8.64 |
| 1.52- | Photo radical generator (PRG) | 0.2-8 | 0.66 |
| T55 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 67.92 |
| | acetate) | | |
| | Titanium oxide blend | 5-90 | 22.78 |
| | (50 wt. % Titanium oxide nanoparticles | | |
| | in PGMEA) | | |

TABLE 15B
15^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.52- | Resin + PRG | 5-15 | 9.30 | 1:99 | 7.07:92.93 | 30:70 | 44.95:55.05 |
| T55 | Titanium oxide | 5-18 | 11.39 | to 20:80 | | to 60:40 | |
| | PGMEA | 40-95 | 79.31 | | | | |

TABLE 16A
16^{th} exemplary nanoimprint lithography (NIL) material

| Formu- | | Amount (wt. %) | |
|---|---|---|---|
| lation | | | Exam- |
| ID | Composition | Range | ple |
| PW | Ormocomp | 3-40 | 10.09 |
| 1.52- | Photo radical generator (PRG) | 0.2-8 | 0.76 |
| T45 | (Diphenyl(2,4,6 trimethylbenzoyl)phosphine | | |
| | oxide and 2-Hydroxy-2- | | |
| | methylpropiophenone 50/50 blend) | | |
| | PGMEA (Propylene glycol methyl ether | 0-90 | 71.30 |
| | acetate) | | |
| | Titanium oxide blend | 5-90 | 18 |
| | (50 wt. % Titanium oxide nanoparticles | | |
| | in PGMEA) | | |

TABLE 16B
16^{th} exemplary nanoimprint lithography (NIL) material

| | | | | | | (Resin + PRG) to | |
|---|---|---|---|---|---|---|---|
| Formulation | | Amount (wt. %) | | PRG to Resin wt % Ratio | | Nanoparticles wt % Ratio | |
| ID | Composition | Range | Example | Range | Example | Range | Example |
| PW 1.52- | Resin + PRG | 5-16 | 10.85 | 1:99 | 6.97:93.03 | 45:55 | 54.85:45.15 |
| T45 | Titanium oxide | 4-14 | 8.93 | to 20:80 | | to 70:30 | |
| | PGMEA | 40-95 | 80.23 | | | | |

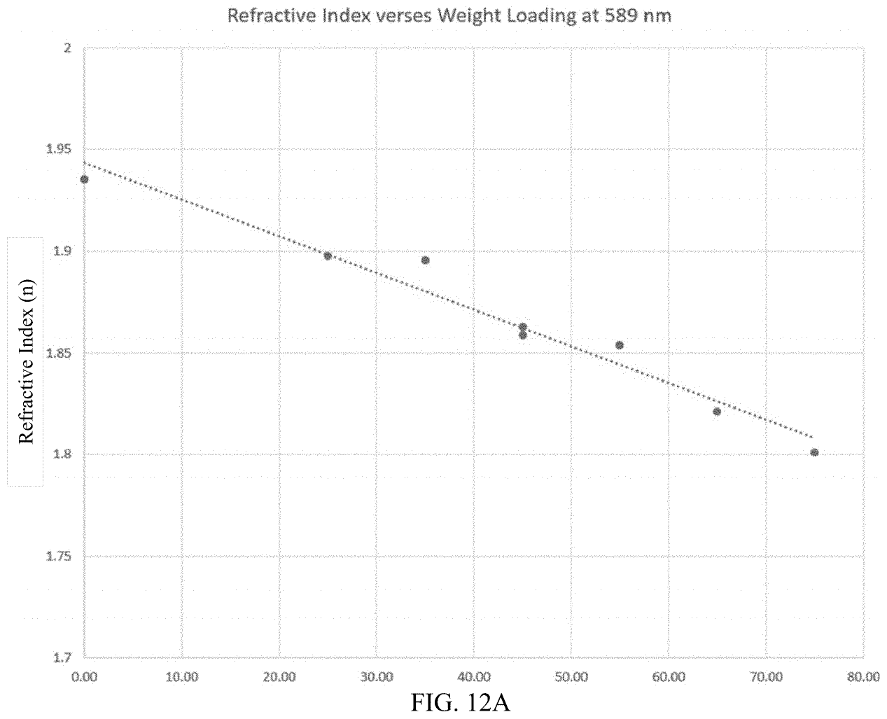

FIG. 11 is a plot showing the NIL material refractive index for visible light at 589 nm versus nanoparticle loading for the various NIL materials of FIGS. 10A-10D and Tables 1A-16B. Generally, an increase in the refractive index of the base resin may correspond to an increase in the refractive index of the cured NIL material. However, in some embodiments, for selected base resin materials, when combined with selected nanoparticle loading percentages, a decrease in the base resin refractive index may correspond to an increase in the refractive index of the cured NIL material. For example, as shown in FIG. 11, when the titanium oxide nanoparticle weight percentage exceeds 45%, the cured NIL material having the base resin with a refractive index of 1.6 may exhibit a higher refractive index than the cured NIL material having the base resin with a refractive index of 1.7. In other words, a decrease in the base resin refractive index (e.g., from 1.7 to 1.6) may correspond to an increase in the refractive index of the cured NIL material. One possible explanation for such correlation may be that the base resin having the 1.6 refractive index may interact with the ligands of the nanoparticles in a manner that may promote a more homogenous mixing of the base resin and the nanoparticles which may lead to an increased refractive index of the cured NIL material as compared to the cured NIL material including the base resin having the 1.7 refractive index.

Tables 17-21 below list various compositions for various NIL materials that include 75% nanoparticle loading where the nanoparticles includes a combination of titanium oxide nanoparticles and zirconium oxide nanoparticles. The ratio of the zirconium oxide nanoparticle loading to the titanium oxide nanoparticle loading may range from 7:1 to 1:3, from 6:1 to 1:3, from 5:1 to 1:3, from 4:1 to 1:3, from 3:1 to 1:3, from 2:1 to 1:3, from 1:1 to 1:3, or from 1:2 to 1:3. Although the various NIL materials listed in Tables 17-22 include only titanium oxide and/or zirconium oxide nanoparticles, various ML materials having combination of other nanoparticles may be prepared for NIL molding the slanted grating, and the combined nanoparticle loading may range from 45% to 90%, 45% to 85%, 45% to 80%, from 45% to 75%, from 45% to 70%, from 45% to 65%, from 45% to 60%, from 45% to 55%, or from 45% to 50%.

TABLE 17
17^{th} exemplary nanoimprint lithography (NIL) material

| | | | | Zirconium oxide to | |
|---|---|---|---|---|---|
| Formulation | | Amount (wt. %) | | Titanium oxide wt % ratio | |
| ID | Composition | Range | Example | Range | Example |
| HRI- | Miramer HR6042 | 1.5-4 | 2.60 | 70:15 | 65:10 |
| 1ZR65TI10PG43 | Miramer 1192 | 1.5-4 | 2.60 | to 60:5 | |
| | Photo radical generator (PRG) | 0.2-8 | 0.40 | | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | PGMEA (Propylene glycol methyl ether | 0-90 | 60.24 | | |
| | acetate) | | | | |
| | Zirconium oxide blend | 5-90 | 29.60 | | |
| | (50 wt. % Zirconium oxide nanoparticles | | | | |
| | in PGMEA) | | | | |
| | Titanium oxide blend | 3-15 | 4.55 | | |
| | (50 wt. % Titanium oxide nanoparticles in | | | | |
| | PGMEA) | | | | |

TABLE 18
18^{th} exemplary nanoimprint lithography (NIL) material

| | | | | Zirconium oxide to | |
|---|---|---|---|---|---|
| Formulation | | Amount (wt. %) | | Titanium oxide wt % ratio | |
| ID | Composition | Range | Example | Range | Example |
| HRI- | Miramer HR6042 | 1.5-4 | 2.60 | 60:25 | 55:20 |
| 1ZR55TI20PG43 | Miramer 1192 | 1.5-4 | 2.60 | to | |
| | Photo radical generator (PRG) | 0.2-8 | 0.40 | 50:15 | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | PGMEA (Propylene glycol methyl ether | 0-90 | 60.24 | | |
| | acetate) | | | | |
| | Zirconium oxide blend | 5-90 | 25.05 | | |
| | (50 wt. % Zirconium oxide nanoparticles | | | | |
| | in PGMEA) | | | | |
| | Titanium oxide blend | 3-15 | 9.10 | | |
| | (50 wt. % Titanium oxide nanoparticles in | | | | |
| | PGMEA) | | | | |

TABLE 19
19^{th} exemplary nanoimprint lithography (NIL) material

| | | | | Zirconium oxide to | |
|---|---|---|---|---|---|
| Formulation | | Amount (wt. %) | | Titanium oxide wt % ratio | |
| ID | Composition | Range | Example | Range | Example |
| HRI- | Miramer HR6042 | 1.5-4 | 2.60 | 50:45 | 45:30 |
| 1ZR45TI30PG43 | Miramer 1192 | 1.5-4 | 2.60 | to | |
| | Photo radical generator (PRG) | 0.2-8 | 0.40 | 40:25 | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | PGMEA (Propylene glycol methyl ether | 0-90 | 60.24 | | |
| | acetate) | | | | |
| | Zirconium oxide blend | 5-90 | 20.49 | | |
| | (50 wt. % Zirconium oxide nanoparticles | | | | |
| | in PGMEA) | | | | |
| | Titanium oxide blend | 3-15 | 13.66 | | |
| | (50 wt. % Titanium oxide nanoparticles in | | | | |
| | PGMEA) | | | | |

TABLE 20
20^{th} exemplary nanoimprint lithography (NIL) material

| | | | | Zirconium oxide to | |
|---|---|---|---|---|---|
| Formulation | | Amount (wt. %) | | Titanium oxide wt % ratio | |
| ID | Composition | Range | Example | Range | Example |
| HRI- | Miramer HR6042 | 1.5-4 | 2.60 | 40:45 | 35:40 |
| 1ZR35TI40PG43 | Miramer 1192 | 1.5-4 | 2.60 | to | |
| | Photo radical generator (PRG) | 0.2-8 | 0.40 | 30:35 | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | PGMEA (Propylene glycol methyl ether | 0-90 | 60.24 | | |
| | acetate) | | | | |
| | Zirconium oxide blend | 5-90 | 15.90 | | |
| | (50 wt. % Zirconium oxide nanoparticles | | | | |
| | in PGMEA) | | | | |
| | Titanium oxide blend | 3-24 | 18.21 | | |
| | (50 wt. % Titanium oxide nanoparticles in | | | | |
| | PGMEA) | | | | |

TABLE 21
21^{st} exemplary nanoimprint lithography (NIL) material

| | | | | Zirconium oxide to | |
|---|---|---|---|---|---|
| Formulation | | Amount (wt. %) | | Titanium oxide wt % ratio | |
| ID | Composition | Range | Example | Range | Example |
| HRI- | Miramer HR6042 | 1.5-4 | 2.60 | 30:55 | 25:50 |
| 1ZR25TI50PG43 | Miramer 1192 | 1.5-4 | 2.60 | to | |
| | Photo radical generator (PRG) | 0.2-8 | 0.40 | 20:45 | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | PGMEA (Propylene glycol methyl ether | 0-90 | 60.24 | | |
| | acetate) | | | | |
| | Zirconium oxide blend | 5-90 | 11.38 | | |
| | (50 wt. % Zirconium oxide nanoparticles | | | | |
| | in PGMEA) | | | | |
| | Titanium oxide blend | 3-28 | 22.76 | | |
| | (50 wt. % Titanium oxide nanoparticles in | | | | |
| | PGMEA) | | | | |

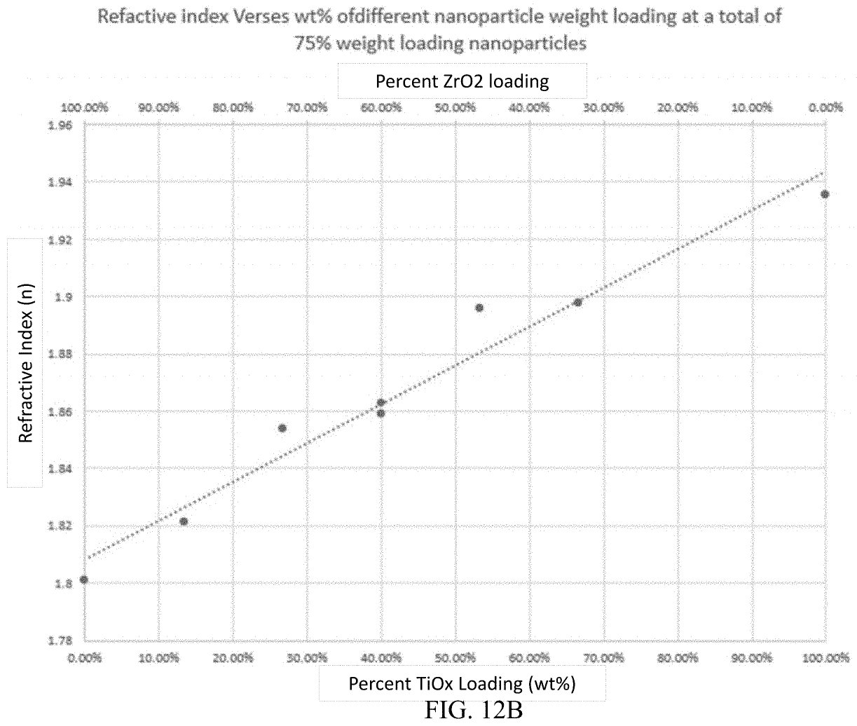

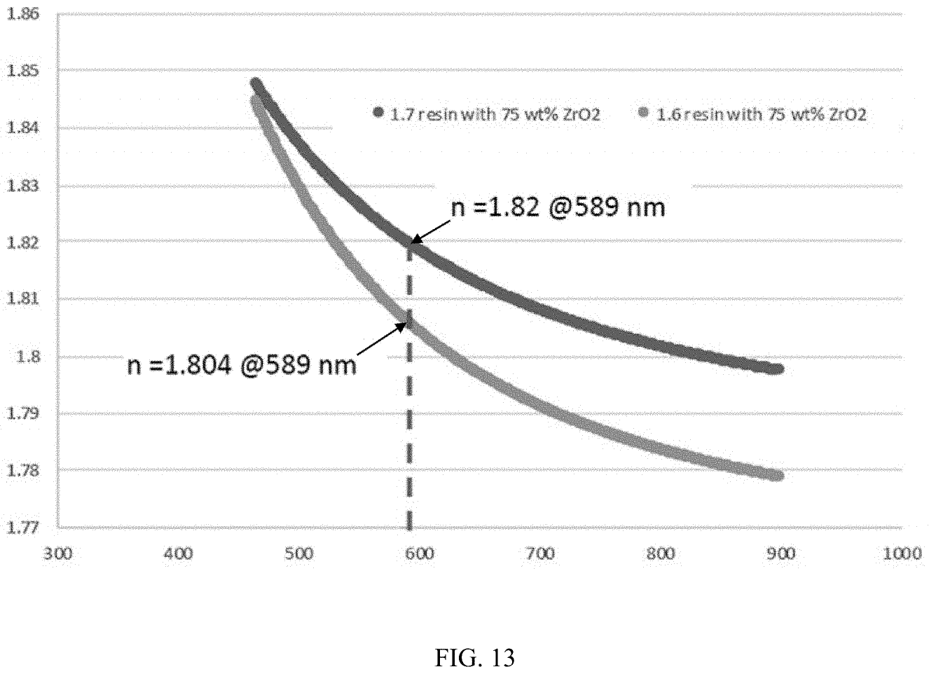

Table 22 below lists various nanoparticle loading and the corresponding NIL material refractive index. FIG. 12A is a plot showing the NIL material refractive index for visible light at 589 nm versus nanoparticle loading at wavelength of 589 nm for the various materials listed in Table 22. FIG. 12B is a plot showing the NIL material refractive index for visible light at 589 nm versus weight percentage of the component nanoparticles listed in Table 22.

TABLE 22
Exemplary nanoparticle loading and corresponding NIL material refractive index

| | Zirconium | | | | |
|---|---|---|---|---|---|
| | oxide | Titanium oxide | Zirconium oxide to | Wavelength | Refractive |
| Nanoparticles | (wt. %) | (wt. %) | Titanium oxide wt % ratio | (nm) | index (n) |
| Zirconium | 25 | 50 | 33.33:66.67 | 589 | 1.897551 |
| oxide and | 35 | 40 | 46.67:53.33 | | 1.895669 |
| Titanium | 45 | 30 | 60.00:40.00 | | 1.858924 |
| oxide | 45 | 30 | 60.00:40.00 | | 1.863 |
| | 55 | 20 | 73.33:26.67 | | 1.853745 |
| | 65 | 10 | 86.67:13.33 | | 1.821127 |
| Titanium | 0 | 75 | 0 | | 1.93 |
| oxide | | | | | |
| Zirconium | 75 | 0 | / | | 1.801 |
| oxide | | | | | |

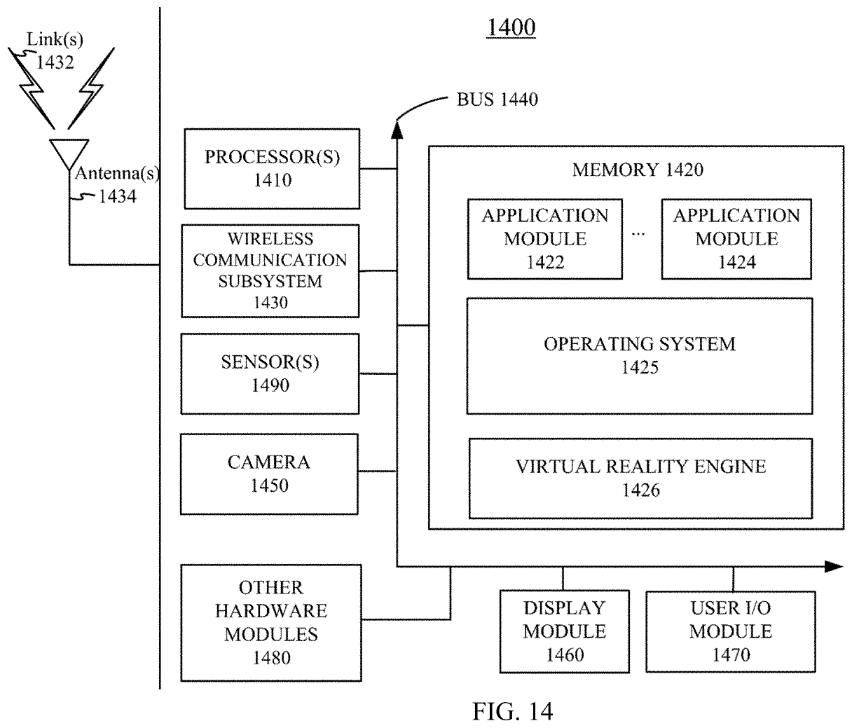

FIG. 13 is a plot showing the NIL material refractive index versus light wavelength for various NIL materials having different base resin materials and the same nanoparticle loading. The NIL material refractive indices refer to the refractive indices of the cured NIL materials. The nanoparticles of the NIL materials plotted in FIG. 13 are zirconium oxide nanoparticles, such as zirconium oxide nanoparticles dispersed in PGMEA provided by Pixelligent® under the part number PCPG-3-50-PGA. The NIL materials each include 75% nanoparticle loading, which refers to the weight percentage (wt. %) of the zirconium oxide nanoparticles in the cured NIL materials (i.e., without PGMEA solvent).

The NIL material of the upper curve in FIG. 13 includes a base resin material that has a refractive index of about 1.7. The base resin material thereof includes thianthrene diacrylate, such as thianthrene diacrylate with PRG (3% by wt. PI) provided by Sigma-Aldrich Corp. The NIL material of the lower curve in FIG. 13 includes a base resin material that has a refractive index of about 1.6. The base resin material thereof includes a combination of base resin materials, such as Miramer HR6042 provided by Miwon Specialty Chemical Co., Ltd. and Miramer 1192 provided by Miwon Specialty Chemical Co., Ltd. The NIL materials of FIG. 13 each further include a photo radical generator (PRG), such as a 50/50 blend of diphenyl(2,4,6 trimethylbenzoyl)phosphine oxide and 2-hydroxy-2-methylpropiophenone provided by Sigma-Aldrich Corp.

Tables 23 and 24 below list the composition or formulation of the NIL materials of FIG. 13. In particular, Table 23 below lists the composition or formulation of the NIL material including the base resin having a refractive index of about 1.7, and Table 24 below lists the composition or formulation of the NIL material including the base resin having a refractive index of about 1.6. Both NIL materials include 75 wt. % of zirconium oxide nanoparticle loading, i.e., the cured NIL material (without PMGEA solvent) including 75 wt. % zirconium oxide nanoparticles.

TABLE 23
22^{nd} exemplary nanoimprint lithography (NIL) material

| | | | | (Resin + PRG) to | |
|---|---|---|---|---|---|
| Formulation | | Amount (wt. %) | | Nanoparticles wt % Ratio | |
| ID | Composition | Range | Example | Range | Example |
| HRI-6 | Thianthrene Diacrylate with PRG (3% | 8-20 | 13.74 | 10:90 | 25:75 |
| | by wt. PI) | | | to 60:40 | |
| | Photo radical generator (PRG) | 0.3-0.8 | 0.42 | | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | Zirconium oxide blend | 75-95 | 85.84 | | |
| | (50% PGMEA/50% Zirconium oxide) | | | | |

TABLE 24
23^{rd} exemplary nanoimprint lithography (NIL) material

| | | | | (Resin + PRG) to | |
|---|---|---|---|---|---|
| Formulation | | Amount (wt. %) | | Nanoparticles wt % Ratio | |
| ID | Composition | Range | Range | Example | Example |
| HRI- | Miramer HR6042 | 4-10 | 6.94 | 10:90 | 25:75 |
| 1ZR75PG43 | Miramer 1192 | 4-10 | 6.94 | to 60:40 | |
| (Zachling) | Photo radical generator (PRG) | 0.2-0.5 | 0.28 | | |
| | (Diphenyl(2,4,6 | | | | |
| | trimethylbenzoyl)phosphine oxide and | | | | |
| | 2-Hydroxy-2-methylpropiophenone | | | | |
| | 50/50 blend) | | | | |
| | Zirconium oxide blend | 75-95 | 85.84 | | |
| | (50% PGMEA/50% Zirconium oxide) | | | | |

Table 25 lists the refractive index (RI) of nanoparticles, given the refractive indices of the nanoparticle core (e.g., rutile TiO₂ and anatase TiO₂) and the nanoparticle shell (e.g., ligands), for a range of respective volume fractions of the nanoparticle core and nanoparticle shell, in accordance with some embodiments. The refractive index of the nanoparticles for the respective refractive indices and volume fractions of the nanoparticle core and nanoparticle shell is calculated using Rytov's formula as described in detail above.

TABLE 25
Refractive index of nanoparticles

| | Volume fraction | Volume fraction | RI of |
|---|---|---|---|
| | of rutile TiO₂ | of ligands | nanoparticles |
| RI of rutile TiO₂ | 90% | 10% | 2.499 |
| 2.61 | 80% | 20% | 2.388 |
| RI of anatase TiO₂ | 70% | 30% | 2.277 |
| 2.49 | 60% | 40% | 2.166 |
| | Volume fraction | Volume fraction | RI of |
| RI of ligands | of anatase TiO₂ | of ligands | nanoparticles |
| 1.5 | 90% | 10% | 2.391 |
| | 80% | 20% | 2.292 |
| | 70% | 30% | 2.193 |
| | 60% | 40% | 2.094 |

The various NIL materials described herein allow for imprinting or NIL molding a slanted structure at room temperature. The various NIL material mixtures described herein each have a viscosity that would allow for the various NIL material mixture to flow to conform to the shape of the mold during the NIL molding process. Further, in some embodiments, the NIL materials described herein provide more cost-effective alternatives for achieving high refractive indices of the cured NIL materials. For example, the composition or formulation of the NIL materials described herein may achieve relatively high refractive indices of the cured NIL materials by using a base resin that may have a relative low refractive index (and is thus more cost-effective). For example, as described above, a greater refractive index of the cured NIL material may be achieved using a base resin having a refractive index of about 1.6 instead of a base resin having a refractive index of about 1.7 with a nanoparticle loading as low as about 45%.

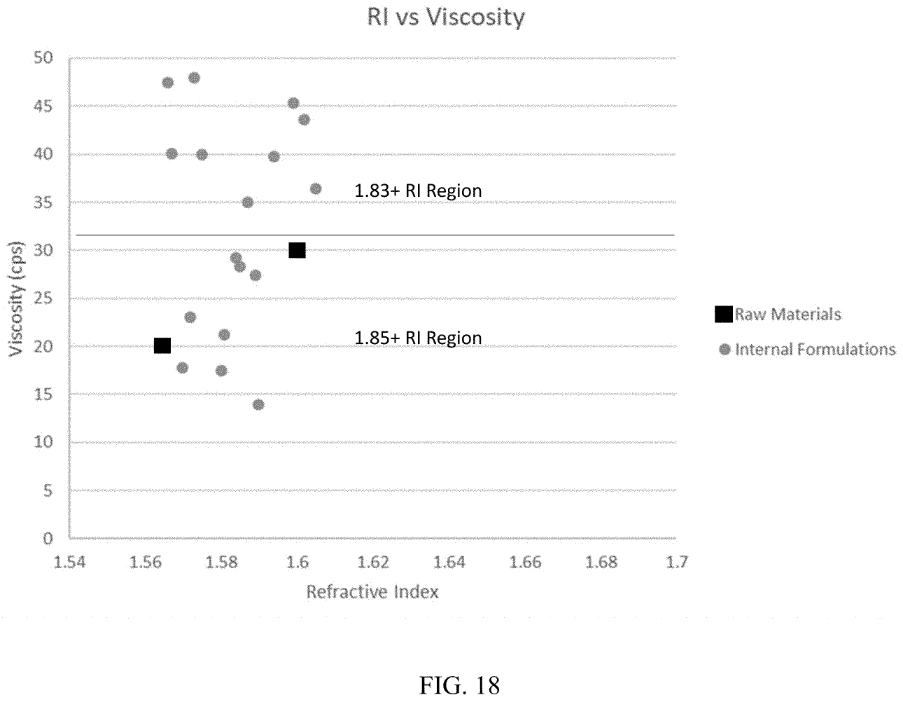

FIG. 17 is a plot showing that the refractive index of various imprinting formulations comprising 75% TiO₂ nanoparticles increases as the viscosity of the base resin component decreases, in accordance with some embodiments. The x- and y-axes represent the refractive index of the base resin component and the viscosity of the base resin component, respectively. FIG. 17 shows that formulations comprising base resin components with high viscosity (e.g., above about 125 cps) and refractive indices of about 1.6 result in NIL precursor materials (e.g., imprinting resins) with refractive indices of less than 1.83. Reducing the viscosity of the base resin component (e.g., below about 125 cps) results in NIL precursor materials with refractive indices of greater than 1.83. Notably, the refractive index of a NIL precursor material comprising a base resin component with a low viscosity (e.g., below about 125 cps) is greater than 1.83 even when the refractive index of the base resin component is low (e.g. as low as 1.565 and/or between 1.56 and 1.62). FIG. 17 thus illustrates that, in some embodiments, NIL precursor materials with high refractive indices are produced by modulating the viscosity rather than the refractive indices of the base resin components. This provides an improvement to traditional methods of formulating NIL precursor materials with desired refractive index values using base resin components that are conventionally considered to be non-optimal for optical purposes (e.g., due to having low refractive indices) and are thus more cost-effective.

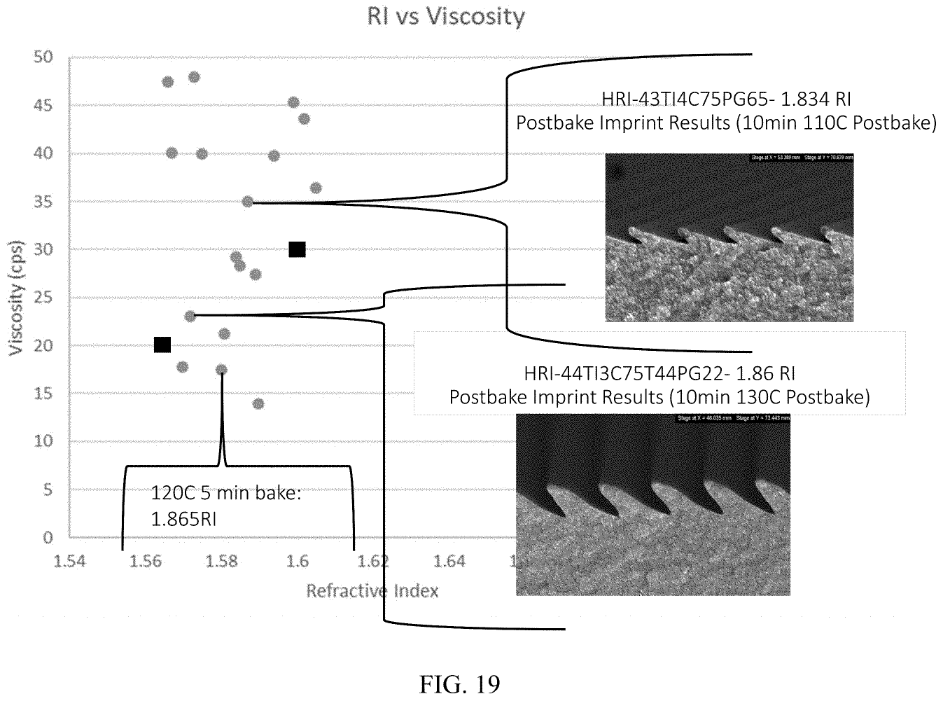

FIG. 18 is a plot showing that the refractive index of various imprinting formulations comprising 75% TiO₂ nanoparticles increases as the viscosity of base resin component decreases, in accordance with some embodiments. The x- and y-axes represent the refractive index of the base resin component and the viscosity of the base resin component, respectively. Specifically, FIG. 18 further examines the optical properties of the various imprinting formulations of FIG. 17 comprising base resin components with viscosities below 50 cps. Base resin components with viscosities of between about 33 cps and about 50 cps resulted in NIL precursor materials with refractive indices greater than 1.83, while base resin components with viscosities of below 33 cps resulted in NIL precursor materials with refractive indices greater than 1.85. Thus, FIG. 18 further illustrates that the refractive index of a NIL precursor material is increased in some embodiments by decreasing the viscosity of the base resin component.

Table 26 lists, among others, the composition or formulation of the various NIL materials of FIGS. 17 and 18. Table 26 includes, for each formulation, the viscosity of the base resin component, the refractive index (RI) of the base resin component measured at 589 nm, the one or more components comprising the respective formulation, and the percent by mass (e.g., mass %) of each respective component for the respective formulation.

TABLE 26
Composition, viscosity, and refractive index of
exemplary nanoprint lithography (NIL) materials

| Formu- | | | | |
|---|---|---|---|---|
| lation | Viscosity | RI at | | Amount |
| ID | (cps) | 589 nm | Composition | (mass %) |
| HRI-1 | 474 | 1.601 | HR6042 | 49.02 |
| | | | Miramer 1192 | 49.02 |
| | | | PRG | 1.96 |
| HRI-2 | 263 | 1.601 | HR6042 | 39.22 |
| | | | Miramer 1192 | 58.82 |
| | | | PRG | 1.96 |
| HRI-3 | 134 | 1.601 | HR6042 | 29.41 |
| | | | Miramer 1192 | 68.63 |
| | | | PRG | 1.96 |
| HRI-4 | 84 | 1.601 | HR6042 | 19.61 |
| | | | Miramer 1192 | 78.43 |
| | | | PRG | 1.96 |
| HRI-5 | 53 | 1.601 | HR6042 | 9.80 |
| | | | Miramer 1192 | 88.24 |
| | | | PRG | 1.96 |
| HRI-11 | 290 | 1.67 | Viscoat 450 | 95.50 |
| | | | PRG | 4.50 |
| HRI-34 | 284.5 | 1.601 | SBPF-022 | 50.00 |
| | | | Miramer 1192 | 50.00 |
| | | | PRG | 2 |
| HRI-35 | 155.77 | 1.602 | SBPF-022 | 40.00 |
| | | | Miramer 1192 | 60.00 |
| | | | PRG | 2 |
| HRI-36 | 99.45 | 1.602 | SBPF-022 | 30.00 |
| | | | Miramer 1192 | 70.00 |
| | | | PRG | 2 |
| HRI-37 | 63.9 | 1.602 | SBPF-022 | 20.00 |
| | | | Miramer 1192 | 80.00 |
| | | | PRG | 2 |
| HRI-38 | 43.62 | 1.602 | SBPF-022 | 10.00 |
| | | | Miramer 1192 | 90.00 |
| | | | PRG | 2 |
| HRI-43 | 35 | 1.587 | Miramer 1192 | 82.65 |
| | | | Viscoat TMP3A | 9.18 |
| | | | X-12-2430C | 1.74 |
| | | | PRG | 6.43 |
| HRI-44 | 23 | 1.572 | SBPF-022 | 19.91 |
| | | | Miramer 1192 | 31.67 |
| | | | Benzyl Methacrylate | 27.15 |
| | | | Viscoat 450 | 9.05 |
| | | | TMP3A/PI/X-12-2430C | 4.07/6.33/1.81 |
| HRI-45 | 83.1 | 1.612 | Miramer 1192 | 50.00 |
| | | | Viscoat 450 | 50.00 |
| HRI-46 | 56.1 | 1.6088 | Miramer 1192 | 70.00 |
| | | | Viscoat 450 | 30.00 |
| HRI-47 | 36.42 | 1.605 | Miramer 1192 | 90.00 |
| | | | Viscoat 450 | 10.00 |
| HRI-48 | 128.6 | 1.612 | Miramer 1122 | 30.00 |
| | | | Viscoat 450 | 70.00 |
| HRI-49 | 77 | 1.6 | Miramer 1122 | 50.00 |
| | | | Viscoat 450 | 50.00 |
| HRI-50 | 45.3 | 1.599 | Miramer 1122 | 35.00 |
| | | | Miramer 1192 | 35.00 |
| | | | Viscoat 450 | 30 |
| HRI-51 | 27.39 | 1.589 | Miramer 1122 | 31.50 |
| | | | Miramer 1192 | 31.50 |
| | | | Viscoat 450 | 27 |
| | | | Benzylmethacrylate | 10.00 |
| HRI-52 | 17.46 | 1.5802 | Miramer 1192 | 32.11 |
| | | | Viscoat 450 | 32.11 |
| | | | Benzyl Methacrylate | 27.52 |
| | | | X-12-2430C | 1.83 |
| | | | PI | 6.42 |
| HRI-53 | 39.72 | 1.594 | Viscoat 450 | 70.00 |
| | | | Benzyl Methacrylate | 30.00 |
| HRI-54 | 29.19 | 1.584 | Miramer 1122 | 42.50 |
| | | | Viscoat 450 | 42.50 |
| | | | Benzyl Methacrylate | 15 |
| HRI-55 | 256.2 | 1.58 | SBPF-022 | 70.00 |
| | | | Benzyl Methacrylate | 30.00 |
| HRI-56 | 47.46 | 1.566 | SBPF-022 | 50.00 |
| | | | Benzyl Methacrylate | 30.00 |
| | | | Miramer 1192 | 20 |
| HRI-57 | 40.08 | 1.567 | SBPF-022 | 50.00 |
| | | | Benzyl Methacrylate | 30.00 |
| | | | Miramer 1122 | 20 |
| HRI-58 | 21.18 | 1.581 | Viscoat 450 | 60.00 |
| | | | Benzyl Methacrylate | 40.00 |
| HRI-59 | 28.26 | 1.585 | Viscoat 450 | 54.00 |
| | | | Benzyl Methacrylate | 36.00 |
| | | | Syngene Monomer-2 | 10 |
| HRI-60 | 13.9 | 1.59 | SBPF-022 | 22.00 |
| | | | Miramer 1192 | 35.00 |
| | | | Divinylbenzene | 30 |
| | | | Viscoat 450 | 10.00 |
| | | | TMP3A | 3.00 |
| HRI-61 | 48 | 1.573 | SBPF-022 | 50.00 |
| | | | Miramer 1192 | 20.00 |
| | | | Benzyl Methacrylate | 30 |
| HRI-62 | 40 | 1.575 | SBPF-022 | 40.00 |
| | | | Miramer 1192 | 20.00 |
| | | | Viscoat 450 | 10 |
| | | | Benzylmethacrylate | 30.00 |
| HRI-63 | 57 | 1.573 | SBPF-022 | 50.00 |
| | | | Miramer 1192 | 20.00 |
| | | | Benzyl Methacrylate | 20 |
| | | | NVP | 10.00 |
| HRI-64 | 17.8 | 1.57 | Miramer 1192 | 30.00 |
| | | | Benzyl Methacrylate | 35.00 |
| | | | Viscoat 450 | 15 |
| | | | BDDA | 3.00 |
| | | | SBPF-022 | 17.00 |
| HRI-73 | 22 | 1.58 | Miramer 1192 | 81 |
| | | | TMP3A | 10.00 |
| | | | NVP | 9.00 |
| HRI-74 | 38 | 1.565 | Miramer 1192 | 71 |
| | | | TMP3A | 20.00 |
| | | | NVP | 9.00 |
| HRI-75 | 56 | 1.55 | Miramer 1192 | 61 |
| | | | TMP3A | 30.00 |
| | | | NVP | 9.00 |

Various base resin components, radical or acid generators, crosslinking agents, additives, and/or solvents are used as raw materials in order to formulate the various precursor materials depicted in FIGS. 17 and 18 and listed in Table 26, in accordance with some embodiments. For example, in some embodiments, biphenylmethyl acrylate (BPMA) (provided by Miwon Specialty Chemical Co., Ltd. under the part number of Miramer 1192) is used as a major component, due to its refractive index of about 1.6 and its low viscosity of 20-40 cps. In some embodiments, TMPTA (provided by Satomer under the part number of SR351) is used as a crosslinking agent to increase the number of reactive functional groups in the NIL precursor material, thus increasing the reactivity between the base resin component and the nanoparticles component. In some embodiments, N-Vinylpyrrolidone (NVP) (provided by BASF, Sigma Aldrich, and/or ASHLAND under the part number of V-Pyrol) is used as a reactive diluent to further reduce viscosity. In some embodiments, X-12-2430C (provided by Shin-Etsu) is used as a surface modification additive to reduce surface energy. In some embodiments, a 50/50 blend of diphenyl(2,4,6 trimethylbenzoyl)phosphine oxide and 2-Hydroxy-2-methylpropiophenone (PRG) (provided by Sigma Aldrich) is used to generate radicals to initiate polymerization under UV exposure. In some embodiments, various base resin components, radical or acid generators, crosslinking agents, additives, and/or solvents used as raw materials in order to formulate the various precursor materials include, without limitation, Miramer M1142 (Miwon Specialty Chemical Co.), Miramer M1122 (Miwon Specialty Chemical Co.), Miramer HR6042 (Miwon Specialty Chemical Co.), SBPF-022 (SHIN-A T&C), Miramer M301 (Miwon Specialty Chemical Co.), Viscoat TMP3A (Osaka Organic Chemical Industry LTD), (2,7-bis[(2-acryloyloxyethl)-sulfanyl]thianthrene) (FRL resin), Viscoat 450 (Osaka Organic Chemical Industry LTD), benzyl methacrylate (Sigma Aldrich), HDDA (1,6-Hexanediol diacrylate) (Sigma Aldrich), BDDA (1,4-Butanediol diacrylate) (Sigma Aldrich), and/or (85-90% acryloxypropylsilsesquioxane)-(10-15% methylsilsesquioxane) copolymer, methoxy terminated (Sigma Aldrich).

FIG. 19 shows the results of slanted imprinting processes for the various imprinting formulations of FIG. 18 in accordance with some embodiments. The imprintability of the various formulations illustrated in FIGS. 17 and 18 and listed in Table 26 is assessed. Each respective formulation can be imprinted with different types of structures for creating surface-relief gratings. For example, Formulation HRI-43 (e.g., HRI-43TI4C75PG65) is imprinted with a NIL mold having a first structure, while Formulation HRI-44 (e.g., HRI-44TI3C75T44PG22) is imprinted with a NIL mold having a second structure. The surface-relief grating comprising Formulation HRI-43 is formed using a process comprising a spin-coating step at 2000 rpm for 45 seconds, a post-apply bake step at 80° C. for 1 minute, a curing step with an exposure time of 40 seconds, a resting step with a dwell time of 2 minutes prior to delamination, and a post-exposure bake step at 110° C. for 10 minutes. The surface-relief grating comprising Formulation HRI-44 is formed using a process comprising a spin-coating step at 2000 rpm for 45 seconds, a curing step with an exposure time of 40 seconds, a resting step with a dwell time of 2 minutes prior to delamination, and a post-exposure bake step at 130° C. for 10 minutes. In some alternative embodiments, a surface-relief grating is formed using a post-exposure bake step at 120° C. for 5 minutes. FIG. 19 illustrates that the disclosed formulations illustrated in FIGS. 17 and 18 and listed in Table 26 can be imprinted and used to form surface-relief structures using various imprinting processes, in accordance with some embodiments.

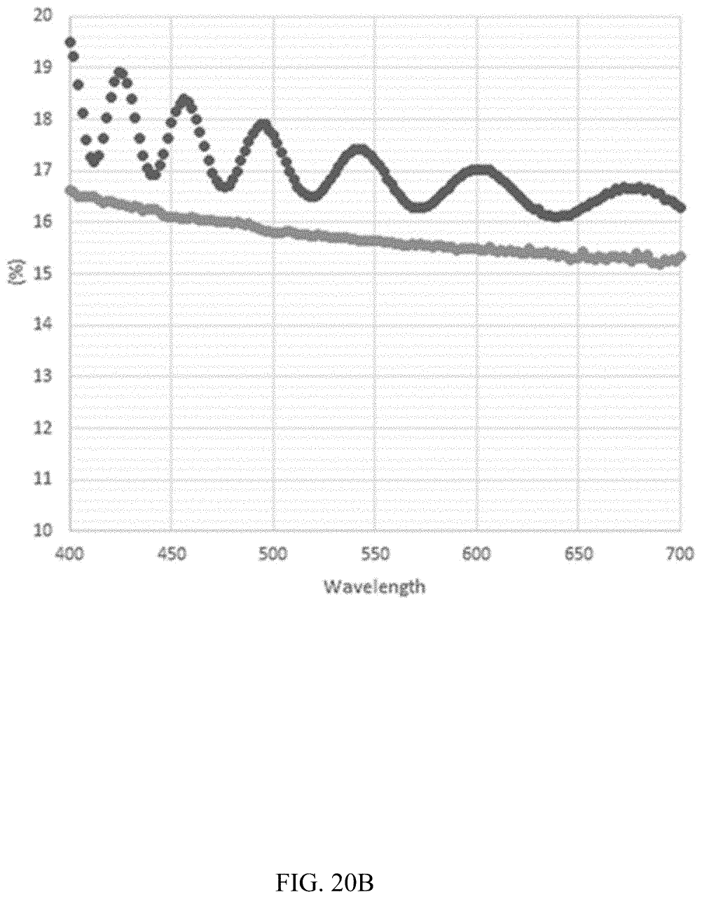

FIGS. 20A and 20B illustrate the impact of an example post-exposure bake process on the refractive index and optics of a surface-relief grating using Formulation HRI-43 in accordance with some embodiments as illustrated in FIG. 19. FIG. 20A shows that, in some embodiments, altering the post-exposure bake process further enhances the refractive index of the cured NIL material. For example, an imprinting process as described for Formulation HRI-43 in FIG. 19 can comprise a post-exposure bake step of 120° C. for 10 minutes, a post-exposure bake step of 120° C. for 4 minutes, a post-exposure bake step of 110° C. for 4 minutes, a post-exposure bake step of 130° C. for 10 minutes, or a post-exposure bake step of 110° C. for 10 minutes. In some embodiments, the resulting surface-relief grating comprising the cured NIL material has a refractive index of 1.827, 1.834, 1.838, or 1.843, respectively. FIG. 20A further illustrates the impact of a post-apply bake step (e.g., 80° C. for 1 minute) on the refractive index of uncured NIL precursor material, resulting in an increase from 1.76 (e.g., no post-apply bake step) to 1.785 (post-apply bake at 80° C. for 1 minute). Additionally, FIG. 20A illustrates the refractive index of cured NIL material (e.g., 1.814) versus uncured NIL precursor material (e.g., 1.785) following a post-apply bake step at 80° C. for 1 minute.

FIG. 20B shows a comparison of the optical performance of a surface-relief grating with a refractive index of 1.834 formed using a post-exposure bake step at 110° C. for 10 minutes (dark gray, top), compared to a glass reference with a refractive index of 1.8 (light gray, bottom). FIG. 20B illustrates the percent absorption (%) of the surface-relief grating and the glass reference indicated along the y-axis versus the light wavelength for a range of visible light (e.g., about 400 to 700 nm).

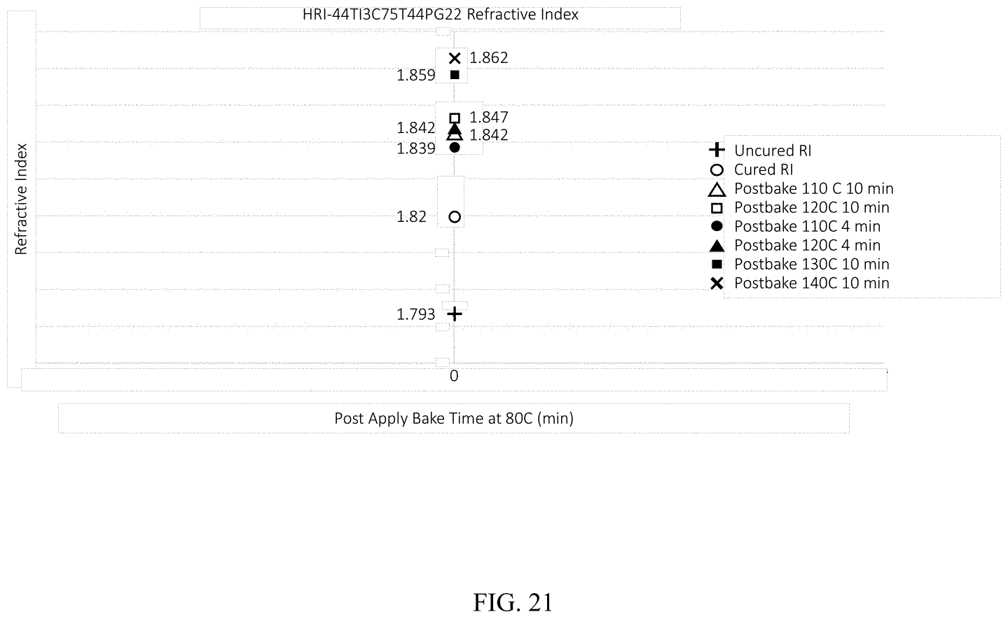

FIG. 21 illustrates the impact of an example post-exposure bake process on the refractive index of a surface-relief grating using Formulation HRI-44 in accordance with some embodiments as illustrated in FIG. 19. FIG. 21 shows that, in some embodiments, altering the post-exposure bake process further enhances the refractive index of the cured NIL material. For example, an imprinting process as described for Formulation HRI-44 in FIG. 19 can comprise a post-exposure bake step of 140° C. for 10 minutes, a post-exposure bake step of 130° C. for 10 minutes, a post-exposure bake step of 120° C. for 4 minutes, a post-exposure bake step of 110° C. for 4 minutes, a post-exposure bake step of 120° C. for 10 minutes, or a post-exposure bake step of 110° C. for 10 minutes. In some embodiments, the resulting surface-relief grating comprising the cured NIL material has a refractive index of 1.839, 1.842, 1.847, 1.859, or 1.862, respectively. FIG. 21 further illustrates the refractive index of cured NIL material (e.g., 1.82) versus uncured NIL precursor material (e.g., 1.793) omitting a post-apply bake step. FIGS. 20A and 20B and FIG. 21 illustrate that the disclosed formulations illustrated in FIGS. 17, 18, and 19 and listed in Table 26 can be imprinted and used to form surface-relief structures with improved parameters (e.g., refractive index) using various imprinting processes, in accordance with some embodiments.

### OTHER EMBODIMENTS

Embodiments of the invention may be used to implement components of an artificial reality system or may be implemented in conjunction with an artificial reality system. Artificial reality is a form of reality that has been adjusted in some manner before presentation to a user, which may include, for example, a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

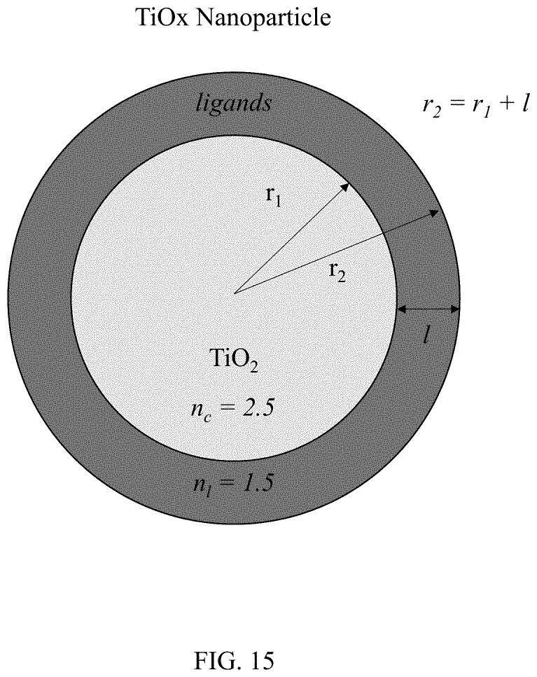

FIG. 14 is a simplified block diagram of an example electronic system 1400 of an example near-eye display (e.g., HMD device) for implementing some of the examples disclosed herein. Electronic system 1400 may be used as the electronic system of an HMD device or other near-eye displays described above. In this example, electronic system 1400 may include one or more processor(s) 1410 and a memory 1420. Processor(s) 1410 may be configured to execute instructions for performing operations at a number of components, and can be, for example, a general-purpose processor or microprocessor suitable for implementation within a portable electronic device. Processor(s) 1410 may be communicatively coupled with a plurality of components within electronic system 1400. To realize this communicative coupling, processor(s) 1410 may communicate with the other illustrated components across a bus 1440. Bus 1440 may be any subsystem adapted to transfer data within electronic system 1400. Bus 1440 may include a plurality of computer buses and additional circuitry to transfer data.

Memory 1420 may be coupled to processor(s) 1410. In some embodiments, memory 1420 may offer both short-term and long-term storage and may be divided into several units. Memory 1420 may be volatile, such as static random access memory (SRAM) and/or dynamic random access memory (DRAM) and/or non-volatile, such as read-only memory (ROM), flash memory, and the like. Furthermore, memory 1420 may include removable storage devices, such as secure digital (SD) cards. Memory 1420 may provide storage of computer-readable instructions, data structures, program modules, and other data for electronic system 1400. In some embodiments, memory 1420 may be distributed into different hardware modules. A set of instructions and/or code might be stored on memory 1420. The instructions might take the form of executable code that may be executable by electronic system 1400, and/or might take the form of source and/or installable code, which, upon compilation and/or installation on electronic system 1400 (e.g., using any of a variety of generally available compilers, installation programs, compression/decompression utilities, etc.), may take the form of executable code.

In some embodiments, memory 1420 may store a plurality of application modules 1422 through 1424, which may include any number of applications. Examples of applications may include gaming applications, conferencing applications, video playback applications, or other suitable applications. The applications may include a depth sensing function or eye tracking function. Application modules 1422-1424 may include particular instructions to be executed by processor(s) 1410. In some embodiments, certain applications or parts of application modules 1422-1424 may be executable by other hardware modules 1480. In certain embodiments, memory 1420 may additionally include secure memory, which may include additional security controls to prevent copying or other unauthorized access to secure information.

In some embodiments, memory 1420 may include an operating system 1425 loaded therein. Operating system 1425 may be operable to initiate the execution of the instructions provided by application modules 1422-1424 and/or manage other hardware modules 1480 as well as interfaces with a wireless communication subsystem 1430 which may include one or more wireless transceivers. Operating system 1425 may be adapted to perform other operations across the components of electronic system 1400 including threading, resource management, data storage control and other similar functionality.

Wireless communication subsystem 1430 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 1400 may include one or more antennas 1434 for wireless communication as part of wireless communication subsystem 1430 or as a separate component coupled to any portion of the system. Depending on desired functionality, wireless communication subsystem 1430 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 1430 may permit data to be exchanged with a network, other computer systems, and/or any other devices described herein. Wireless communication subsystem 1430 may include a means for transmitting or receiving data, such as identifiers of HMD devices, position data, a geographic map, a heat map, photos, or videos, using antenna(s) 1434 and wireless link(s) 1432. Wireless communication subsystem 1430, processor(s) 1410, and memory 1420 may together comprise at least a part of one or more of a means for performing some functions disclosed herein.

Embodiments of electronic system 1400 may also include one or more sensors 1490. Sensor(s) 1490 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 1490 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or some combination thereof. The position sensors may be located external to the IMU, internal to the IMU, or some combination thereof. At least some sensors may use a structured light pattern for sensing.

Electronic system 1400 may include a display module 1460. Display module 1460 may be a near-eye display, and may graphically present information, such as images, videos, and various instructions, from electronic system 1400 to a user. Such information may be derived from one or more application modules 1422-1424, virtual reality engine 1426, one or more other hardware modules 1480, a combination thereof, or any other suitable means for resolving graphical content for the user (e.g., by operating system 1425). Display module 1460 may use liquid crystal display (LCD) technology, light-emitting diode (LED) technology (including, for example, OLED, ILED, mLED, AMOLED, TOLED, etc.), light emitting polymer display (LPD) technology, or some other display technology.

Electronic system 1400 may include a user input/output module 1470. User input/output module 1470 may allow a user to send action requests to electronic system 1400. An action request may be a request to perform a particular action. For example, an action request may be to start or end an application or to perform a particular action within the application. User input/output module 1470 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 1400. In some embodiments, user input/output module 1470 may provide haptic feedback to the user in accordance with instructions received from electronic system 1400. For example, the haptic feedback may be provided when an action request is received or has been performed.

Electronic system 1400 may include a camera 1450 that may be used to take photos or videos of a user, for example, for tracking the user's eye position. Camera 1450 may also be used to take photos or videos of the environment, for example, for VR, AR, or MR applications. Camera 1450 may include, for example, a complementary metal-oxide-semiconductor (CMOS) image sensor with a few millions or tens of millions of pixels. In some implementations, camera 1450 may include two or more cameras that may be used to capture 3-D images.

In some embodiments, electronic system 1400 may include a plurality of other hardware modules 1480. Each of other hardware modules 1480 may be a physical module within electronic system 1400. While each of other hardware modules 1480 may be permanently configured as a structure, some of other hardware modules 1480 may be temporarily configured to perform specific functions or temporarily activated. Examples of other hardware modules 1480 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 1480 may be implemented in software.

In some embodiments, memory 1420 of electronic system 1400 may also store a virtual reality engine 1426. Virtual reality engine 1426 may execute applications within electronic system 1400 and receive position information, acceleration information, velocity information, predicted future positions, or some combination thereof of the HMD device from the various sensors. In some embodiments, the information received by virtual reality engine 1426 may be used for producing a signal (e.g., display instructions) to display module 1460. For example, if the received information indicates that the user has looked to the left, virtual reality engine 1426 may generate content for the HMD device that mirrors the user's movement in a virtual environment. Additionally, virtual reality engine 1426 may perform an action within an application in response to an action request received from user input/output module 1470 and provide feedback to the user. The provided feedback may be visual, audible, or haptic feedback. In some implementations, processor(s) 1410 may include one or more GPUs that may execute virtual reality engine 1426.

In various implementations, the above-described hardware and modules may be implemented on a single device or on multiple devices that can communicate with one another using wired or wireless connections. For example, in some implementations, some components or modules, such as GPUs, virtual reality engine 1426, and applications (e.g., tracking application), may be implemented on a console separate from the head-mounted display device. In some implementations, one console may be connected to or support more than one HMD.

In alternative configurations, different and/or additional components may be included in electronic system 1400. Similarly, functionality of one or more of the components can be distributed among the components in a manner different from the manner described above. For example, in some embodiments, electronic system 1400 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A nanoimprint lithography (NIL) precursor material comprising a base resin component having a first refractive index ranging from 1.45 to 1.80, and a nanoparticles component having a second refractive index greater than the first refractive index of the base resin component.

2. The NIL precursor material of claim 1, wherein the base resin component is UV curable.

3. The NIL precursor material of claim 1, wherein the base resin component is light-sensitive.

4. The NIL precursor material of claim 1, wherein the first refractive index is measured at 589 nm.

5. The NIL precursor material of claim 1, wherein the base resin component has a viscosity ranging from 0.5 cps to 400 cps.

6. The NIL precursor material of claim 5, wherein the viscosity is measured in the absence of the nanoparticles component.

7. The NIL precursor material of claim 5, wherein the viscosity is measured in the absence of a solvent.

8. The NIL precursor material of claim 1, wherein the base resin component comprises one or more crosslinkable monomers, one or more polymerizable monomers, or both, wherein the crosslinkable monomers or the polymerizable monomers comprise one or more crosslinkable or polymerizable moieties.

9. The NIL precursor material of claim 8, wherein the crosslinkable or polymerizable moieties are selected from an ethylenically unsaturated group, an oxirane ring, and a heterocyclic group.

10. The NIL precursor material of claim 8, wherein the crosslinkable or polymerizable moieties are selected from vinyl, allyl, epoxide, acrylate, and methacrylate.

11. The NIL precursor material of claim 8, wherein the crosslinkable or polymerizable moieties are selected from optionally substituted alkenyl, optionally substituted cycloalkenyl, optionally substituted alkynyl, optionally substituted acrylate, optionally substituted methacrylate, optionally substituted styrene, optionally substituted epoxide, optionally substituted thiirane, optionally substituted lactone, and optionally substituted carbonate.

12. The NIL precursor material of claim 8, wherein the crosslinkable or polymerizable moieties are selected from:

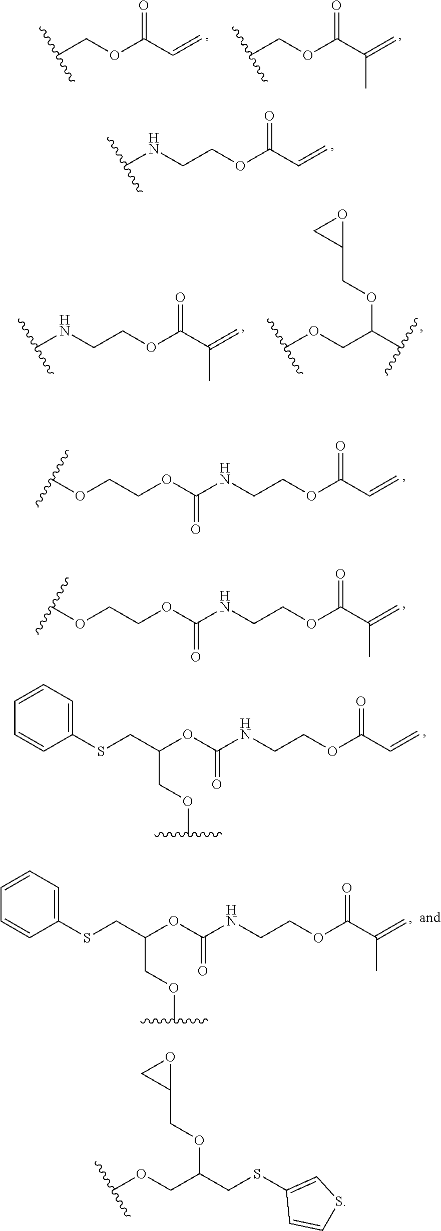

13. The NIL precursor material of claim 1, wherein the nanoparticles component comprises one or more of titanium oxide, zirconium oxide, hafnium oxide, tungsten oxide, zinc tellurium, gallium phosphide, or any combination or derivative thereof.

14. The NIL precursor material of claim 1, wherein the nanoparticles component comprises a plurality of surface-modified nanoparticles, a plurality of capped nanoparticles, or both.

15. The NIL precursor material of claim 14, wherein the surface-modified nanoparticles, the capped nanoparticles, or both, comprise a substantially inorganic core, and a substantially organic shell.

16. The NIL precursor material of claim 15, wherein the substantially organic shell comprises one or more crosslinkable or polymerizable moieties.

17. The NIL precursor material of claim 15, wherein the substantially organic shell comprises one or more of an organosilane or a corresponding organosilanyl substituent, an organoalcohol or a corresponding organoalkoxy substituent, or an organocarboxylic acid or a corresponding organocarboxylate substituent.

18. The NIL precursor material of claim 1, wherein the second refractive index ranges from 2.00 to 2.61.

19. A cured NIL material comprising a substantially cured resin component and a nanoparticles component ranging from 45 wt. % to 90 wt. % of the cured NIL material, wherein the cured NIL material has a third refractive index, and wherein the cured NIL material is made by exposing the NIL precursor material of claim 1 to a light source.

20. The cured NIL material of claim 19, wherein the third refractive index ranges from 1.75 to 2.00.
